(19) United States
(12) Patent Application Publication
(10) Pub. No.: US 2025/0253230 A1
(43) Pub. Date: Aug. 7, 2025

(54) Structure and Method for Three-Dimensional Capacitor with Enhanced Packaging Density and Reduced Warpage

(71) Applicant: Taiwan Semiconductor Manufacturing Company, Ltd., Hsin-Chu (TW)

(72) Inventors: Tzu-Ting LIU, Taoyuan City (TW); Hsiang-Ku SHEN, Hsinchu City (TW); Yi-Shan HSIEH, Hsinchu (TW); Chia-Yueh CHOU, Taoyuan City (TW); Ying-Ju WU, Hsinchy (TW); Chen-Chiu HUANG, Taichung City (TW); Dian-Hau CHEN, Hsinchu (TW)

(21) Appl. No.: 18/907,126

(22) Filed: Oct. 4, 2024

Related U.S. Application Data
(60) Provisional application No. 63/550,352, filed on Feb. 6, 2024.

(51) Int. Cl. H01L 23/522; H01L 21/768; H01L 27/06

(52) U.S. Cl. CPC H01L 23/5223; H01L 21/76834; H01L 21/7687; H10D 1/042; H10D 1/714; H10D 1/716; H10D 88/00

(57) ABSTRACT

The present disclosure provides a semiconductor structure that includes a substrate having devices formed thereon and an interconnect structure electrically coupling the devices into an integrated circuit; a passivation structure formed on the interconnect structure; and a capacitor embedded in the passivation structure, wherein the capacitor includes first metal-insulator-metal (MIM) stacks inserted in first trenches, and second MIM stacks formed into first pillar structures.

This application claims priority to U.S. Provisional Patent Application Ser. No. 63/550,352 filed Feb. 6, 2024, the entire disclosure of which is hereby incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of IC processing and manufacturing, and for these advancements to be realized, similar developments in IC processing and manufacturing are needed. For example, a capacitor, as a passive device, is an important device in integrated circuits and is widely used for various purposes, such as in random access memory (RAM) non-volatile memory devices, decoupling capacitor, or RC circuit. When the IC moves to advanced technology nodes with less feature sizes, a capacitor is almost non-shrinkable and cannot be scaled down to small dimensions due to capacitor characteristics. A capacitor takes a significant circuit area penalty. Furthermore, the existing method making a capacitor introduces defects into the capacitor and causes undesired issues, such as stress and induced wafer warpage. Accordingly, it would be desirable to provide a capacitor structure integrated with other circuit devices and a method of manufacturing thereof absent the disadvantages discussed above.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a sectional view of an integrated circuit (IC) structure having a capacitor, constructed according to some embodiments of the present disclosure;

FIG. 1B is a sectional view of an IC structure having a capacitor, constructed according to some embodiments of the present disclosure;

FIGS. 2A and 2C are sectional views of an IC structure having a capacitor, constructed according to some embodiments of the present disclosure;

FIGS. 2B and 2D are top views of the IC structure having a capacitor, constructed according to some embodiments of the present disclosure;

FIG. 2E is a schematic sectional view of a capacitor, constructed according to some embodiments of the present disclosure;

FIG. 3 is a sectional view of an IC structure having a capacitor, constructed according to some embodiments of the present disclosure;

FIG. 4A is a sectional view of an IC structure having a capacitor, constructed according to some embodiments of the present disclosure;

FIG. 4B is a top view of the IC structure having a capacitor, constructed according to some embodiments of the present disclosure;

FIG. 5 is a sectional view of an IC structure having a capacitor, constructed according to some embodiments of the present disclosure;

FIG. 6A is a sectional view of an IC structure having a capacitor, constructed according to some embodiments of the present disclosure;

FIG. 6B is a top view of the IC structure having a capacitor, constructed according to some embodiments of the present disclosure;

FIG. 7A is a sectional view of an IC structure having a capacitor, constructed according to some embodiments of the present disclosure;

FIG. 7B is a top view of the IC structure having a capacitor, constructed according to some embodiments of the present disclosure;

FIG. 8A is a sectional view of an IC structure having a capacitor, constructed according to some embodiments of the present disclosure;

FIG. 8B is a top view of the IC structure having a capacitor, constructed according to some embodiments of the present disclosure;

FIG. 8C is a sectional view of an IC structure having a capacitor, constructed according to some embodiments of the present disclosure;

FIG. 9A is a sectional view of an IC structure having a capacitor, constructed according to some embodiments of the present disclosure;

FIG. 9B is a top view of the IC structure having a capacitor, constructed according to some embodiments of the present disclosure;

FIG. 10A is a sectional view of an IC structure having a capacitor, constructed according to some embodiments of the present disclosure;

FIG. 10B is a diagrammatical section view of the IC structure having a capacitor, constructed according to some embodiments of the present disclosure;

FIGS. 11A and 11C are sectional views of an IC structure having a capacitor, constructed according to some embodiments of the present disclosure;

FIG. 11B is a top view of the IC structure having a capacitor, constructed according to some embodiments of the present disclosure;

FIGS. 12A, 12B, 12C, 12D, 12E, 12F, 12G, 12H, 12I, 12J, 12K and 12L are sectional views of an IC structure at various fabrication stages, constructed according to some embodiments of the present disclosure;

FIGS. 13A, 13B, 13C, 13D and 13E are sectional views of an IC structure at various fabrication stages, constructed according to some embodiments of the present disclosure;

FIGS. 14A, 14B, 14C, 14D, 14E, 14F, 14G and 14H are sectional views of an IC structure at various fabrication stages, constructed according to some embodiments of the present disclosure;

FIGS. 15A, 15B, 15C and 15D are sectional views of an IC structure at various fabrication stages, constructed according to some embodiments of the present disclosure;

FIGS. 16A, 16B, 16C, 16D, 16E, 16F, 16G and 16H are sectional views of an IC structure at various fabrication stages, constructed according to some embodiments of the present disclosure;

FIGS. 17A, 17C and 17D are sectional views of an IC structure having a capacitor, constructed according to some embodiments of the present disclosure;

FIG. 17B is a top view of the IC structure having a capacitor, constructed according to some embodiments of the present disclosure;

FIGS. 18A, 18B, 18C and 18D are sectional views of an IC structure having a capacitor, constructed according to some embodiments of the present disclosure;

FIGS. 19A and 19C are sectional views of an IC structure having a capacitor, constructed according to some embodiments of the present disclosure;

FIG. 19B is a top view of the IC structure having a capacitor, constructed according to some embodiments of the present disclosure;

FIGS. 20A, 20B, 20C, 20D, 20E, 20F, 20G and 20H are sectional views of an IC structure at various fabrication stages, constructed according to some embodiments of the present disclosure;

FIG. 21A is a sectional view of an IC structure having a capacitor, constructed according to some embodiments of the present disclosure;

FIG. 21B is a top view of the IC structure having a capacitor, constructed according to some embodiments of the present disclosure;

FIG. 22A is a sectional view of an IC structure having a capacitor, constructed according to some embodiments of the present disclosure;

FIG. 22B is a top view of the IC structure having a capacitor, constructed according to some embodiments of the present disclosure;

FIGS. 23A and 23C are sectional views of an IC structure having a capacitor, constructed according to some embodiments of the present disclosure;

FIG. 23B is a top view of the IC structure having a capacitor, constructed according to some embodiments of the present disclosure;

FIGS. 24A, 24B, 24C, 24D, 24E, 24F, 24G, 24H, 24I and 20J are sectional views of an IC structure at various fabrication stages, constructed according to some embodiments of the present disclosure;

FIGS. 25A, 25B, 25C, 25D, 25E, 25F, 25G, 25H, 25I and 25J are sectional views of an IC structure at various fabrication stages, constructed according to some embodiments of the present disclosure;

FIG. 26A is a sectional view of an IC structure having a capacitor, constructed according to some embodiments of the present disclosure;

FIG. 26B is a top view of the IC structure having a capacitor, constructed according to some embodiments of the present disclosure;

FIGS. 27A, 27B, 27C, 27D, 27E, 27F, 27G, 27H, 27I, 27J, 27K and 27L are sectional views of an IC structure at various fabrication stages, constructed according to some embodiments of the present disclosure;

FIGS. 28A, 28B and 28C are sectional views of an IC structure having a capacitor, constructed according to some embodiments of the present disclosure; and

FIG. 29 is a sectional view of an IC structure, constructed according to some embodiments of the present disclosure.

### DETAILED DESCRIPTION

The following disclosure provides many different embodiments, or examples, for implementing different features. Reference numerals and/or letters may be repeated in the various examples described herein. This repetition is for the purpose of simplicity and clarity and does not in itself dictate a relationship between the various disclosed embodiments and/or configurations. Further, specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Moreover, the formation of a feature on, connected to, and/or coupled to another feature in the present disclosure may include embodiments in which the features are formed in direct contact, and may also include embodiments in which additional features may be formed interposing the features, such that the features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one feature relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described, or other values as understood by person skilled in the art. For example, the term “about 5 nm” encompasses the dimension range from 4.5 nm to 5.5 nm.

The present disclosure relates generally to an integrated circuit (IC) structure and a method making the same, and more particularly, to a capacitor integrated with other devices, such as in a three-dimensional (3D) IC structure. The IC structure further includes other devices, such as field-effect transistors (FETs), fin-like FETs (FinFETs), and other multi-gate devices. In some examples, the multi-gate devices include gate-all-around (GAA) devices.

The disclosed IC structure includes one or more capacitors formed in the passivation layer and further configured within and integrated with the redistribution layer (RDL) in the passivation structure. The IC structure includes a substrate (such as a semiconductor substrate); various devices (such as field-effect transistors, memory devices, other suitable devices or a combination thereof) formed on the substrate; an interconnect structure formed over the devices and coupling the devices into an integrated circuit; and a passivation structure that is formed over the interconnect structure, seals the devices and the interconnect structure, and provides bonding features (such as aluminum pads or AP) through the passivation structure. The passivation structure includes multiple passivation layers of various passivation materials, and further includes a redistribution layer as a conductive structure to redistribute the bonding features and coupling the interconnect structure to the bonding features. Particularly, a capacitor, such as a decoupling capacitor, a capacitor for a dynamic random-access memory (DRAM) device, other type capacitor, or a combination thereof, is formed in the passivation structure and integrated with the RDL structure. In the disclosed embodiments, the capacitor has a metal-insulator-metal (MIM) structure. Portions of the RDL structure are patterned to form electrodes of the corresponding capacitor. The capacitor is formed with the RDL structure and the passivation material layers of the passivation structure. The passivation structure includes multiple passivation layers, such as a first passivation layer over the interconnect structure, and a second passivation layer over the first interconnect structure. Each passivation layer includes silicon nitride, silicon oxide (such as undoped silica glass or USG), or a combination thereof. In some embodiments, the RDL includes first portions vertically extending from top metal lines of the interconnect structure in the first passivation layer and second portions laterally extending in the second passivation layer. In furtherance of some embodiments of the present disclosure, each passivation layer is split into a plurality of passivation sublayers. For example, the first passivation layer is split into five passivation sublayers, such as a first passivation sublayer (Pass1-1), a second passivation sublayer (Pass1-2), a third passivation sublayer (Pass1-3), a fourth passivation sublayer (Pass1-4), and a fifth passivation sublayer (Pass1-5). It is understood that the number of the passivation sublayers can be any proper number n (wherein n is an integer such as 2, 3, 4, 5, 6, . . . ), depending on individual designs and applications. In the disclosed embodiment, each passivation layer includes multiple passivation sublayers and is formed through multiple depositions so that various electrodes of the capacitor can be formed. For example, the processing procedure includes depositing one passivation sublayer; depositing a first metal layer; patterning the deposited first metal layer as a first electrode of the capacitor; depositing a dielectric layer as a dielectric material layer of the capacitor; depositing a second metal layer; patterning the deposited second metal layer as a second electrode of the capacitor; and depositing another passivation sublayer. This processing procedure can be repeated multiple times (such as 3 times or 5 times) to form multiple metal-dielectric-metal (MIM) stacks configured in one passivation layer (or multiple passivation sublayers of the one passivation layer) of the passivation structure. Those MIM stack are connected to form a MIM capacitor with comb structure. For example, the odd metal layers are electrically connected to a first electrode and the even metal layers are electrically connected to a second electrode of the capacitor.

Metal features of the RDL structure, including metal vias and metal lines, are also formed in the passivation structure. The portions of the RDL structure are configured to properly connect to the electrodes of the capacitor. For example, one metal via of the RDL structure is landing on and electrically connected to the odd metal layers and another metal via of the RDL structure is landing on and electrically connected to the even metal layers, thereby forming the first and second electrodes of the capacitor, respectively. Thus, the capacitor is packed in a small circuit area but with a large capacitor area folded and vertically stacked. Furthermore, the stacked MIM structure may be further folded into one or more trenches, thereby further reducing the circuit area occupied by the capacitor. The IC structure integrated with one or more capacitors is further described below in detail.

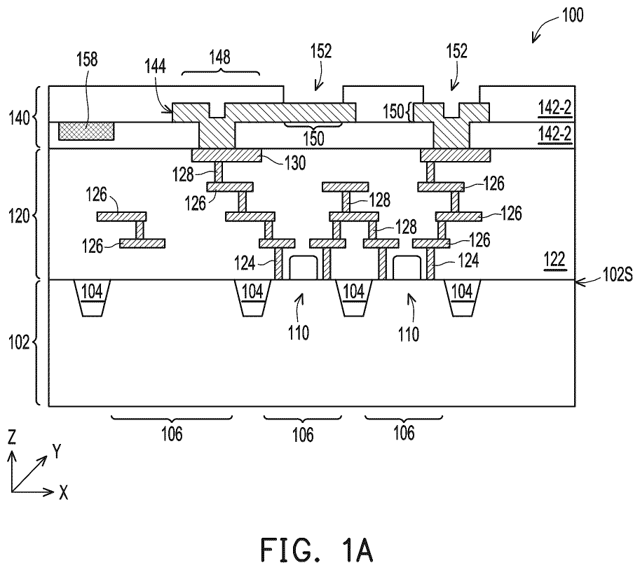

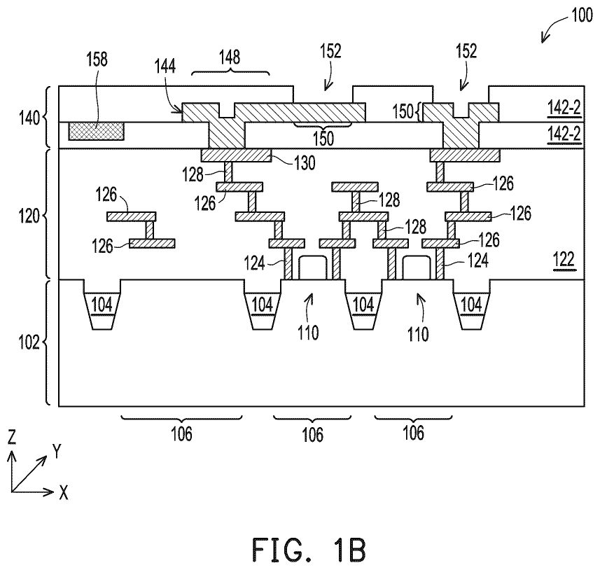

FIG. 1A is a sectional view of an integrated circuit (IC) structure (or semiconductor structure, or a workpiece) 100 constructed according to various aspects of the present disclosure in some embodiments. FIG. 1B is a sectional view of the semiconductor structure 100 with fin active regions constructed according to other embodiments. The semiconductor structure 100 and the method making the same are collectively described with reference to FIGS. 1A and 1B. In some embodiments, the IC structure 100 includes flat active regions with various IC devices, such as plain field-effect transistors (FETs), formed thereon, as illustrated in FIG. 1A. In some embodiments, the IC structure 100 includes fin active regions with various IC devices formed thereon, as illustrated in FIG. 1B.

The IC structure 100 includes a substrate 102, such as a semiconductor substrate. In some embodiments, substrate 102 includes a silicon substrate. Alternatively, substrate 102 may include an elementary semiconductor, such as silicon or germanium in a crystalline structure; a compound semiconductor, such as silicon germanium, silicon carbide, gallium arsenic, gallium phosphide, indium phosphide, indium arsenide, and/or indium antimonide; or combinations thereof. Possible substrate 102 also includes a silicon-on-insulator (SOI) substrate. SOI substrates are fabricated using separation by implantation of oxygen (SIMOX), wafer bonding, and/or other suitable methods. Substrate 102 includes a top surface 102S with two orthogonal directions X and Y defined thereon and a normal direction Z being perpendicular to both X and Y directions. The directions X, Y and Z constitute a Cartesian coordinate.

Substrate 102 also includes various isolation features, such as isolation features 104 formed on substrate 102 and defining various active regions on substrate 102, such as active regions 106. The isolation feature 104 utilizes proper isolation technology, such as shallow trench isolation (STI), to define and electrically isolate the various active regions. The isolation feature 104 includes one or more dielectric material, such as silicon oxide, silicon nitride, silicon oxynitride, low-k dielectric material, other suitable dielectric materials, or combinations thereof. The isolation feature 104 is formed by any suitable process. As one example, the formation of the STI feature(s) 104 includes a lithography process to expose a portion of the substrate, etching a trench in the exposed portion of the substrate (for example, by using a dry etching and/or wet etching), filling the trench (for example, by using a chemical vapor deposition (CVD) process) with one or more dielectric materials, and planarizing the substrate and removing excessive portions of the dielectric material(s) by a polishing process, such as a chemical mechanical polishing (CMP) process. In some examples, the filled trench may have a multi-layer structure, such as a thermal oxide liner layer and filling layer(s) of silicon oxide, silicon nitride, or both.

The active region 106 is a region with a semiconductor surface wherein various doped features are formed and configured for one or more device, such as a diode, a transistor, and/or other suitable devices, to be formed thereon. The active region may include a semiconductor material similar to that (such as silicon) of the bulk semiconductor material of the substrate 102 or different semiconductor material, such as silicon germanium (SiGe), silicon carbide (SiC), or multiple semiconductor material layers (such as alternative silicon and silicon germanium layers) formed on the substrate 102 by epitaxial growth, for performance enhancement, such as strain effect to increase carrier mobility.

In some embodiments illustrated in FIG. 1B, the active region 106 is three-dimensional, such as a fin active region extended above the isolation feature 104. The fin active region is extruded from substrate 102 and has a three-dimensional profile for more effective coupling between the channel region (or simply referred to as channel) and the gate electrode of a FET. The fin active region 106 may be formed by selective etching to recess the isolation features 104, or selective epitaxial growth to grow active regions with a semiconductor material same or different from that of the substrate 102, or a combination thereof. In some embodiments, the channel region includes a plurality of channels vertically stacked, to form multiple gate transistors, such as gate-all-around (GAA) field-effect transistor.

Substrate 102 further includes various doped features, such as n-type doped wells, p-type doped wells, source and drain, other doped features, or a combination thereof configured to form various devices or components of the devices. The IC structure 100 includes various IC devices 110 formed on substrate 102. The IC devices 110 include field-effect transistors (FETs), fin FETs (FinFETs), GAA FETS, diodes, bipolar transistors, imaging sensors, resistors, capacitors, inductors, memory cells, or a combination thereof. In FIG. 1A (or FIG. 1B), FETs are provided only for illustration.

The IC structure 100 further includes an interconnect structure 120 formed on the IC devices 110. The interconnection structure 120 includes various conductive features to couple various IC devices 110 into an integrated circuit. The interconnect structure 120 further includes an interlayer dielectric (ILD) layer 122 to separate and isolate various conductive features. For example, the interconnect structure 120 includes contacts 124; metal lines 126; and vias 128. The metal lines 126 are distributed in multiple metal layers. In FIG. 1A, four metal layers are illustrated. The top metal lines are separately labeled with numerical 130. Contacts 124 provide vertical electrical routing from substrate 102 to the metal lines. The vias 128 provide vertical electrical routing between adjacent metal layers. Various conductive features are formed by one or more conductive materials, such as metal, metal alloy, silicide, other suitable conductive materials or combinations thereof. For example, the metal lines 126 may include copper, aluminum copper alloy, other suitable conductive material, or a combination thereof. The vias 128 may include copper, aluminum copper alloy, other suitable conductive material, or a combination thereof. The contacts 124 may include tungsten, silicide, nickel, cobalt, copper, other suitable conductive material, or a combination thereof. In some examples, various conductive features may further include a barrier layer, such as tantalum and tantalum nitride, titanium and titanium nitride, or other suitable materials. In the present embodiment, the top metal lines 130 include copper.

The ILD layer 122 includes one or more dielectric material to provide isolation functions to various device components (such as gates) and various conductive features (such as metal lines, contacts and vias). The ILD layer 122 includes a dielectric material, such as silicon oxide, a low-k dielectric material, other suitable dielectric material, or a combination thereof. In some examples, the low-k dielectric material includes fluorinated silica glass (FSG), carbon doped silicon oxide, Xerogel, Aerogel, amorphous fluorinated carbon, Parylene, BCB (bis-benzocyclobutenes), polyimide, and/or other suitable dielectric materials with dielectric constant substantially less than that of the thermal silicon oxide. The formation of the ILD layer 122 may include deposition and chemical mechanical polishing (CMP). The deposition may include spin-on coating, CVD, other suitable deposition technology or a combination thereof. The ILD layer 122 may include multiple layers and is collectively formed with various conductive features in a proper procedure, such as a damascene process. In some embodiments, the interconnect structure 120 or a portion thereof is formed by deposition and patterning. For example, a metal (or metal alloy) is deposited by physical vapor deposition (PVD) and is patterned by lithography process and etching. Then an ILD layer 122 is disposed on by deposition (and CMP). In some embodiments, the interconnect structure 120 uses a damascene process to form metal lines. In a damascene process, an ILD layer is deposited, may be further planarized by CMP, and then is patterned by lithography and etching to form trenches. One or more conductive material is deposited to fill the trenches, and another CMP process is applied to remove the excessive conductive material and planarize the top surface, thereby forming conductive features. The damascene process may be used to form metal lines, vias, and contacts. A dual damascene process may be applied to form one layer of metal lines and vias adjacent the metal lines.

The IC structure 100 also includes a passivation structure 140 formed over the interconnect structure 120 to provide sealing effect to the IC devices 110 and the interconnect structure 120. The passivation structure 140 includes one or more passivation layers 142 and a redistribution layer (RDL) structure 144 formed in the passivation layers. The RDL structure 144 is positioned over and electrically connected to the interconnect structure 120 to redistribute bonding pads. This redistribution allows for the formation of connections from the edge to the center of an IC chip, facilitating flip chip bonding or other suitable packaging technologies to integrate an IC chip with a board, such as a printed circuit board.

The RDL structure 144 includes various metallic features embedded in the passivation layer 142 and may include metal lines and metal vias in a configuration to electrically connect the top metal lines 130 to the bond pads according to the designed circuit. Portions of the RDL structure 144 in the openings 152 of the passivation layer 142 function as bond pads 150. In the present embodiment, the passivation layer 142 includes a first passivation layer 142-1 and a second passivation layer 142-2 disposed on the first passivation layer 142-1. In the disclosed embodiment, the first passivation layer 142-1 includes a redistribution via (RV) hole aligned to a top metal line 130 so that a portion 148 of a RDL structure 144 is formed in the RV hole and directly contacts the top metal line 130. The portion 148 of the RDL structure 144 is also referred to as RV pad 148. The RDL structure 144 vertically extends from the first passivation layer 142-1 to the second passivation layer 142-2 and horizontally extends from the RV pad 148 to the bond pad 150 to redistribute bond pad. The RDL structure 144 may include multiple metal layers according to some embodiments. In the disclosed embodiments, the first passivation layer 142-1 includes a silicon nitride (SiN) layer and an un-doped silica glass (USG) layer on the SiN layer; and the second passivation layer 142-2 includes an USG layer and a SiN layer disposed on the USG layer. The passivation structure 140 further includes one or more capacitor 158 formed in the passivation layers. Each passivation layer is further split into multiple sublayers with the capacitor(s) 158 folded and embedded therein, which will be further described later in detail.

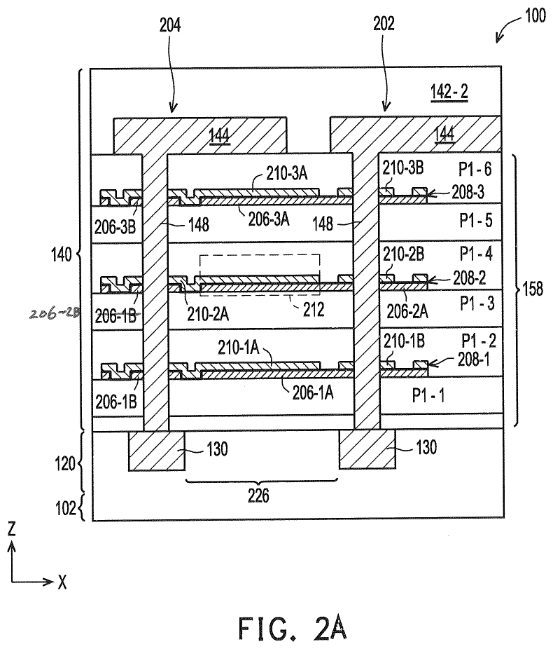

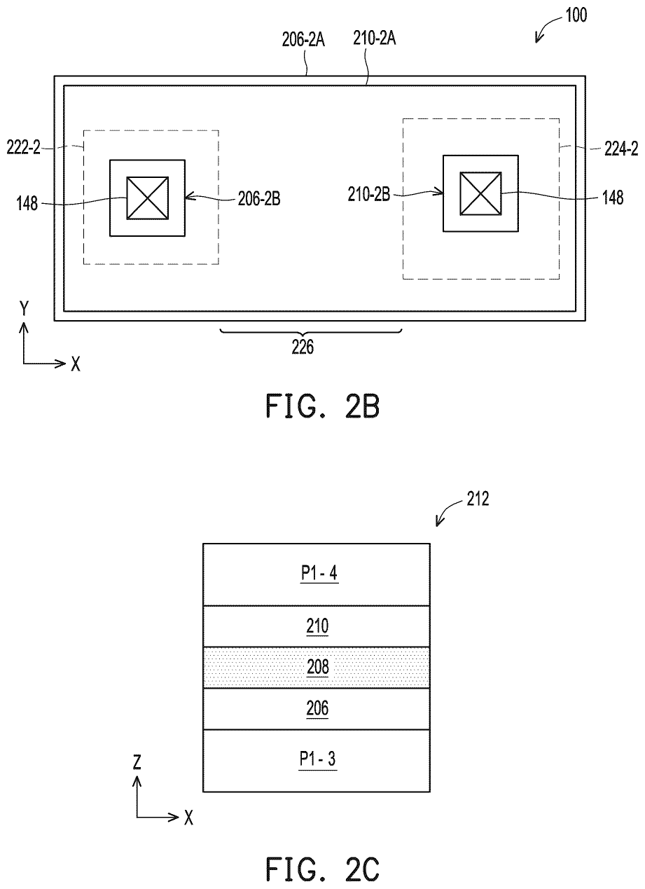

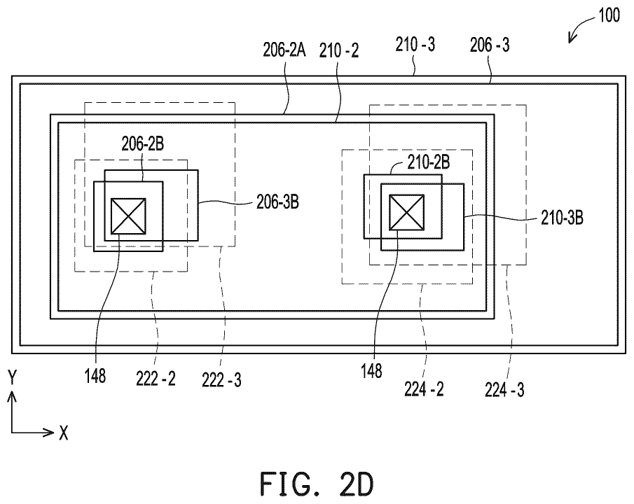

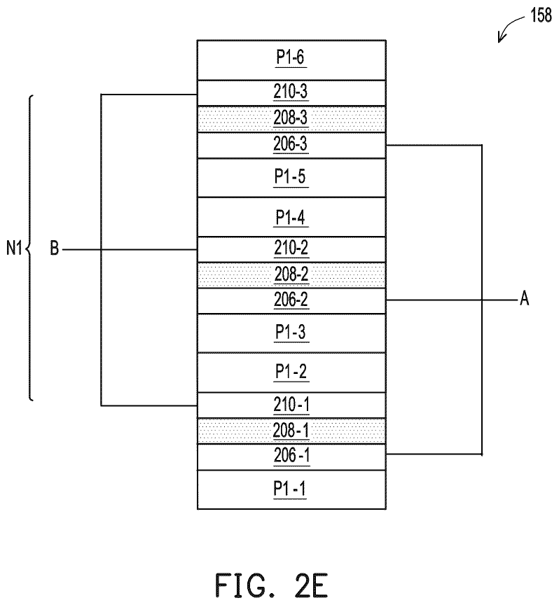

FIGS. 2A and 2C are sectional views of an IC structure 100, FIGS. 2B and 2D are top views of the IC structure 100, and FIG. 2E is a fragmentary sectional view of the IC structure 100, in portion, constructed according to various embodiments. The IC structure 100 includes a substrate 102; various devices 110 (such as field-effect transistors, memory devices, other suitable devices or a combination thereof, not shown) formed on the substrate 102; an interconnect structure 120 formed over the devices 110 and coupling the devices 110 into an integrated circuit; and a passivation structure 140 that is formed over the interconnect structure 120, seals the devices 110 and the interconnect structure 120, and provides bonding features (such as aluminum pads or AP). The passivation structure 140 includes multiple passivation layers 142 of various passivation materials, and further includes a redistribution layer (RDL) structure 144 as conductive paths to redistribute the bond features and coupling the interconnect structure 120 to the bond features. Particularly, a capacitor 158, such as a decoupling capacitor, other type capacitor or a combination thereof, is formed in the passivation structure 140 with the RDL structure 144. In the disclosed embodiments, the capacitor 158 has a metal-insulator -metal (MIM) structure. I addition to the redistribution bond features, portions of the RDL structure 144 are patterned to form electrodes of the corresponding capacitor 158.

As illustrated in FIG. 2A, the capacitor 158 is formed with the RDL structure 144 and the passivation layers 142 of the passivation structure 140. The passivation structure 140 includes multiple passivation layers 142 (such as passivation layers 142-1 and 142-2), and at least one of the passivation layers 142 includes a plurality of passivation sublayers. For example, the first passivation layer 142-1 includes a first passivation sublayer (P1-1), a second passivation sublayer (P1-2), a third passivation sublayer (P1-3), a fourth passivation sublayer (P1-4), a fifth passivation sublayer (P1-5), and a sixth passivation sublayer (P1-6). In the disclosed embodiment, the multiple passivation sublayers (such as P1-1 through P1-6) are formed through multiple depositions so that conductive plates of capacitor 158 can be stacked and interdigitated with the multiple passivation sublayers of the in the passivation structure 140 in order to increase the capacitance without increasing the occupied die area. Particularly, the passivation sublayers and the conductive plates are alternatively deposited, and the conductive plates are further pattered by lithography process and etching. For example, the processing procedure includes depositing one passivation sublayer (such as P1-1); depositing a first metal layer (or a bottom metal layer) 206; patterning the deposited first metal layer 206 as a first metal plate of the capacitor 158; depositing a dielectric material layer 208 as a dielectric layer of the capacitor; depositing a second metal layer (or a top metal layer) 210; patterning the deposited second metal layer 210 as a second metal plate of the capacitor 158; and depositing another passivation sublayer (such as P1-2). This processing procedure can be repeated multiple times (such as 3 times, as illustrated in FIG. 2A) to form multiple metal-insulator-metal (MIM) stacks (such as 3 MIM stacks as illustrated in FIG. 2A) in one passivation layer (e.g., the first passivation layer 142-1) of the passivation structure 140. Those MIM stacks are further connected to form a MIM capacitor 158 with comb structure. For example, the first metal layers 206 are electrically connected to a first electrode 202 and the second metal layers 210 are electrically connected to a second electrode 204 of the capacitor 158, as described below in detail. In FIG. 2A, capacitor 158 includes three MIM stacks vertically stacked one over another. It is understood that capacitor 158 may include any proper number of MIM stacks, such as 4, 5 or 6 MIM stacks. For better description, the first metal layer 206, the dielectric layer 208 and the second metal layer 210 for those three MIM stacks may be referred separately to avoid confusion. Specifically, the first MIM stack includes the first metal layer (or bottom metal layer) 206-1, the dielectric layer 208-1 and the second metal layer (or top metal layer) 210-1; the second MIM stack includes the first metal layer 206-2, the dielectric layer 208-2 and the second metal layer 210-2; and the third MIM stack includes the first metal layer 206-3, the dielectric layer 208-3, and the second metal layer 210-3.

A portion 212 of a MIM stack (such as the second MIM stack in the dashed box of FIG. 2A) is zoomed in and is further illustrated in FIG. 2C in a sectional view. The capacitor 158 includes multiple MIM stacks (each including the first metal layer 206; the dielectric material layer 208; and the second metal layer 210) stacked and sandwiched between passivation sublayers, such as P1-3 and P1-4. In various embodiments, each of the first and second metal layers 206, 210 includes any suitable conductive material, such as metal, metal alloy, silicide, other suitable conductive material or a combination thereof. In some examples, the first metal layers 206 and the second metal layers 210 include titanium nitride (TiN). In various embodiments, the first metal layers 206 and the second metal layers 210 are deposited physical vapor deposition (PVD), plating, other suitable deposition method or a combination thereof.

The dielectric material layers (or simply dielectric layers) 208 function as dielectric medium of the capacitor 158 and include high-k dielectric material, low-k dielectric material, silicon oxide, silicon nitride, silicon oxynitride, or a combination thereof. A high-k dielectric material is a dielectric material with a dielectric constant greater than that of the thermal silicon oxide. In some embodiments, the high-k dielectric material includes metal oxides, metal nitrides, metal silicates, transition metal-oxides, transition metal-nitrides, transition metal-silicates, oxynitrides of metals. In furtherance of the embodiments, the high-k dielectric material includes metal aluminates, zirconium silicate, zirconium aluminate, HfO₂, ZrO₂, ZrOₓN_{y}, HfOₓN_{y}, HfSiₓO_{y}, ZrSiₓO_{y}, HfSiₓO_{y}N_{z}, ZrSiₓO_{y}N_{z}, Al₂O₃, TiO₂, Ta₂O₅, La₂O₃, CeO₂, Bi₄Si₂O₁₂, WO₃, Y₂O₃, LaAlO₃, PbTiO₃, BaTiO₃, SrTiO₃, PbZrO₃, other suitable high-k dielectric material or a combination thereof. In various examples, the method to form a high-k dielectric material film includes vapor phase deposition (CVD), metal organic chemical vapor phase deposition (MOCVD), PVD, atomic layer deposition (ALD), molecular beam epitaxy (MBE), other suitable technique, or a combination thereof. In another example, the high-k dielectric material may be formed by UV-Ozone Oxidation, which includes sputtering metal film; and oxidation by in-situ of metal film by O2 in presence of UV light.

Metal features of the RDL structure 144, including metal vias and metal lines, are also formed in the passivation structure 140. The portions of the RDL structure 144 are configured to properly connect the plates of the capacitor 158 as the corresponding electrodes 202 and 204 of the capacitor 158. In one example, a first metal via (or RV pad) 148 of the RDL structure 144 is landing and electrically connected to the first metal layers 206 and a second metal via 148 of the RDL structure 144 is landing and electrically connected to the second metal layers 210, thereby forming the first and second electrodes (202, 204) of the capacitor 158, as further illustrated in FIG. 2A. Note that each of the first and metal vias 148 is contacts both the bottom metal layers 206 and the top metal layers 210. However, the bottom metal layers 206 and the top metal layers 210 are patterned such that the capacitor 158 is properly connected to the first electrode 202 and the second electrode 204, which is further explained below.

First and second metal layers (or bottom and top metal layers) 206 and 210 may have different patterns, such as different shape, dimensions or a combination thereof, so that the vias 148 can properly connected to corresponding metal layers. Take the MIM stack between the passivation sublayers P1-3 and P1-4 as an example. The first metal layer 206 is patterned into a main plate 206A (the right portion in FIG. 2A) and an island 206B (the left portion in FIG. 2A) disconnected from each other. The second metal layer 210 is patterned into a main plate 210A (the left portion in FIG. 2A) and an island 210B (the right portion in FIG. 2A) disconnected from each other. The main plate 206A of the first metal layer 206 and the main plate 210A of the second metal layer 210 are overlapped (in the top view) and sandwich the dielectric material layer 208 therebetween. The overlapped main plates 206A, 210A of the first metal layer 206 and the second metal layer 210, and the dielectric material layer 208 constitute a MIM stack of the capacitor 158, as enclosed in a dashed line box 212 of FIG. 2A. The island 206B of the first metal layer 206 and the island 210B of the second metal layer 210 are not portions of the capacitor 158 and may be eliminated. However, the presence of the islands 206B and 210B can effectively reduce the boundary effect and increase the capacitance of the capacitor 158 (or particularly the capacitance of the corresponding MIM stack of the capacitor 158). Furthermore, the main plate 206A of the first metal layer 206 further extends to the right so that the first metal via 148 is landing thereon, thereby forming the first electrode 202 to the first main plate 206A of the MIM stack. Even though the first metal via 148 is also landing on the island 210B of the second metal layer 210, the island 210B stands along and is not connected to the main plate 210A, therefore being disconnected from the MIM stack. Similarly, the main plate 210A of the second metal layer 210 further extends to the left so that the second metal via 148 is landing thereon, thereby forming the second electrode 204 to the second main plate 210A of the MIM stack. Even though the second metal via 148 is also landing on the island 206B of the first metal layer 206, the island 206B stands along and is not connected to the main plate 206A, therefore being disconnected from the MIM stack.

In some embodiments illustrated in FIG. 2B in a top view, only one MIM stack (such as the second MIM stack between the passivation sublayers P1-3 and P1-4, note that all labels to various features of the second MIM stack are differentiated from others by “-2”) is shown for simplicity. As described above, the island 206-2B of the first metal layer 206-2 and the island 210-2B of the second metal layer 210-2 may be eliminated or present but designed with any proper shape according to some embodiments. The first metal via 148 (on the right side) is connected to the first main plate 206-2A; and the second metal via 148 (on the left side) is connected to the second main plate 210-2A.

Especially, the first metal layer 206-2 includes the main plate 206-2A with a first opening 222-2, the first metal via 148 is landing on the main plate 206-2A while the second metal via 148 falls within the first opening 222-2 and is disconnected from the first main plate 206-2A. In the disclosed embodiment, the first metal layer 206-2 further includes the island 206-2B formed within the first opening 222-2 with less dimensions so to have enough margins to be disconnected from the first main plate 206-2A. In furtherance of the embodiment, the first opening 222-2 and the island 206-2B may be designed with any proper shapes, such as square shapes, round shapes, rectangle shapes, other proper shapes or combinations thereof.

Similarly, in FIG. 2B, the second metal layer 210-2 includes the main plate 210-2A with a second opening 224-2, the second metal via 148 is landing on the main plate 210-2A while the first metal via 148 falls within the second opening 224-2 and is disconnected from the second main plate 210-2A. In the disclosed embodiment, the second metal layer 210-2 further includes the island 210-2B formed within the second opening 224-2 with less dimensions so to have enough margins to be disconnected from the second main plate 210-2A. In furtherance of the embodiment, the second opening 224-2 and the island 210-2B may be designed with any proper shapes, such as square shapes, round shapes, rectangle shapes, other proper shapes or combinations thereof.

Referring again to FIG. 2B, the first main plate 206-2A of the first metal layer 206-2 and the second main plate 210-2A of the second metal layer 210-2 within the region 226 (including the MIM stack in the dashed line box 212 of FIG. 2A, as well as other MIM stacks within the same region) substantially define the capacitive area of capacitor 158. The remaining portions (such as openings or islands 222-2 and 224-2) reserve the landing areas for the electrodes of capacitor 158. Note that only one MIM stack (e.g., the second MIM stack comprising the first metal layer 206-2, the dielectric layer 208-2 and the second metal layer 210-2) is depicted in FIG. 2B. Further note that the dielectric layer 208-2 is not shown in FIGS. 2B and 2D. Other MIM stacks, each also consisting of a stack of one first metal layer 206, one dielectric layer 208 and one second metal layer 210, overlap each other in the top view. The first metal layers 206 (or second metal layers 210) in different MIM stacks may have identical or differing patterns. FIG. 2D shows two MIM stacks of the first metal layers 206, the dielectric layer 208 and the second metal layers 210 in the top view, demonstrating that the first metal layers 206 (or the second metal layers 210) are patterned differently. In the disclosed embodiment illustrated in FIG. 2D, only the second and third MIM stacks, especially the corresponding metal layers, are illustrated for simplicity.

In FIG. 2D, the third (or first) MIM stack is similar to the second MIM stack in FIG. 2B, while the third MIM stack is designed and configured differently. Specifically, in the second MIM stack, the first metal layer 206-2, the second metal layer 210-2, the first opening of the first metal layer 222-2, and the second opening of the second metal layer 224-2 are designed and configured similar to those in FIG. 2B. The third MIM stack includes the first metal layer 206-3, the second metal layer 210-3, a first opening 222-3 of the first metal layer 206-3, and a second opening 224-3 of the second metal layer 210-3, which are designed differently. The first openings 222-2 and 222-3 differ in size and location but overlap, with the second via 148 disposed in the overlapped region of these first openings. Similarly, the second openings 224-2 and 224-3 also differ in size and location but overlap, with the first via 148 disposed in the overlapped region of these second openings. In the disclosed embodiment illustrated in FIG. 2D, the islands 206-2B, 206-3B, 210-2B and 210-3B may present or alternatively be eliminated.

Such formed capacitor 158 is further illustrated in FIG. 2E. Particularly, capacitor 158 includes a plurality of first metal layers 206 (such as 206-1, 206-2 and 206-3), a plurality of dielectric layers 208 (such as 208-1, 208-2 and 208-3), and a plurality of second metal layers 210 (such as 210-1, 210-2 and 210-3) alternatively stacked to form multiple MIM stacks (three MIM stacks in the present example), which are further connected to form an interleaved capacitor 158. The first metal layers 206 (such as 206-1, 206-2 and 206-3) are electrically connected through first metal via 148 and first metal line 202 of the RDL structure 144 to form a first electrode A; and the second metal layers 210 (such as 208-1, 208-2 and 208-3) are electrically connected through second metal via 148 and second metal line 204 of the RDL structure 144 to form a second electrode B. The capacitor 158 includes a number N₁ of MIM stacks (each having a sandwiched 206, 208 and 210) embedded in the passivation sublayers (P1-1, P1-2, and etc., . . . ) of the first passivation layer 142-1. N₁ is any suitable integer, such as 2, 3, 4, 5 or etc. In the illustrated embodiment, N₁ is 3. The total capacitance of the interleaved capacitor 158 is C=εAN₁/d, in which ε is the permittivity of the dielectric layers 208; A is the area of first and second metal layers 206, 208; and d is the distance of the adjacent first and second metal layers or thickness of one dielectric layer 208. Note that the A is the overlapped area of the main plate 206A of the bottom metal layer 206 and the main plate 210A of the top metal layer 210. From the above formula, increasing the permittivity of the dielectric layers 148 and increasing the areas of the conductive layers 146 will effectively increase the capacitance of the interleaved capacitor 158. As stated above, to increase the capacitance of the interleaved capacitor 158, one or more high-k dielectric material is employed to form the dielectric layers 208. Increasing N₁ also increases the capacitance of the capacitor 158. To further increase the capacitance of the interleaved capacitor 158, the MIM stacks of the first metal layer 206, the second metal layer 210, and the dielectric layers 208 are folded into deep trenches or on pillar structures (sometime also referred to as fin structures, which are different from fin active regions) to increase the areas of the metal layers 206, 210 without increasing the packing area of the capacitor 158 on the substrate 102, which will be further described later. Note that a pillar structure refers to a MIM stack formed on a pillar or formed into a pillar structure so that MIM stack can vertically folded to reduce the area and increase the capacitance.

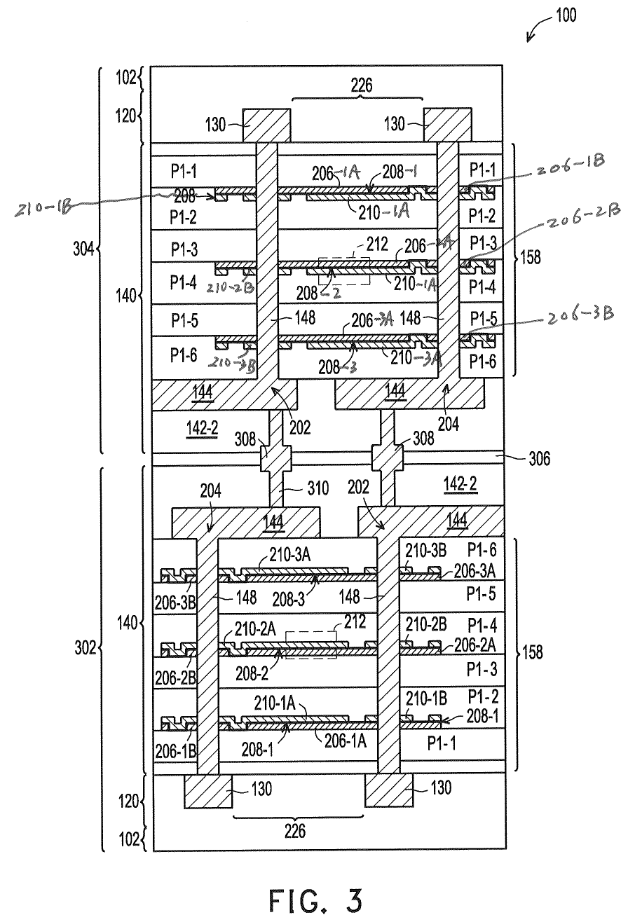

FIG. 3 is a sectional view of an IC structure 100, in portion, constructed according to various embodiments. The IC structure 100 also includes a capacitor 158 embedded in the passivation structure 144. However, the IC structure 100 includes a first IC die 302 and a second IC die 304 bonded together through a bonding interface 306, thereby forming a three-dimensional IC (3DIC) structure having a capacitor 158 extended in the first die 302 and the second die 304. The first IC die 302 and the second IC die 304 are bonded in a proper mode, such as frontside to frontside bonding. The bonding interface 306 may adopt any suitable bonding structure, such as hybrid bonding structure, wherein the bonding interface 306 includes conductive bonding interfaces and dielectric bonding interfaces. The conductive bonding interfaces include conductive features 308 to provide electrical routing. The conductive features 308 may be bonding pads from the first IC die 302 and the second IC die 304 directly bonded together. Dielectric bonding interfaces may be any suitable dielectric material, such as silicon oxide from the first IC die 302 and the second IC die 304 directly bonded together to provide bonding strength. For example, a silicon oxide layer is formed on the frontside of each IC die, such as formed on the corresponding passivation structure 140. The RDL structure 144 on each IC die may further include other metal lines, vias or a combination thereof, configured to coupled with the conductive bonding interface so that the capacitor 158 of the first IC die 302 and the capacitor 158 of the second IC die 304 are integrated into a single capacitor (still be referred to as a capacitor 158). After bonding, the substrate of the second IC die 304 may be removed from the 3DIC structure.

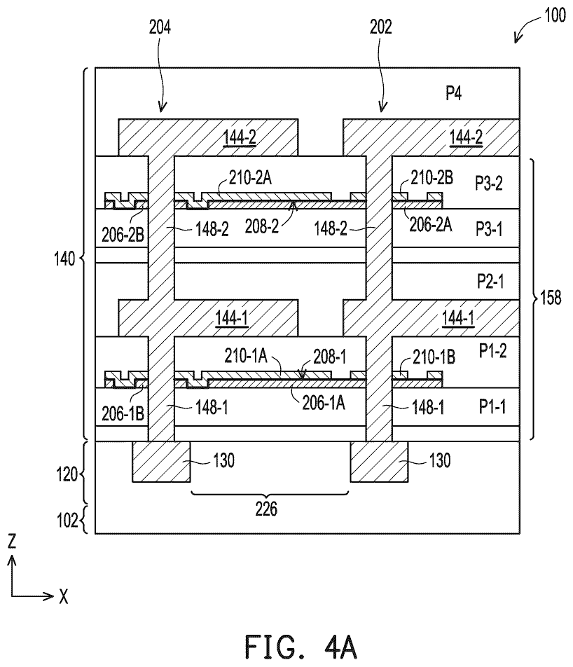

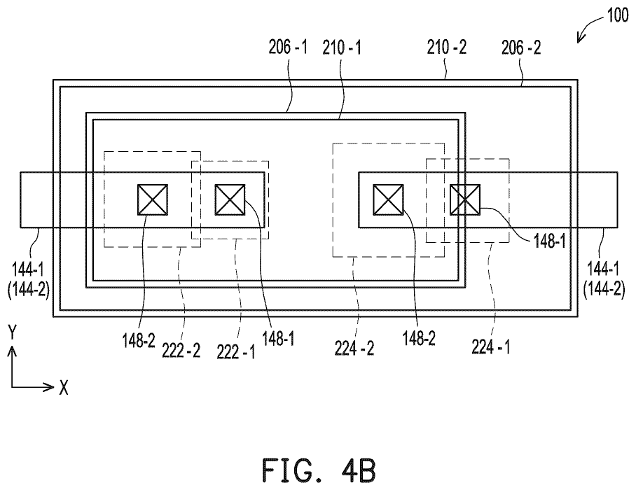

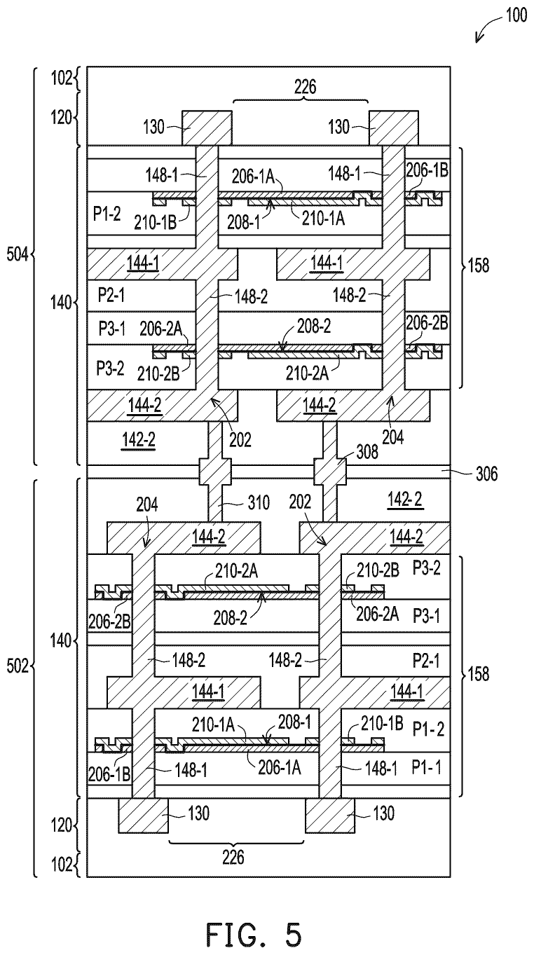

FIG. 4A is a sectional view of an IC structure 100, FIG. 4B is a top view of the IC structure 100, and FIG. 5 is a fragmentary sectional view of the IC structure 100, in portion, constructed according to various embodiments.

The IC structure 100 in FIGS. 4A, 4B and 5 illustrates a different IC structure having one or more capacitor 158 integrated therein. In FIGS. 4A and 4B, the IC structure 100 includes a capacitor 158 and a RDL structure 144 embedded in the passivation structure 140. Especially, the RDL structure 144 includes two or more metal layers (e.g., 144-1 and 144-2); and two or more via layers 148 (148-1 and 148-2) configured to connect the top metal features 130 of the interconnect structure 120, such as to bond pads over the RDL structure 144. Accordingly, the passivation structure 140 also includes two or more passivation layers 142, such as a first passivation layer P1, a second passivation layer P2, a third passivation layer P3, and a fourth passivation layer P4. The first vias 148-1 are formed in the first passivation layer P1, the first metal lines 144-1 are formed in the second passivation layer P2, the second vias 148-2 are formed in the third passivation layer P3, and the second metal lines 144-2 are formed in the fourth passivation layer P4.

Furthermore, the capacitor 158 extends through multiple passivation layers of the passivation structure 140. Capacitor 158 includes a first MIM stack embedded in the first passivation layer P1 and a second MIM stack embedded in the third passivation layer P3. The first passivation layer P1 includes a first sublayer P1-1 and a second sublayer P1-2 with the first MIM stack sandwiched therebetween; and the third passivation layer P3 includes a first sublayer P3-1 and a second sublayer P3-2 with the second MIM stack sandwiched therebetween.

RDL structure 144 includes first metal lines 144-1 formed in the second passivation layer P2 and second metal lines 144-2 formed in the fourth passivation layer P4, first vias 148-1 underlying the first metal lines 144-1 and the second vias 148-2 overlying the first metal lines 144-1. As illustrated in FIG. 4B, the first vias 148-1 and the second vias 148-2 may be designed with same or different location, shape, size or a combination thereof. For example, the opening 222-1 of the first metal layer 206-1 in the first passivation layer P1 and the opening 222-2 of the first metal layer 206-2 in the third passivation layer P3 are designed differently in terms of location and dimension. The opening 224-1 of the second metal layer 210-1 in the first passivation layer P1 and the opening 224-2 of the second metal layer 210-2 in the third passivation layer P3 are designed differently in terms of location and dimension. Especially, the first via 148-1 and second via 148-2 associated with the first electrode 202 of the capacitor 158 can be designed without overlapping; and the first via 148-1 and second via 148-2 associated with the second electrode 202 of the capacitor 158 can be designed without overlapping, as illustrated in FIG. 4B. Note that the layout of the capacitor 158 in FIG. 4A and FIG. 4B are constructed differently according to different embodiments. However, the corresponding vias are landing on the corresponding metal layers of the MIM stack, as illustrated in FIGS. 4A and 4B.

FIG. 5 is a sectional view of an IC structure 100 having a 3DIC structure, in which a first IC die 502 and a second IC die 504 are configured in a stack, bonded together with a bonding interface 306, and sealed in the same packaging. The bonding structure is similar to the bonding structure in FIG. 3, such as in an frontside to frontside bonding mode and having an hybrid bonding interface 306 to provide electrical routing. Each of the first IC die 502 and the second IC die 504 is similar to the IC structure 100 in FIG. 4A, such as MIM stacks being extended through multiple passivation layers and the RDL structure 144 includes multiple metal layers and via layers. Especially, the MIM stacks on the IC dies 502, 504 are coupled together to form a capacitor 158 through the bonding interface 306.

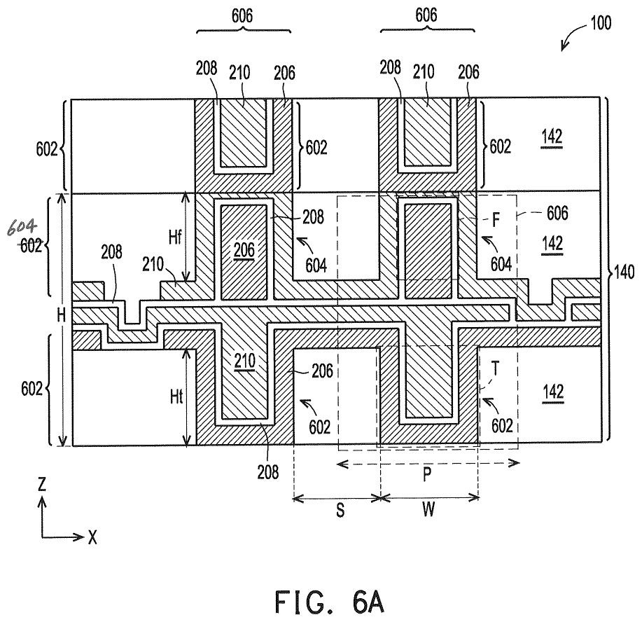

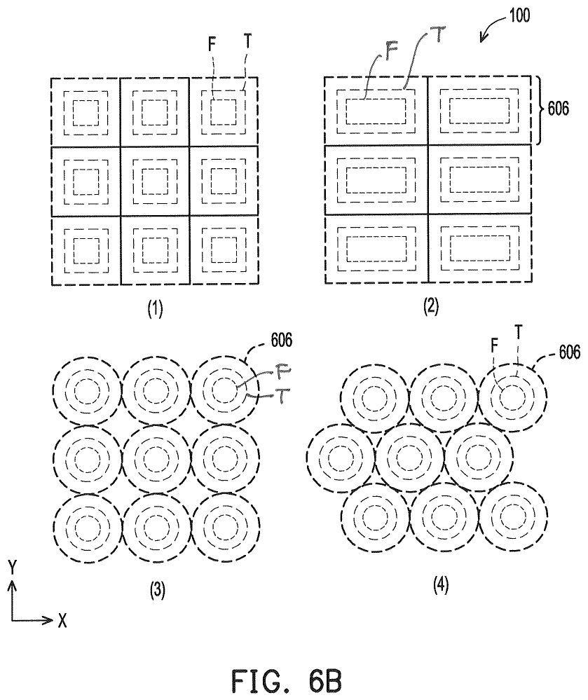

FIG. 6A is a sectional view of an IC structure 100, and FIG. 6B is a top view of the IC structure 100, in portion, constructed according to various embodiments. As illustrated in FIG. 6A, the IC structure 100 includes one or more capacitor 158 having a 3D structure and formed in trenches 602, into a pillar structure 604 or both so that the MIM stacks are inserted in one or more trenches 602, folded into one or more pillar structure 604, or a combination thereof, thereby increasing the capacitance of the capacitor 158 and reducing the packing area. A MIM stack inserted in a trench 602 is also referred to as a trench MIM stack 602; and A MIM stack formed into a pillar structure 604 is also referred to as a pillar MIM stack 604. As illustrated in FIG. 6A, the IC structure 100 includes both trench MIM stacks 602 folded and inserted in deep trenches and pillar MIM stacks 604 folded into pillar structures. In the disclosed embodiments, the pillar MIM stacks 604 and the trench MIM stacks 602 are aligned and overlapped. The trench MIM stacks 602 and the pillar MIM stacks 604 may be connected to form different capacitors 158 or alternatively are connected into one capacitor 158. A trench MIM stack 602 and a corresponding pillar MIM stack 604 are aligned with each other and stack together to form one hybrid MIM stack in a cross configuration. A 3D MIM unit 606 includes one or more trench MIM stack 602, one or more pillar MIM stack 604, one or more hybrid MIM stack, or a combination thereof, vertically stacked, aligned or alternatively offset. In some embodiments, the 3D MIM unit 606 may include one or more trench MIM stack, one or more pillar MIM stack, on or more flat MIM stack in different configurations. A flat MIM stack is a MIM stack formed on a flat surface or a substantially flat surface. In the present embodiment illustrated in FIG. 6A, the 3D MIM unit 606 includes one hybrid MIM stack and one trench MIM stack 602 vertically stacked together. The shape of one 3D MIM unit 606 will be further described in FIG. 6B later. Various dimensions are designed with consideration of the packing density, capacitance, uniformity, and processing quality of the capacitor(s) 158. The MIM stack inserted in a deep trench 602 and the MIM stacked formed on a pillar structure 604 may have different dimensions for other advantages, such as reducing stress. Note that dimensions (including width and length) of the MIM stack associated with the trench 602 are defined in the dashed box T and dimensions (including width and length) of the MIM stack associated with the pillar structure 604 are defined in the dashed box F.

In the disclosed embodiments, the 3D MIM unit 606 has a height H, and width W. The trench 602 and the pillar structure 604 have different widths so that the trench MIM stack 602 and the pillar MIM stack 604 have the same width W according to some embodiment. The MIM stack inserted in the deep trench 602 has a height Ht and the MIM stack formed on the pillar structure 604 has a height Hf. The 3D MIM units 606 have a periodic dimension (or pitch) P, and a spacing S. In some embodiments, height H ranges between 0.4 μm and 1.6 μm; pitch P ranges between 0.2 μm and 0.8 μm; width W ranges between 0.1 μm and 0.4 μm; spacing S ranges between 0.1 μm and 0.4 μm; height Ht ranges between 0.2 μm and 0.8 μm; and height Hf ranges between 0.2 μm and 0.8 μm. The sidewalls of the MIM stack inserted in a deep trench 602 and the sidewalls of the MIM stack formed on a pillar structure 604 are vertical or have angles in certain ranges. In some embodiments, the sidewalls of the MIM stack inserted in the deep trench 602 have an angle to the plane defined by X and Y directions ranging between 75° and 90°; and the sidewalls of the MIM stack formed on the pillar structure 604 have an angle to the plane defined by X and Y directions ranging between 90° and 105°. The thickness of the metal layers 206 and 210 ranges between 200 angstroms (A^{o}) and 700 angstroms (A^{o}).

In some embodiments, the top metal layer 210 of the pillar MIM stack 604 and the bottom metal layer 206 of the overlying trench MIM stack 602 directly contact each other. In this case, they are connected to the same capacitor electrode. Furthermore, the bottom metal layer 206 of the pillar MIM stack 604 and the top metal layer 210 of the overlying trench MIM stack 602 are connected together into another capacitor electrode through other conductive features including via(s) 148 and metal line(s) 144, such as those in FIG. 4A.

In some other embodiments, the top metal layer 210 of the pillar MIM stack 604 and the bottom metal layer 206 of the overlying trench MIM stack 602 may be isolated from each other and separated by a dielectric layer, such as a portion of the passivation layer 142. In this case, the trenches in the overlying trench MIM stacks 602 are formed in the overlying passivation layer 142 with a bottom portion of the passivation layer 142 remaining in the trenches to provide proper isolation. Accordingly, the electrical connections of the various MIM stacks 602 and 604 have freedoms to be achieved through other conductive features including via(s) 148 and metal line(s) 144, such as those in FIG. 4A, depending on individual design.

As illustrated in FIG. 6B, the 3D MIM units 606 are configured in an array with various configurations and geometry, such as with a shape of square illustrated in (1), rectangle illustrated in (2), round illustrated in (3) and (4) in the top view. The configurations of the 3D MIM unit 606 may be aligned along X and Y directions or alternatively with dense packing density without alignments or aligned in a direction tilted from X and Y directions. Note that the dimensions T and F are defined above in FIG. 6A.

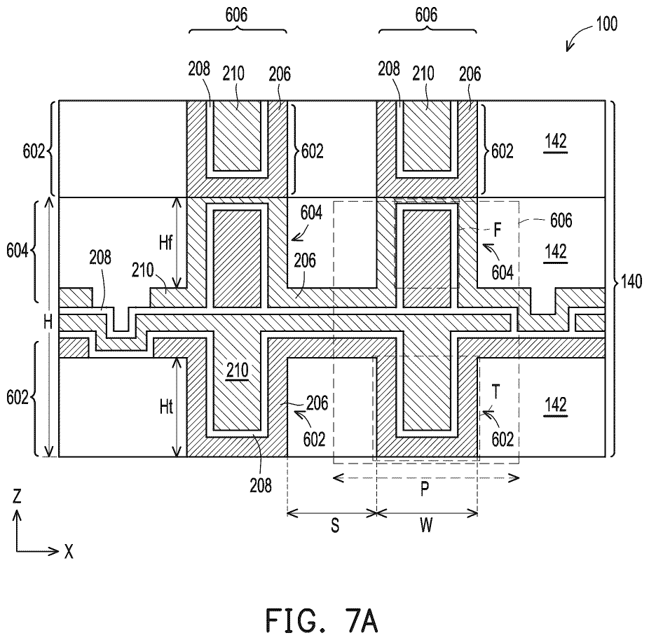

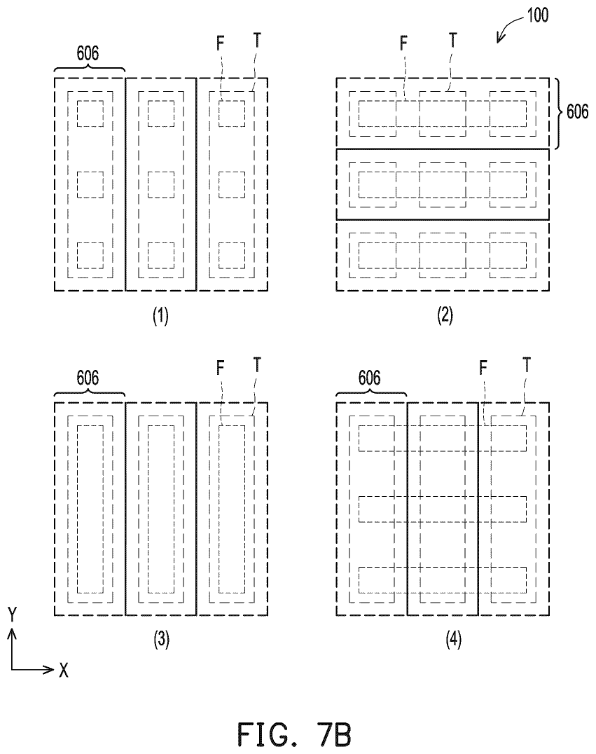

FIG. 7A is a sectional view of an IC structure 100, and FIG. 7B is a top view of the IC structure 100, in portion, constructed according to various embodiments. The IC structure 100 includes one or more capacitor 158 having 3D structure and formed in trenches 602, in a pillar structure 604 so that the MIM stacks are inserted in one or more trenches 602, folded on one or more pillar structure 604, or a combination thereof, thereby increasing the capacitance of the capacitor 158 and reducing the packing area. As illustrated in FIG. 7A, the IC structure 100 includes both MIM stacks folded and inserted in deep trenches 602 are also referred to by the numeral 602; and MIM stacks folded on pillar structures 604 are also referred to by the numeral 604 without confusion. In the disclosed embodiments, the pillar MIM stacks 604 and the trench MIM stacks 602 are aligned and overlapped. The trench MIM stacks 602 and the pillar MIM stacks 604 may form different capacitors 158 or alternatively are connected into one capacitor 158. In some embodiments, a trench MIM stack 602 and a corresponding pillar MIM stack 604 are aligned with each other and stacked together to form one 3D MIM unit 606. The shape of one 3D MIM unit 606 will be further described in FIG. 6B later. Various dimensions are designed in consideration of the packing density, capacitance, uniformity, and processing quality of the capacitor(s) 158.

In the disclosed embodiments, the 3D MIM unit 606 has a height H, and width W. The trench MIM stack 602 and the pillar MIM stack 604 have the same width W according to the disclosed embodiment. The trench MIM stack 602 has a height Ht and the pillar MIM stack 604 has a height Hf. The 3D MIM units 606 have a periodic dimension (or pitch) P, and a spacing S. In various embodiments, height H ranges between 0.4 μm and 1.6 μm; pitch P ranges between 0.2 μm and 0.8 μm; width W ranges between 0.1 μm and 0.4 μm; spacing S ranges between 0.1 μm and 0.4 μm; height Ht ranges between 0.2 μm and 0.8 μm; and height Hf ranges between 0.2 μm and 0.8 μm. The sidewalls of the trench MIM stack 602 and the sidewalls of the pillar MIM stack 604 are vertical or have angles in certain ranges. In some embodiments, the sidewalls of the trench MIM stack 602 have an angle to the plane defined by X and Y directions in a range between 75° and 90°; and the sidewalls of the pillar MIM stack 604 have an angle to the plane defined by X and Y directions in a range between 90° and 105°. The thickness of the metal layers 206 and 210 ranges between 200 angstroms (A^{o}) and 700 angstroms (A^{o}).

The trench MIM stack 602 and the pillar MIM stack 604 may have different dimensions and different shapes for other advantages, such as reducing stress. Note that dimensions (including width and length) of the MIM stack associated with the trench 602 is defined in the dashed box T and dimensions (including width and length) of the MIM stack associated with the pillar structure 604 is defined in the dashed box F. As illustrated in FIG. 7B, the 3D MIM units 606 are configured in an array with various configurations and geometry. For examples, the trench MIM stack 602 has a rectangle shape (or a slot shape) and the pillar MIM stack 604 has a square shape as illustrated in FIG. 7B (1). The trench MIM stack 602 has a square shape and the pillar MIM stack 604 has a rectangle shape as illustrated in FIG. 7B (2). The trench MIM stack 602 has a rectangle shape and the pillar MIM stack 604 has a rectangle shape but with smaller sizes as illustrated in FIG. 7B (3). The trench MIM stack 602 has a rectangle shape longitudinally oriented along Y direction and the pillar MIM stack 604 has a rectangle shape longitudinally oriented along X direction in FIG. 7B (4). Furthermore, the trench MIM stack 602 and the pillar MIM stack 604 may have different dimensions such as those illustrated in FIG. 7B (1) to (4).

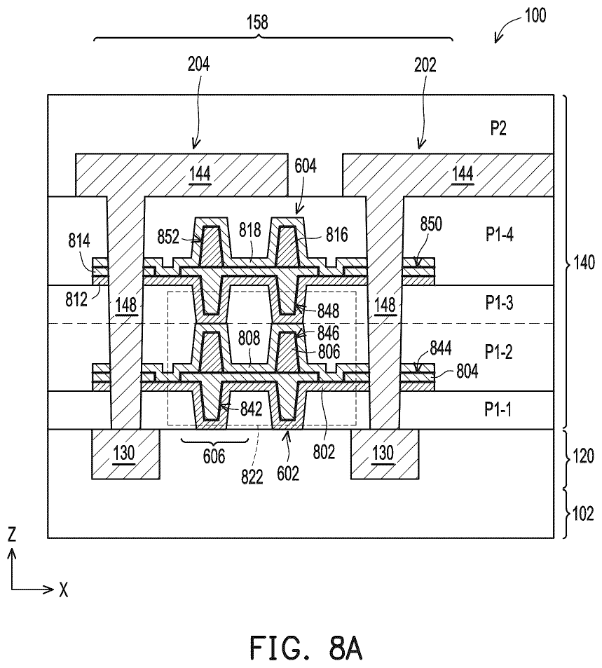

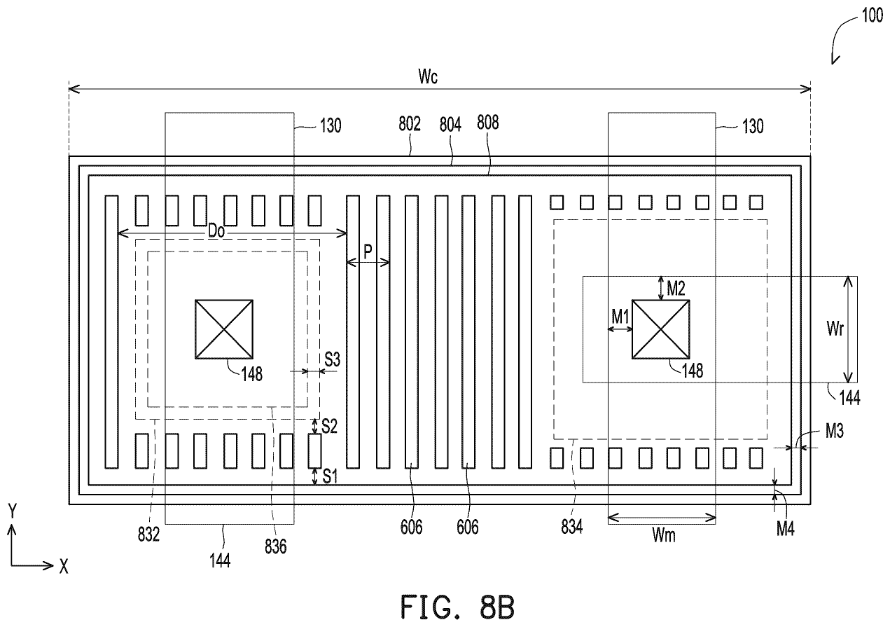

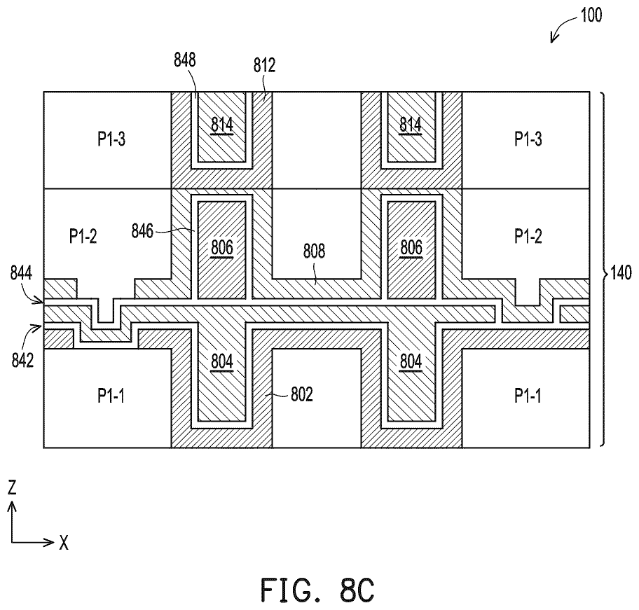

FIG. 8A is a sectional view of an IC structure 100, FIG. 8B is a top view of the IC structure 100, and FIG. 8C is a sectional view of an IC structure 100, in portion, constructed according to various embodiments. Similarly, the IC structure 100 includes a capacitor 158 in 3D structure having 3D MIM units 606. In the present embodiment illustrated in FIG. 8A, a 3D MIM unit 606 includes two hybrid MIM stacks vertically aligned and stacked together. As described above, each hybrid MIM stack includes a trench MIM stack 602 and a pillar MIM stack 604 stacked on the trench MIM stack 602. In the disclosed embodiment, the pillar MIM stack 604 and the trench MIM stack 602 in each 3D MIM unit 606 are vertically aligned and overlapped. The metal layers to form 3D MIM units 606 include metal layers 802, 804, 806, 808, 812, 814, 816, and 818 configured as illustrated in FIG. 8A and isolated from each other by dielectric layers 842, 844, 846, 848, 850 and 852. In the present embodiments, the metal layers 802 and 804, and a dielectric layer 842 sandwiched therebetween form one or more first trench MIM stack 602 as a part of the capacitor 158. The metal layers 806 and 808, and a dielectric layer 846 sandwiched therebetween form one or more first pillar MIM stack 604 as a part of the capacitor 158. Similarly, the metal layers 812 and 814 and a dielectric layer 848 sandwiched therebetween form one or more second trench MIM stack 602; and the metal layers 816 and 818 and a dielectric layer 852 sandwiched therebetween form one or more second pillar MIM stack 604. The first trench MIM stack 602 and the first pillar MIM stack 604 are aligned and stacked, and furthermore are isolated from each other by a dielectric layer 844 with a first cross configuration. The second trench MIM stack 602 and the second pillar MIM stack 604 are aligned and stacked, and furthermore are isolated from each other by a dielectric layer 850 in a second cross configuration. The first trench MIM stack 602, the first pillar MIM stack 604, the second trench MIM stack 602 and the second pillar MIM stack 604 are further vertically aligned and configured to form a 3D MIM unit 606. In FIG. 8A, multiple 3D MIM stacks 606 are configured into an array and are electrically connected to the capacitor 158 through vias 148 and metal lines 144 of the RDL structure. Especially, various metal layers are patterned to form various openings or islands so that the vias 148 are properly connected to respective metal layers. to form an interleaved capacitor 158, as further illustrated in FIG. 8B.

FIG. 8B illustrates the layout and configuration of various features of capacitor 158. Especially, those metal layers are patterned to have openings (or islands), such as openings 832, 834 and 836 so that that a certain via 148 can properly contact some metal layers while avoiding contacting other metal layers. In FIG. 8B, only the metal layers 802, 804 and 808 in the passivation layers P1-1 and P1-2 are illustrated. The metal layers 812, 814 and 818 in the passivation layers P1-3 and P1-4 may have similar dimensions, shapes and locations, such as similar openings described below. The metal layer 806 is patterned into plugs directly landing on the metal layer 804, therefore being connected to a same electrode. The metal layer 806 is not shown in FIG. 8B for simplicity. Similarly, the metal layer 816 is patterned into plugs directly landing on the metal layer 814, therefore being connected to a same electrode. In some embodiments, the metal layer 802 has an opening 832; the metal layer 808 has an opening 836; and the metal layer 804 have an opening 834. The 3D MIM unit 606 may have a rectangle shape or other suitable shape with uniform spacing and width.

In the disclosed embodiments, the IC structure 100 includes following dimensions designed for enhanced packing density, capacitance and pattern uniformity. The metal layer 802 has a width Wc, metal lines 144 of RDL structure have a width Wr, top metal layers 130 have a width Wm, and the opening 832 has a dimension Do. Spacing S1 defines a spacing between the 3D MIM unit 606 and the closest edge of the metal layers (such as the metal layer 808), spacing S2 defines a spacing between the 3D MIM unit 606 to the openings of the metal layers, and spacing S3 defines a margin between the openings. M1 defines a margin between via 148 and the metal line 144 of the RDL structure; M2 defines a margin between via 148 and the top metal line 130; M3 defines a margin between openings 832 and 836; and M4 defines a margin between the metal layers 804 and 808. 3D MIM units 606 are configured periodically with a pitch P. In some embodiments, at least a set of the metal line in the top metal layer 130 and the metal line 144 of the RDL structure may be designed with similar shape and dimensions.

In various embodiments, via 148 has dimensions 0.8 μm×0.8 μm˜2.7 μm×2.7 μm; the metal line of the RDL structure 144 has a width Wr ranging between 1.2 μm and 35 μm; Wm ranges between 1.2 μm and 20 μm; M1 or M2 equal or is greater than 0.2 μm ranges; Wc ranges between 1 μm and 300 μm; Do ranges between 2.5 μm and 5 μm; S3 ranges between 0.05 μm and 0.2 μm; each of M3 and M4 ranges between 0.05 μm and 0.2 μm; each of S1 and S2 equals or is greater than 0.1 μm; and P ranges between 0.2 μm and 0.8 μm. The rest parameters are described in FIGS. 6A˜6B and are not repeated.

A portion of the IC structure 100 in FIG. 8A in the dashed box 822 is zoomed in and is further illustrated in FIG. 8C. The IC structure 100 includes the dielectric layers 842, 844, 846 and 848 sandwiched between adjacent metal layers. For example, the dielectric layer 842 is sandwiched between the metal layers 802 and 804; the dielectric layer 844 is sandwiched between the metal layers 804 and 808 (or 806 in some portions); and the dielectric layer 846 is sandwiched between the metal layers 806 and 808; and the dielectric layer 848 is sandwiched between the metal layers 812 and 814. Those dielectric layers include one or more dielectric material, such as high k dielectric material, other suitable dielectric material, or a combination thereof, as described above. The thicknesses of those dielectric layers depend on individual capacitor in each application. The metal layers include any suitable conductive material as described above. For example, the metal layers include titanium nitride, other conductive material or a combination thereof. The thickness of those metal layers (802 through 818) ranges between 200 angstroms (A^{o}) and 700 angstroms (A^{o}).

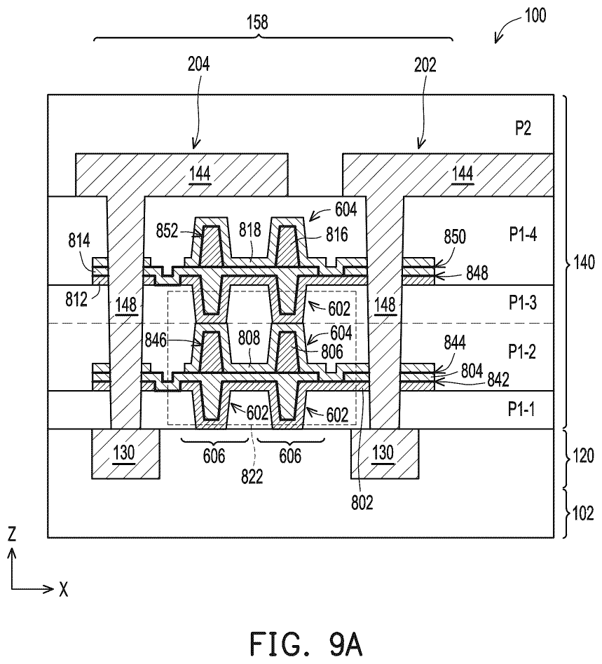

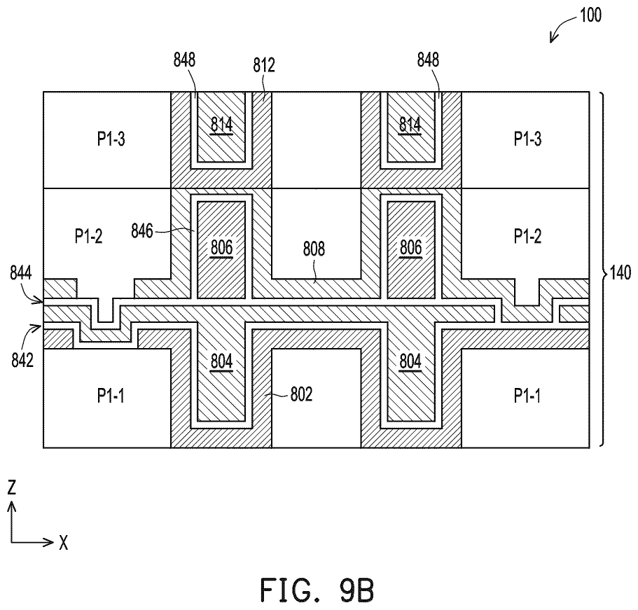

FIG. 9A is a sectional view of an IC structure 100, and FIG. 9B is a sectional view of an IC structure 100, in portion, constructed according to various embodiments. Particularly, a portion of the IC structure 100 in in the dashed box 822 of FIG. 9A is zoomed in and is further illustrated in FIG. 9B. The IC structure 100 includes a dielectric layer 842, 844, 846, 848, 850 and 852 sandwiched between adjacent metal layers. Similarly, the IC structure 100 includes a capacitor 158 in 3D structure having trench MIM stacks 602 and pillar MIM stacks 604 configured in one or more 3D MIM units 606. In the disclosed embodiment, each 3D MIM unit 606 includes two pillar MIM stacks 604 and two trench MIM stacks 602 vertically aligned and overlapped to form two hybrid MIM stacks.

The IC structure 100 in FIGS. 9A and 9B is similar to the IC structure 100 in FIGS. 8A through 8C. However, the IC structure 100 in FIGS. 9A and 9B is designed differently in 3D MIM units 606. The 3D MIM unit 606 includes an upper portion and a lower portion, each portion includes a trench MIM stack 602 and a pillar MIM stack 604. The upper portion and lower portion are vertically distanced and electrically isolated from each other (such as by portion of the passivation layer P1-3, thus allowing those MIM stacks with more freedom to be coupled into one capacitor or separate capacitors.

Various embodiments of the IC structure 100 described above in FIGS. 6A through 9B include a capacitor 158 having a trench MIM stack 602, a pillar MIM stack, or both as a hybrid MIM stack (or 3D MIM unit) 606. The IC structure 100 having a hybrid MIM stack 606 has various advantages, such as increasing the packing density and enhanced capacitance of the corresponding capacitor 158. Furthermore, it can reduce IC die stress, warpage and deformation.

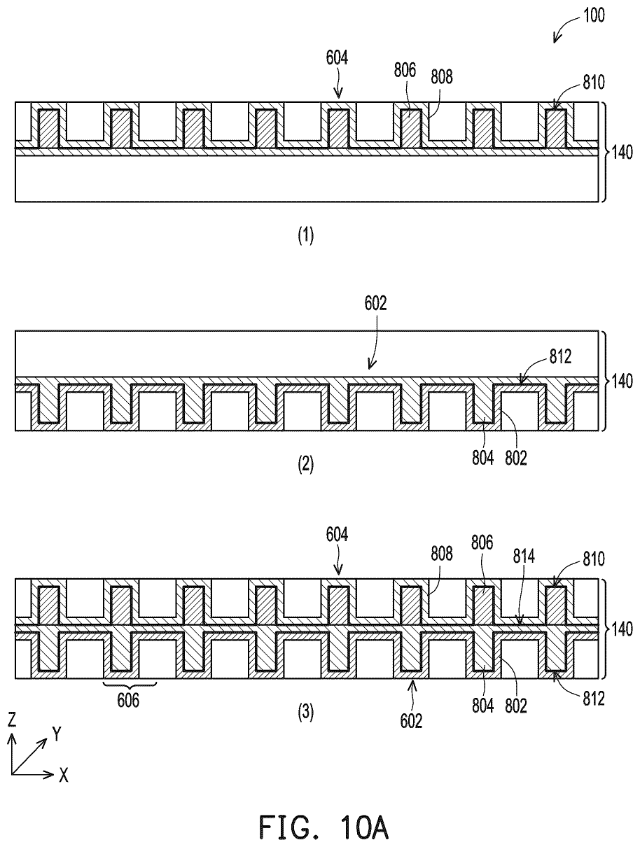

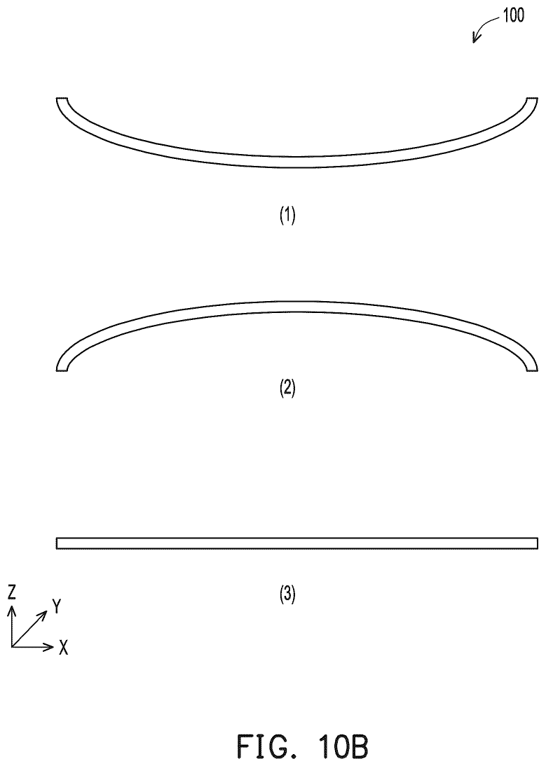

FIG. 10A illustrates sectional views of the IC structure 100, and FIG. 10B illustrates sectional views of the IC structure 100, in portion, according to various embodiments. Especially, FIG. 10A only illustrates portions of the capacitor 158 of the IC structure 100 while FIG. 10B only illustrates a IC die as a whole with the corresponding IC structure 100 formed thereon.

In the first embodiment illustrated in FIGS. 10A (1) and 10B (1), the IC structure 100 only includes pillar MIM stacks 604 but without trench MIM stacks 602, the IC die will be deformed with a warpage illustrated in FIG. 10B (1).

In the second embodiment illustrated in FIGS. 10A (2) and 10B (2), the IC structure 100 only includes trench MIM stacks 602 but without pillar MIM stacks 604, the IC die will be deformed with a warpage illustrated in FIG. 10B (2).

In the third embodiment illustrated in FIGS. 10A (3) and 10B (3), the IC structure 100 includes both trench MIM stacks 602 and pillar MIM stacks 604. In furtherance of the embodiment, trench MIM stacks 602 and pillar MIM stacks 604 are vertically aligned, matched (in term of dimensions, compositions or both) and stacked to form hybrid MIM stacks 606, thereby cancelling the stresses generated by both. Accordingly, the deformation of IC die will be eliminated or minimized, resulting in the IC die without warpage as illustrated in FIG. 10B (3).

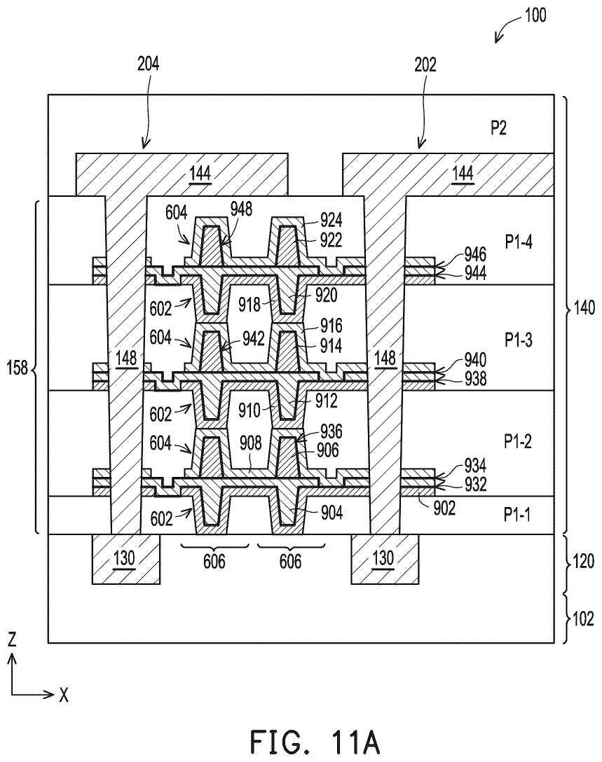

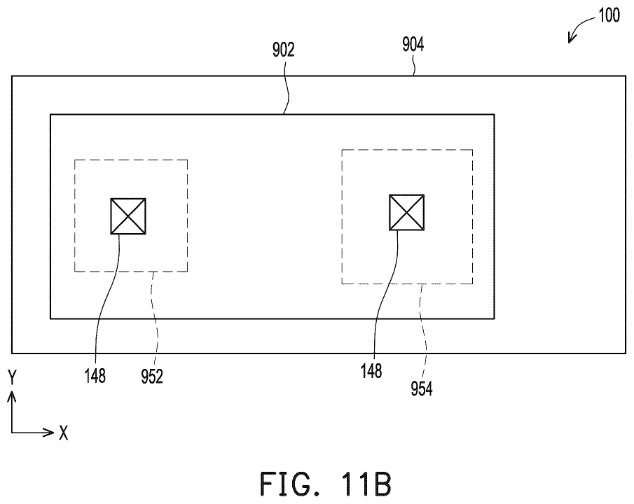

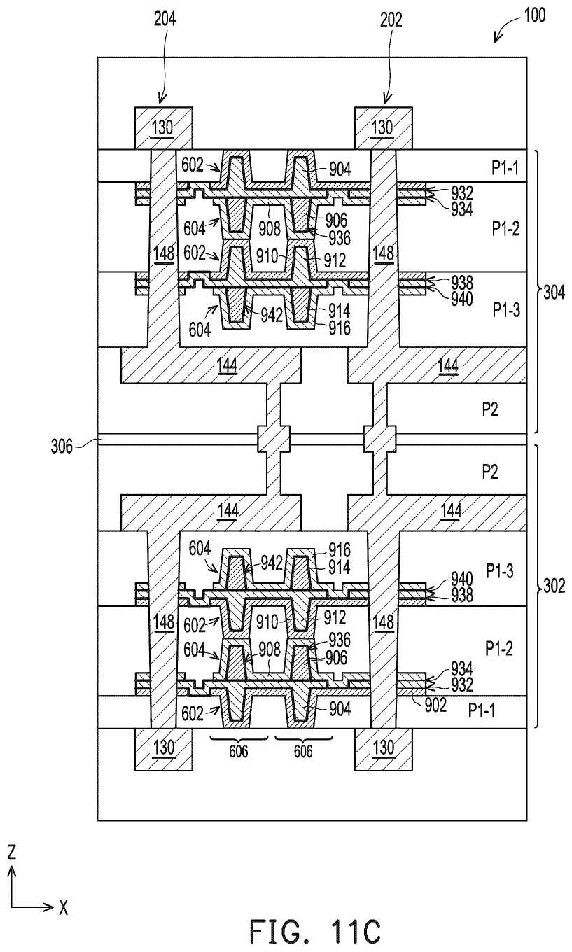

FIG. 11A is a sectional view of an IC structure 100, FIG. 11B is a top view of the IC structure 100, and FIG. 11C is a fragmentary sectional view of the IC structure 100, in portion, constructed according to various embodiments. As illustrated in FIG. 11A, the IC structure 100 includes one or more capacitor 158 having 3D MIM units 606 each having one or more trench MIM stack 602 and one or more pillar MIM stack 604 configured in a cross shape. Particularly, each 3D MIM unit 606 includes two hybrid MIM stacks vertically aligned and stacked. As described above, a hybrid MIM stack includes a trench MIM stack 602 and a pillar MIM stack 604 vertically aligned and stacked in a cross configuration. Each 3D MIM unit 606 may include multiple N (such as three) hybrid MIM vertically aligned and stacked together. It is understood that the number N can be any proper integer, such as 2, 3, 4 and etc. In the present embodiment illustrated in FIG. 11A, each 3D MIM unit 606 includes two hybrid MIM stacks vertically aligned and stacked together. In some embodiments, a hybrid MIM stack may be vertically distanced.

FIG. 11B illustrates the IC structure 100, in portion, in a top view. Particularly, only the metal layers 902 and 904 are illustrated in FIG. 11B. Especially, the metal layer 902 includes an opening 952 so that the metal via 148 on the left side is able to land on the metal layer 904 without landing on the metal layer 902. The metal layer 902 may include an island in the opening 952, such as illustrated in FIG. 11A, which will modify the distribution of the electric field in the capacitor 158 and reduce the boundary effect. The island is optional and may be eliminated. Similarly, the metal layer 904 includes an opening 954 so that the metal via 148 on the right side is able to land on the metal layer 902 without landing on the metal layer 904. The metal layer 904 may include an island in the opening 954, such as illustrated in FIG. 11A. In the disclosed embodiment, the metal layers 910 and 918 may have the patterns and the openings similar or same to those of the metal layer 902; and the metal layers 912 and 920 may have the pattern and the opening similar or same to those of the metal layer 904.

Similarly, the IC structure 100 may also include 3DIC structure, as illustrated in FIG. 11C. The IC structure 100 in FIG. 11C includes a first IC die 302 and a second IC die 304 bonded together through a bonding interface 306, thereby forming a 3DIC structure having a capacitor 158 extended in the first die 302 and the second die 304. The first IC die 302 and the second IC die 304 are bonded in a proper mode, such as frontside to frontside bonding. The bonding interface 306 may adopt any suitable bonding structure, such as hybrid bonding structure, similar to those described in FIG. 3. Capacitor structure in the first IC die 302 and capacitor structure in the second IC die 304 are similar to capacitor 158 in FIG. 11A. However, those capacitor structure are electrically connected and integrated together through the conductive traces of the bonding interface 306. In the disclosed embodiment, capacitor structure of the first IC die 302 and the capacitor structure of the second IC die 304 are integrated into a single capacitor (still be referred to as a capacitor 158).

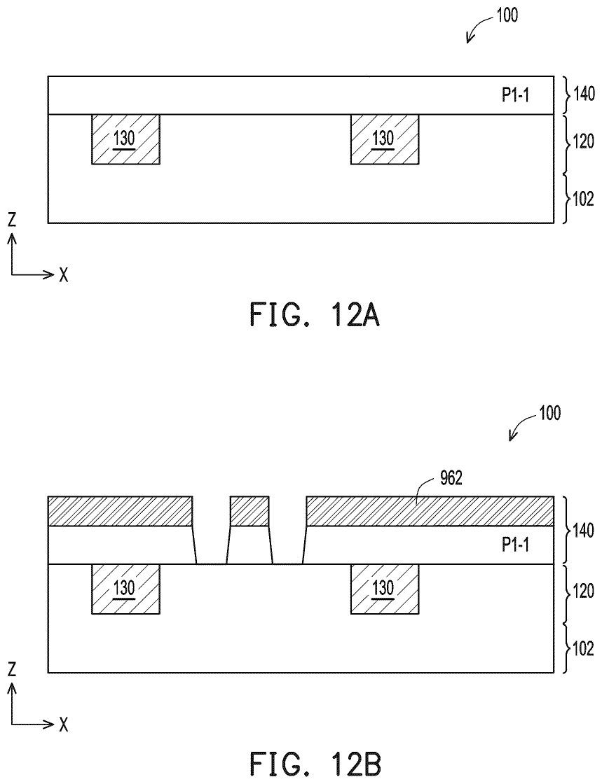

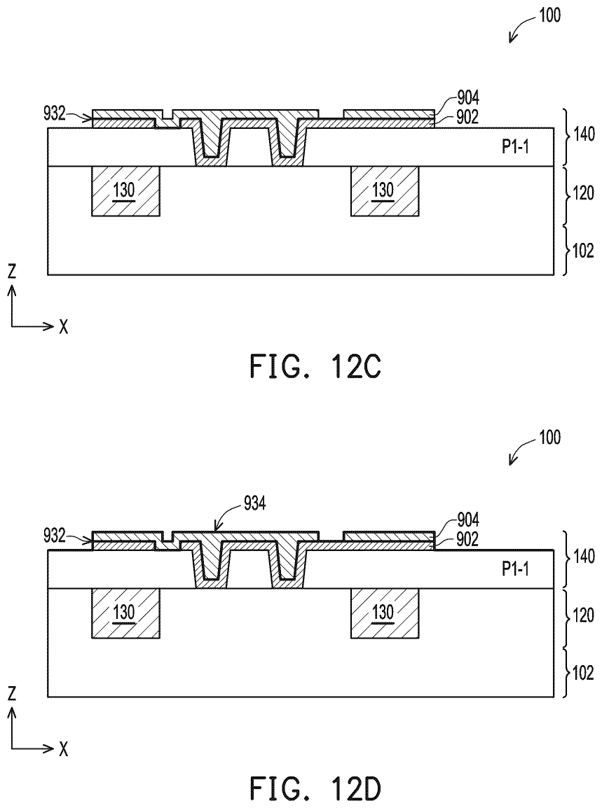

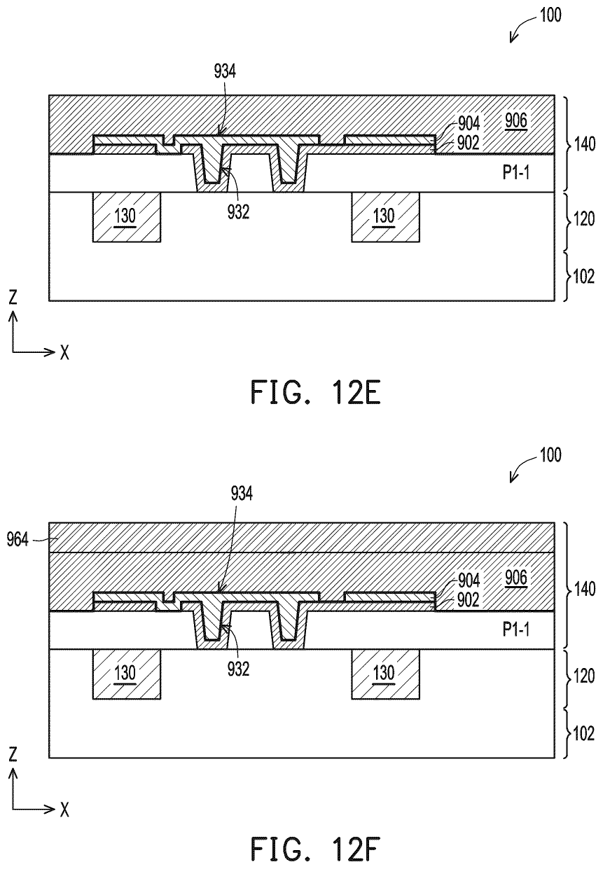

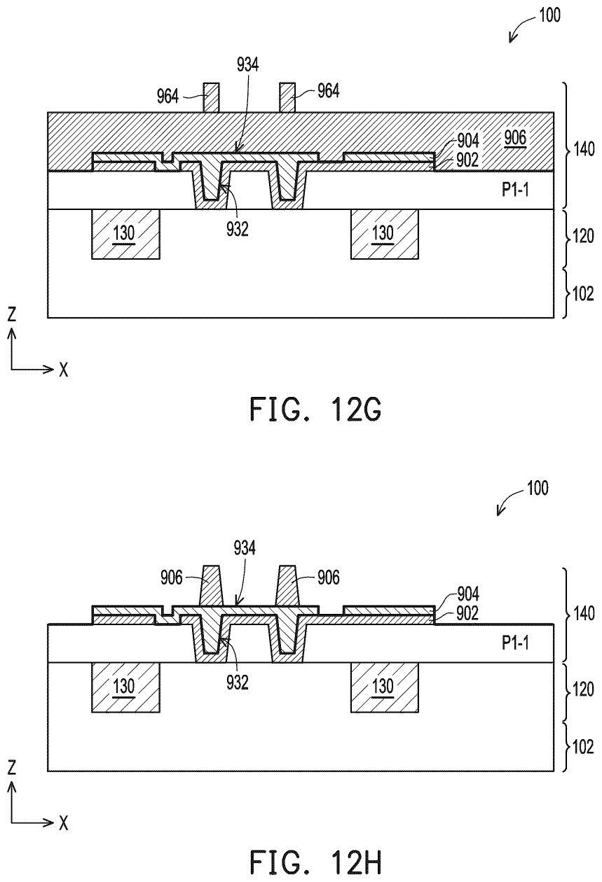

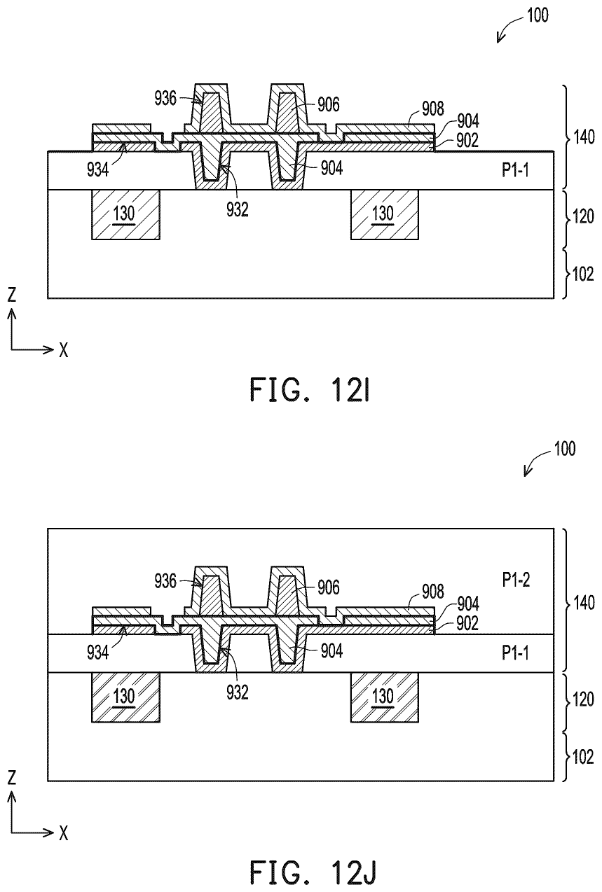

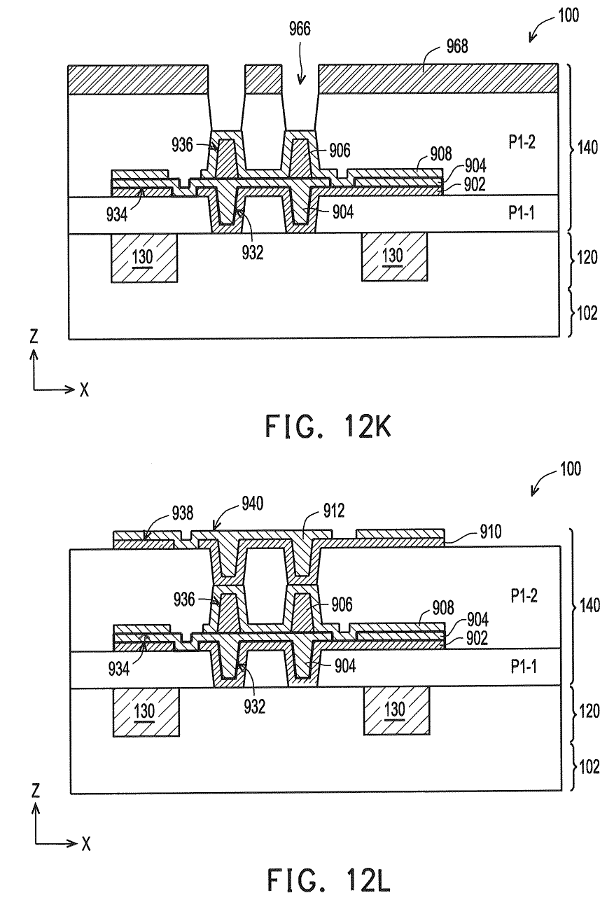

FIGS. 12A through 12L are sectional views of an IC structure 100 at various fabrication stages, in portion, constructed according to some embodiments. The IC structure 100 and the method making the same are collectively described through FIGS. 12A˜12L.

In FIG. 12A, an IC structure (or workpiece) 100 is provided. The IC structure 100 includes a substrate 102 and an interconnect structure 120. The substrate 102, devices formed thereon, and the interconnect structure 120 are described in FIGS. 1A and 1B. The descriptions are not repeated here for simplicity. For example, the interconnect structure 120 includes top metal lines 130. In FIG. 12A, a first passivation sublayer P1-1 is formed on workpiece 100. The first passivation sublayer P1-1 include silicon nitride with a thickness ranging between 4 k A^{o} and 10 k A^{o}. The formation of the first passivation sublayer P1-1 includes deposition (such as by CVD) and chemical mechanical polishing (CMP).

In FIG. 12B, the first passivation sublayer P1-1 is patterned by a patterning procedure that further includes a lithography process to form a patterned photoresist layer 962 and an etching process to pattern the passivation sublayer P1-1 using the patterned photoresist layer 962 as an etch mask. The lithography process includes coating a photoresist layer 962, exposure and development to form a patterned photoresist layer 962, and may further include various baking processes and removing the photoresist layer 962 after etching by wet stripping or plasma ashing. The etching process may include wet etch, dry etch or a combination thereof.

In FIG. 12C, a MIM stack is deposited and patterned. For example, a bottom metal layer 902 is deposited and patterned. A dielectric layer 932 is deposited and may be patterned. A top metal layer 904 is deposited and patterned, thereby forming one or more trench MIM stack 602. The bottom and top metal layers 902, 904 may include any suitable conductive material such as titanium nitride, tantalum, tantalum nitride, titanium, other suitable metal or a combination thereof. The dielectric layer 932 may include any suitable dielectric material such as a high k dielectric material. A high k dielectric material includes SiNx; Ta₂O₅, Al₂O₃, ZrO₂, and HfO₂, HfAlO, ZrAlO, or a combination thereof. The metal layers 802, 804 may be deposited by any suitable method, such as atomic layer deposition (ALD), physical vapor deposition (PVD), other suitable methods or a combination thereof. The dielectric layer 932 may be deposited by chemical vapor deposition (CVD), ALD, other suitable methods, or a combination thereof. Each of the metal layers 902 and 904 may have a thickness ranging between 200 A^{o} and 700 A^{o}. The dielectric layer 932 may have a thickness ranging between 40 A^{o} and 80 A^{o}.

In FIG. 12D, another dielectric layer 934 is deposited over by a suitable method such as CVD. The dielectric layer may have a thickness ranging between 40 A^{o} and 80 A^{o}.

In FIGS. 12E˜12H, another metal layer 906 is deposited and patterned. The metal layer 906 may have a thickness ranging between 100 A^{o} and 200 A^{o}. The metal layer 906 is deposited as illustrated in FIG. 12E; a photoresist layer 964 is coated as illustrated in FIG. 12F; the photoresist layer 964 is patterned by exposure and developing as illustrated in FIG. 12G; and the metal layer 906 is patterned by etching using the patterned photoresist layer 964 as an etch mask, as illustrated in FIG. 12H.

In FIG. 12I, another dielectric layer 936 (similar to the dielectric layers 932 and 934) is further deposited over metal layer 906, and another metal layer 908 is deposited and patterned, thereby forming a pillar MIM stack 604. The metal layer 908 may have a thickness ranging between 100 A^{o} and 700 A^{o}.

In FIG. 12J, a second passivation sublayer P1-2 is deposited and planarized by CMP. The second passivation sublayer P1-2 may have a thickness ranging between 4 k A^{o} and 10 k A^{o}.

In FIG. 12K, the second passivation sublayer P1-2 is patterned to form trenches 966 for trench MIM stacks 602 by a patterning procedure that further includes a lithography process and an etching process. The lithography process includes coating a photoresist layer 968, exposure and development, and may further include various baking processes and removing the photoresist after etching by wet stripping or plasma ashing. The etching process may include wet etch, dry etch or a combination thereof.

In FIG. 12L, a MIM stack is deposited and patterned. For example, a bottom metal layer 946 is deposited and patterned, thereby forming a trench MIM stack 602. A dielectric layer is deposited and may be patterned. The dielectric layer is not shown for simplicity. A top metal layer 948 is deposited and patterned, thereby forming a trench MIM stack 602, similar to that in FIG. 12C in terms of formation and composition.

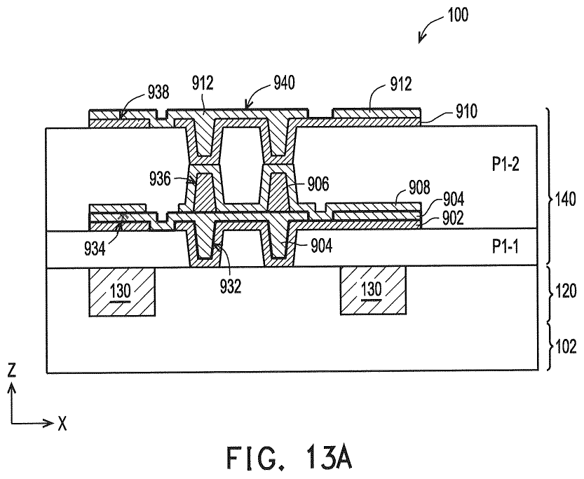

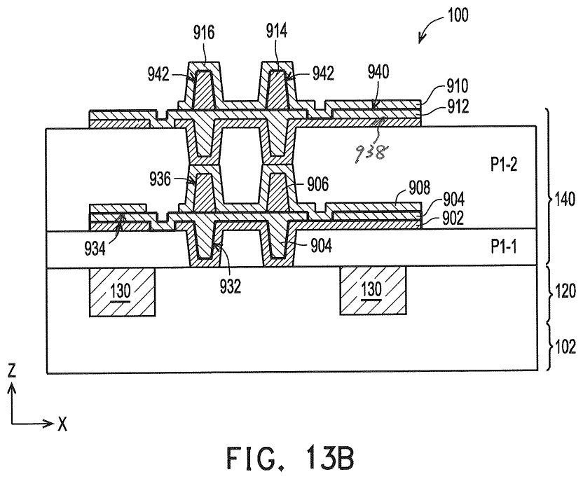

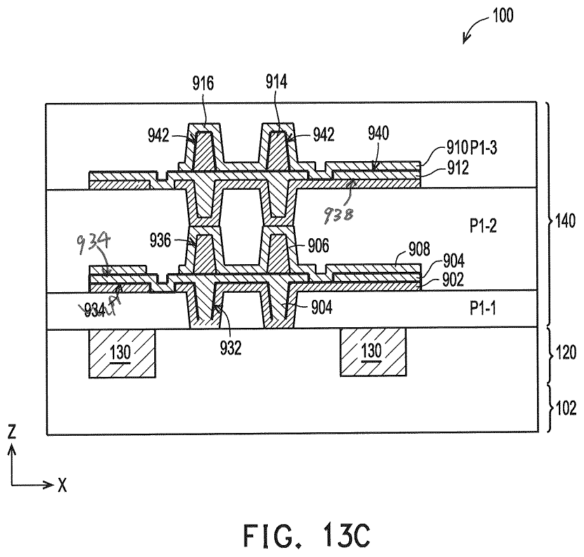

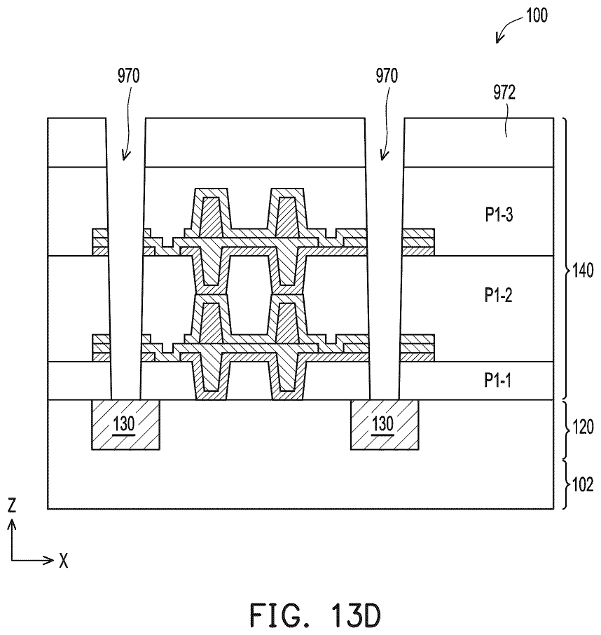

FIG. 13A is similar to FIG. 12L, a dielectric layer 940 is deposited. The dielectric layer 940 includes any suitable dielectric material such as a high k dielectric material. The dielectric layer 940 may have a thickness ranging between 40 A^{o} and 80 A^{o}.

In FIG. 13B, another MIM is deposited and patterned, thereby forming a pillar MIM stack 604. Particularly, a metal layer 914 is deposited and patterned to form metal pillars. Another dielectric layer 942 is further deposited over metal layer 914. Another metal layer 916 is deposited and patterned, collectively forming the pillar MIM stack 604.

In FIG. 13C, a third passivation sublayer P1-3 is deposited and planarized by CMP. In the disclosed embodiment, the third passivation sublayer P1-3 includes silicon nitride. The third passivation sublayer P1-3 may have a thickness ranging between 10 k A^{o} and 15 k A^{o}.

In FIG. 13D, workpiece 100 is patterned to form openings 970 such that the top metal features 130 are exposed within the trenches 970. In the disclosed embodiment, trenches 970 extend through the passivation sublayers P1-1, P1-2 and P1-3. The patterning procedure further includes a lithography process and an etching process. The lithography process includes coating a photoresist layer 972, exposure and development to form a patterned photoresist layer 972 and may further include various baking processes and removing the photoresist after etching by wet stripping or plasma ashing. The etching process may include wet etch, dry etch or a combination thereof. The etching process uses the patterned photoresist layer 972 as an etch mask. Trench depth ranges between 30 k A^{o} and 45 k A^{o}.

In FIG. 13E, one or more conductive material is deposited to fill in the openings 970, thereby forming vias 148 and metal lines 144 as electrodes 202 and 204 of the capacitor 158. In the disclosed embodiment, the conductive material includes metal, metal alloy, other conductive material or a combination thereof. In furtherance of embodiment, the conductive material includes copper. The formation of the metal lines 144 and vias 148 includes deposition, CMP and patterning. The deposition may include PVD, plating, other suitable method or a combination thereof. In some embodiments, the deposition includes depositing a seed layer by PVD and plating such as electro-chemical plating deposition (ECP) on the seed layer. Thereafter, a second passivation layer P2 is deposited and planarized by CMP. In some embodiments, the second passivation layer P2 includes silicon nitride. In some other embodiments, the second passivation layer P2 includes silicon nitride and USG. The above method may be used to form various IC structure 100, such as the IC structure 100 in FIG. 11A according to some embodiments.

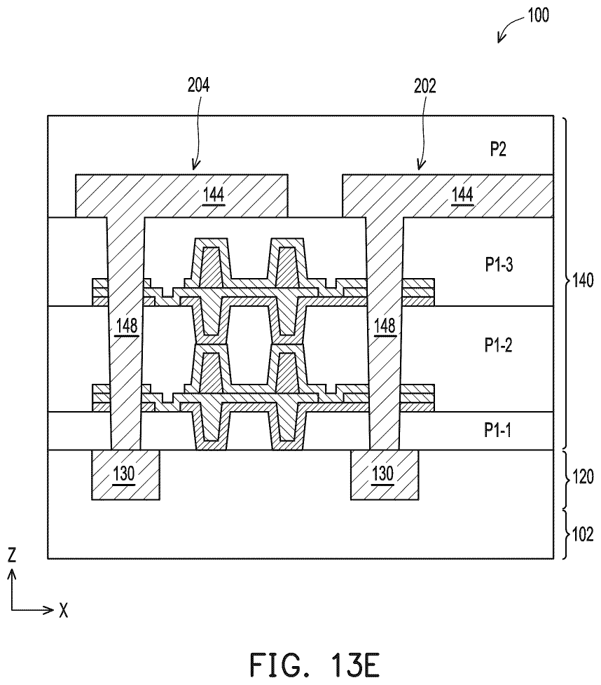

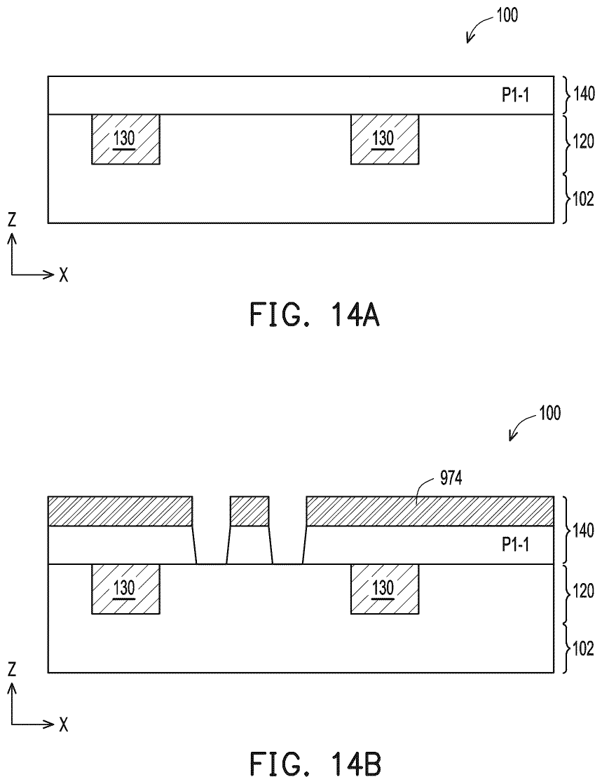

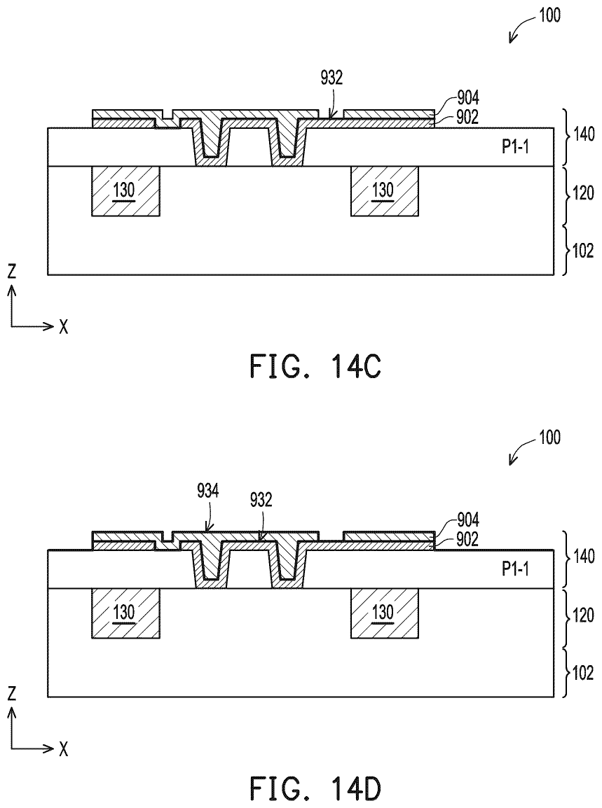

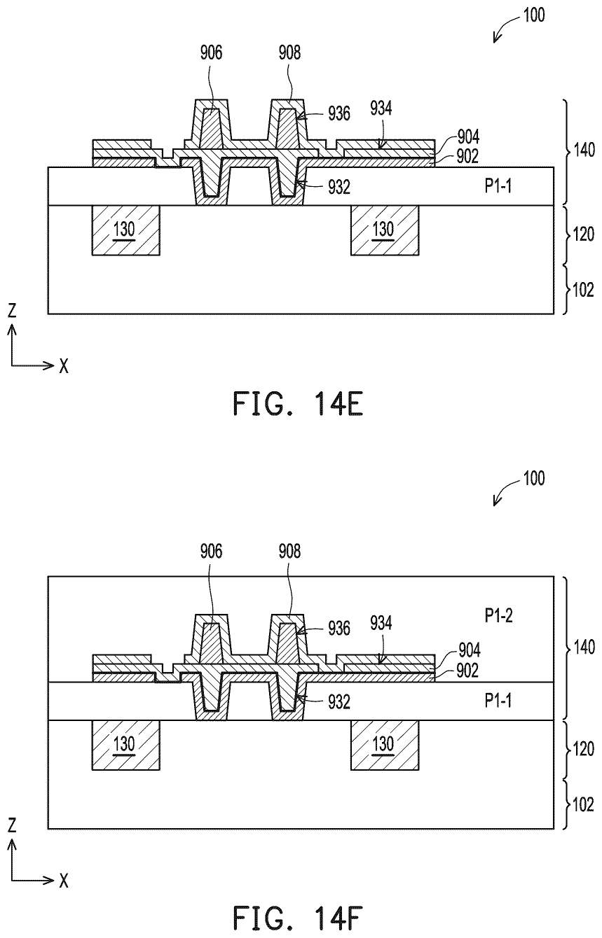

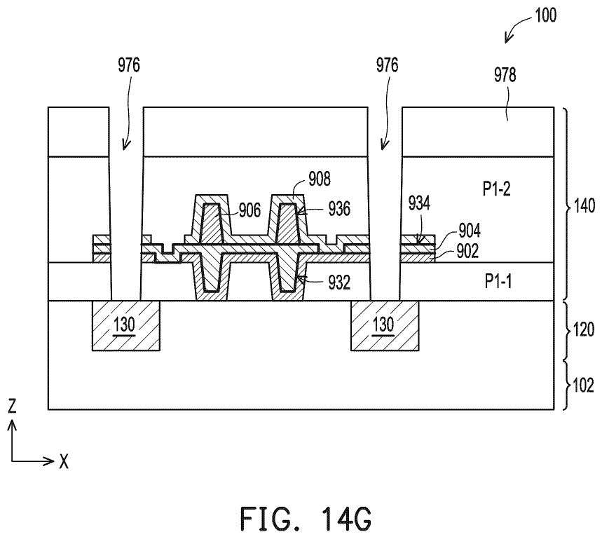

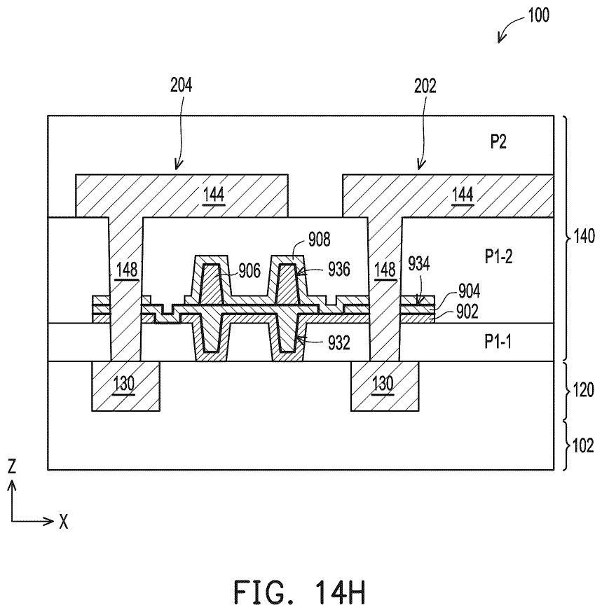

FIGS. 14A through 14H are sectional views of an IC structure 100 at various fabrication stages, in portion, constructed according to some embodiments. The IC structure 100 and the method making the same are collectively described through FIGS. 14A˜14H. FIGS. 14A through 14J are similar to those described in FIGS. 12A through 12J. Similar descriptions are not repeated here for simplicity.

In FIG. 14A, an IC structure (or workpiece) 100 is provided. The IC structure 100 includes a substrate 102 and an interconnect structure 120. The substrate 102, devices formed thereon, and the interconnect structure 120 are described in FIGS. 1A and 1B. The descriptions are not repeated here for simplicity. For example, the interconnect structure 120 includes top metal lines 130. In FIG. 14A, a first passivation sublayer P1-1 is formed on workpiece 100. The first passivation sublayer P1-1 include silicon nitride with a thickness ranging between 4 k A^{o} and 10 k A^{o}. The formation of the first passivation sublayer P1-1 includes deposition (such as by CVD) and CMP.

In FIG. 14B, the first passivation sublayer P1-1 is patterned by a patterning procedure that further includes a lithography process and an etching process. The lithography process includes coating a photoresist layer 974, exposure and development, and may further include various baking processes and removing the photoresist after etching by wet stripping or plasma ashing. The etching process may include wet etch, dry etch or a combination thereof.

In FIG. 14C, a MIM stack is deposited and patterned. For example, a bottom metal layer 902 is deposited and patterned. A dielectric layer 932 is deposited and may be patterned. A top metal layer 904 is deposited and patterned, thereby forming a trench MIM stack 602. The bottom and top metal layers 902, 904 may include any suitable conductive material such as titanium nitride, tantalum, tantalum nitride, titanium, other suitable metal or a combination thereof. The dielectric layer may include any suitable dielectric material such as a high k dielectric material. The metal layers may be deposited by any suitable method, such as ALD, PVD, other suitable methods or a combination thereof. The dielectric layer 932 may be deposited by CVD, ALD, other suitable methods, or a combination thereof. Each of the metal layers 902 and 904 may have a thickness ranging between 200 A^{o} and 700 A^{o}. The dielectric layer may have a thickness ranging between 40 A^{o} and 80 A^{o}.

In FIG. 14D, another dielectric layer 934 is deposited over by a suitable method such as CVD. The dielectric layer 934 may have a thickness ranging between 40 A^{o} and 80 A^{o}.

In FIG. 14E, another MIM stack is deposited and patterned, thereby forming a pillar MIM stack 604. Particularly, a metal layer 906 is deposited and patterned to form metal pillars. Another dielectric layer 936 is deposited on the metal layer 906. Another metal layer 908 is deposited and patterned, collectively forming a pillar MIM stack 604.

In FIG. 14F, a second passivation sublayer P1-2 is deposited and planarized by CMP. The second passivation sublayer P1-2 may have a thickness ranging between 4 k A^{o} and 10 k A^{o}.

In FIG. 14G, workpiece 100 is patterned to form openings 976 such that the top metal features 130 are exposed within the trenches 976. In the disclosed embodiment, trenches 976 extend through the passivation sublayers P1-1 and P1-2. The patterning procedure further includes a lithography process and an etching process. The lithography process includes coating a photoresist layer 978, exposure and development to form a patterned photoresist layer 978 and may further include various baking processes and removing the photoresist after etching by wet stripping or plasma ashing. The etching process may include wet etch, dry etch or a combination thereof. The etching process uses the patterned photoresist layer 978 as an etch mask.

In FIG. 14H, one or more conductive material is deposited to fill in the openings 954, thereby forming vias 958 and metal lines 960 as electrodes 202 and 204 of the capacitor 158. In the disclosed embodiment, the conductive material includes metal, metal alloy, other conductive material or a combination thereof. In furtherance of embodiment, the conductive material includes copper. The formation of the metal lines 960 and vias 958 includes deposition, CMP and patterning. The deposition may include PVD, plating, other suitable method or a combination thereof. In some embodiments, the deposition includes depositing a seed layer by PVD and plating such as electro-chemical plating deposition (ECP) on the seed layer. Thereafter, a second passivation layer P2 is deposited and planarized by CMP. In some embodiments, the second passivation layer P2 includes silicon nitride. In some other embodiments, the second passivation layer P2 includes silicon nitride and USG. The above method may be used to form the IC structure in FIG. 8A according to some embodiments.

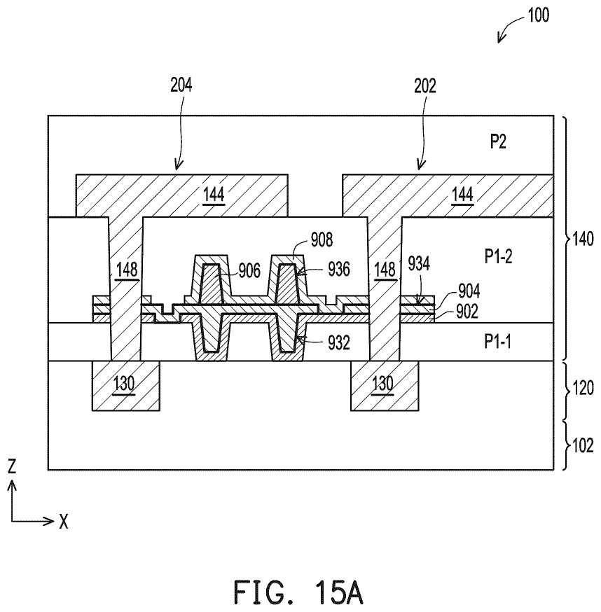

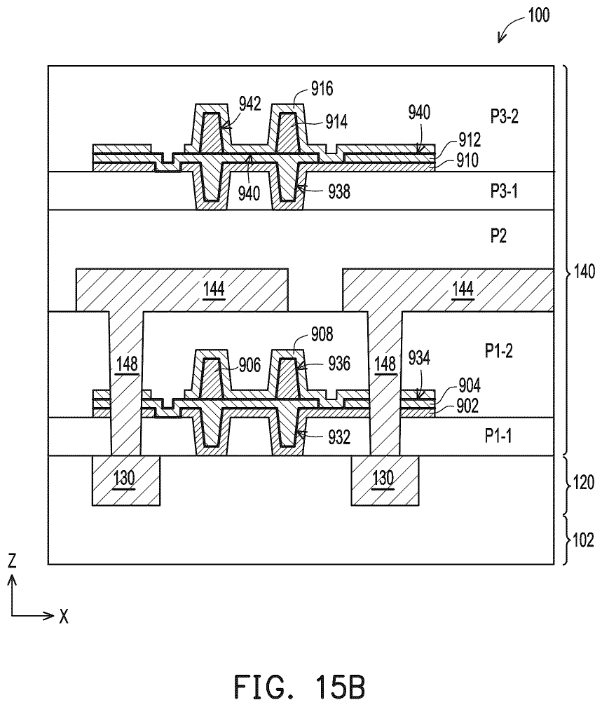

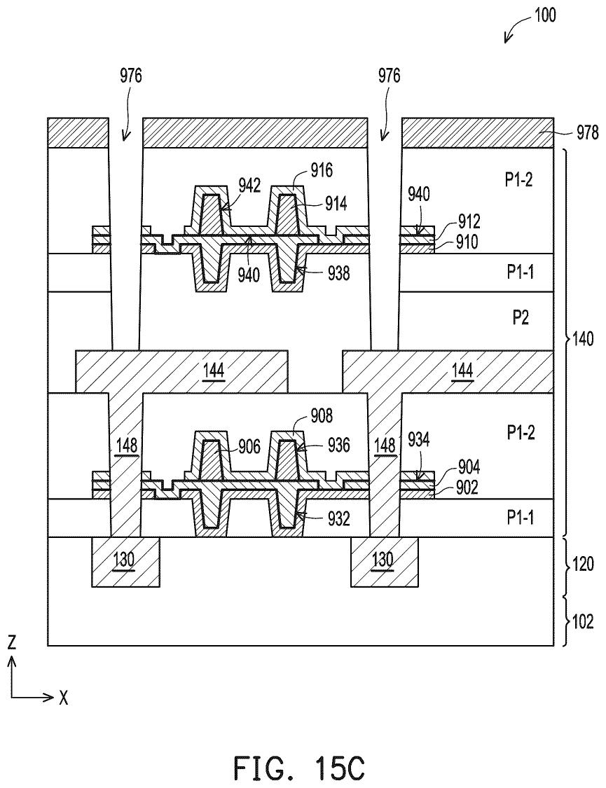

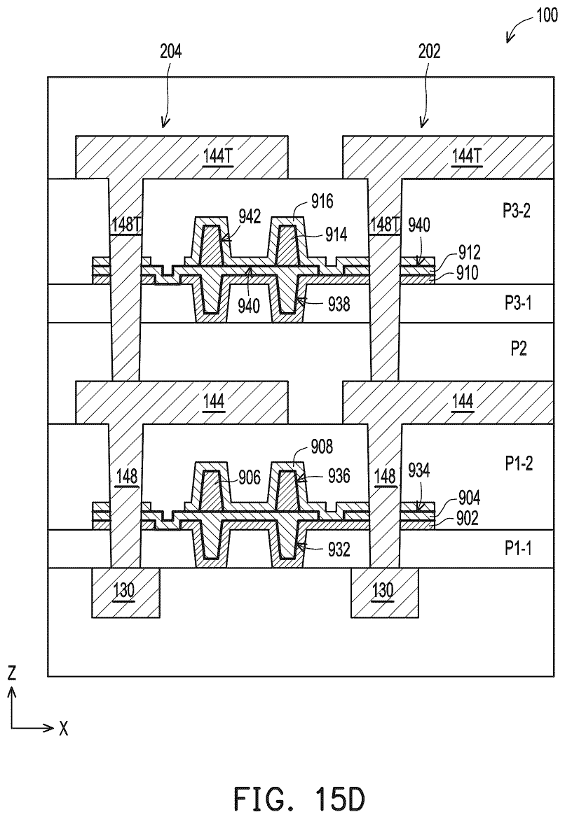

FIGS. 15A through 15D are sectional views of an IC structure 100 at various fabrication stages, in portion, constructed according to some embodiments. The IC structure 100 and the method making the same are collectively described through FIGS. 15A˜15D. The IC structure 100 and the method making the same are continued from FIGS. 14A through 14H.

FIG. 15A is same as FIG. 14H. An IC structure (or workpiece) 100 is provided.

In FIG. 15B, hybrid MIM stacks 606 are formed in the third passivation layer P3 similar or same to the method described in FIGS. 14A through 14F. The third passivation layer P3 includes passivation sublayers P3-1 and P3-2. The hybrid MIM stacks 606 includes trench MIM stacks 602 and pillar MIM stacks 604 vertically aligned and stacked to form hybrid MIM stacks 606.

In FIG. 15C, workpiece 100 is patterned to form openings 976 such that the metal lines 144 are exposed within the trenches 976. In the disclosed embodiment, trenches 976 extend through the passivation sublayers P3-1 and P3-2. The patterning procedure further includes a lithography process and an etching process. The lithography process includes coating a photoresist layer 978, exposure and development to form a patterned photoresist layer 978 and may further include various baking processes and removing the photoresist after etching by wet stripping or plasma ashing. The etching process may include wet etch, dry etch or a combination thereof. The etching process uses the patterned photoresist layer 978 as an etch mask.

In FIG. 15D, one or more conductive material is deposited to fill in the openings 976, thereby forming vias 148T and metal lines 144T collectively with metal lines 144 and vias 148 as electrodes 202 and 204 of the capacitor 158. The hybrid MIM stacks 606 in the first passivation layer P1 and the hybrid MIM stacks 606 in the third passivation layer P3 are thus electrically connected to form the integrated capacitor 158. In the disclosed embodiment, the conductive material includes metal, metal alloy, other conductive material or a combination thereof. In furtherance of embodiment, the conductive material includes copper. The formation of the metal lines 144T and vias 148T includes deposition, CMP and patterning. The deposition may include PVD, plating, other suitable method or a combination thereof. In some embodiments, the deposition includes depositing a seed layer by PVD and plating such as electro-chemical plating deposition (ECP) on the seed layer. Thereafter, a second passivation layer P2 is deposited and planarized by CMP. In some embodiments, the second passivation layer P2 includes silicon nitride. In some other embodiments, the second passivation layer P2 includes silicon nitride and USG. The above method may be used to form the IC structure in FIG. 9A according to some embodiments. In this case, the vias are formed through different procedure and the top portion of the vias and the bottom portion of the vias are electrically connected but are not necessarily aligned, thus providing more freedom with different layout and configuration for various advantages, such as tuning pattern density and reducing the stress to the workpiece by the vias.

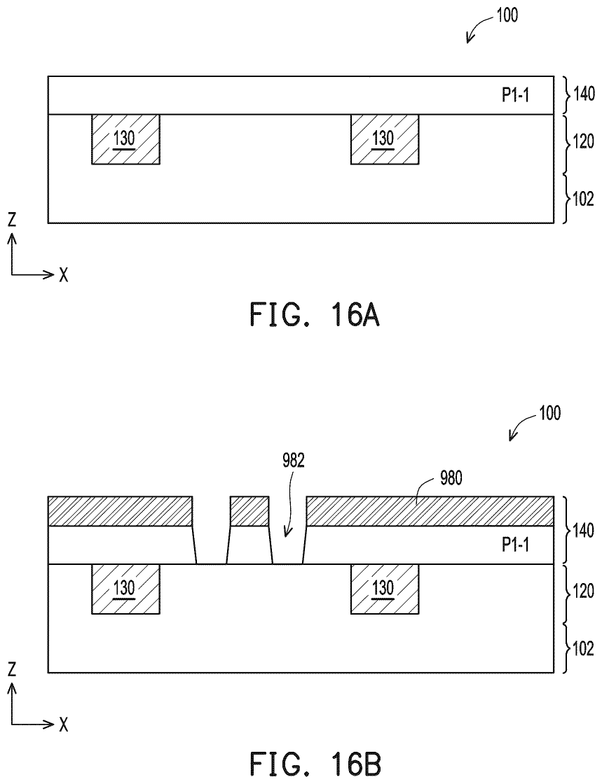

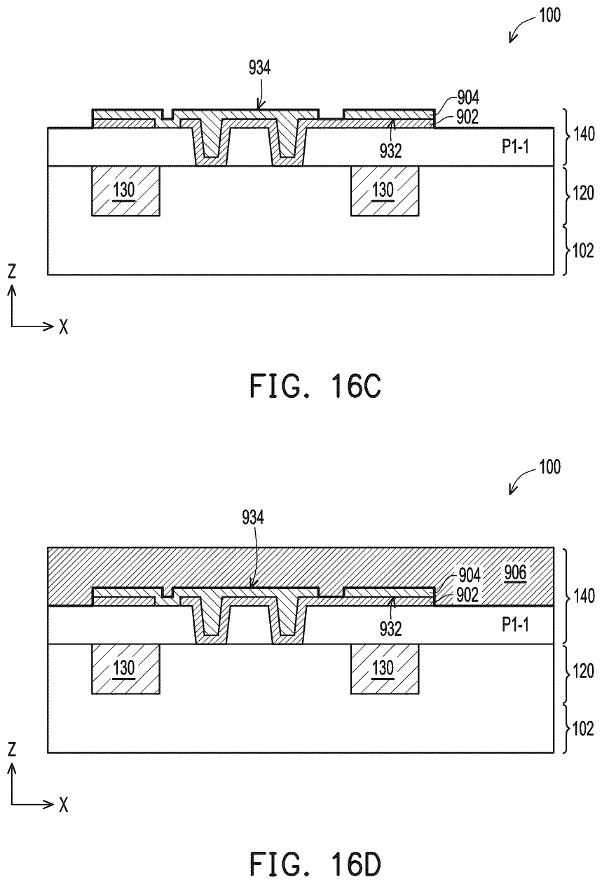

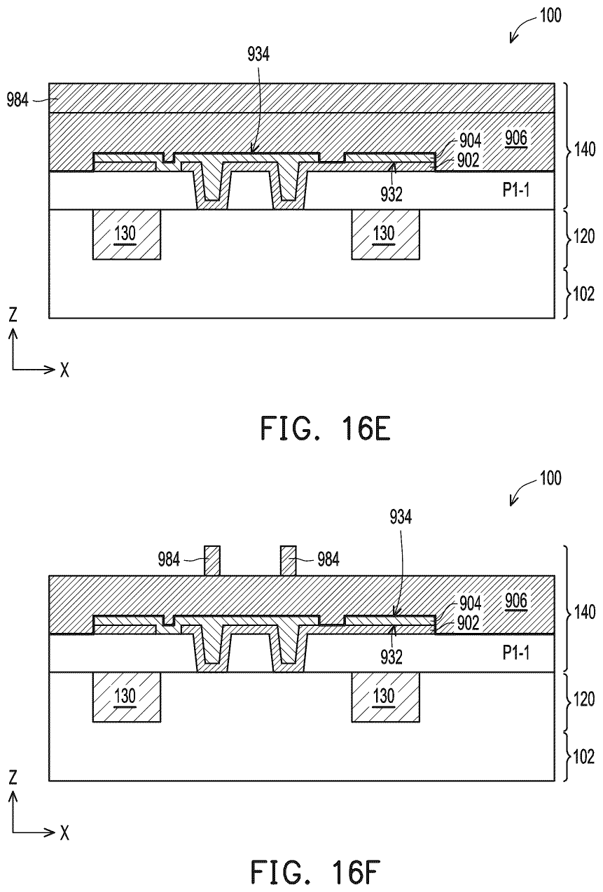

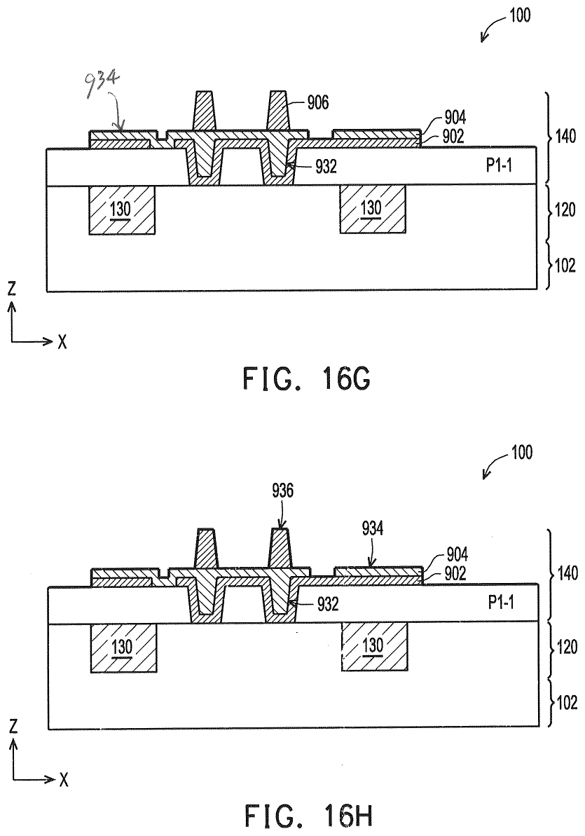

FIGS. 16A through 16H are sectional views of an IC structure 100 at various fabrication stages, in portion, constructed according to some embodiments. The IC structure 100 and the method making the same are collectively described through FIGS. 16A˜16H. The method and structure in FIGS. 16A through 16H are similar or dame to those described in FIGS. 12A through 12L. Similar descriptions are not repeated for simplicity. However, metal layer 906 is not separated from metal layer 904 and therefore are connected to metal layer 904.

In FIG. 16A, an IC structure (or workpiece) 100 is provided. The IC structure 100 includes a substrate 102 and an interconnect structure 120. For example, the interconnect structure 120 includes top metal lines 130. In FIG. 16A, a first passivation sublayer P1-1 is formed on workpiece 100. The first passivation sublayer P1-1 include silicon nitride with a thickness ranging between 4 k A^{o} and 10 k A^{o}. The formation of the first passivation sublayer P1-1 includes deposition such as by CVD and CMP.

In FIG. 16B, the first passivation sublayer P1-1 is patterned to form trenches 982 by a patterning procedure that further includes a lithography process and an etching process. The lithography process includes coating a photoresist layer 980, exposure and development, and may further include various baking processes and removing the photoresist after etching by wet stripping or plasma ashing. The etching process may include wet etch, dry etch or a combination thereof.

In FIG. 16C, a MIM stack is deposited and patterned. For example, a bottom metal layer 902 is deposited and patterned. A dielectric layer 932 is deposited and may be patterned. A top metal layer 904 is deposited and patterned, thereby forming a trench MIM stack 602. The bottom and top metal layers 902, 904 may include any suitable conductive material such as titanium nitride, tantalum, tantalum nitride, titanium, other suitable metal or a combination thereof. The dielectric layer 932 may include any suitable dielectric material such as a high k dielectric material. The metal layers may be deposited by any suitable method, such as ALD, PVD, other suitable methods or a combination thereof. The dielectric layer 932 may be deposited by CVD, ALD, other suitable methods, or a combination thereof. Each of the metal layers 902 and 904 may have a thickness ranging between 200 A^{o} and 700 A^{o}. The dielectric layer 932 may have a thickness ranging between 40 A^{o} and 80 A^{o}. In some embodiments, another dielectric layer 934 may be deposited on the trench MIM stack 602 to separate it from other MIM stacks formed in the subsequent process. The dielectric layer 934 is similar to the dielectric layer 932 in terms of composition and formation.

In FIG. 16D, another metal layer 906 is directly deposited on the metal layer 904 and patterned. Note that the dielectric layer between the metal layers 904 and 906 are eliminated so the corresponding two metal layers 904 and 906 are contacted and electrically connected. The metal layer 906 may have a thickness ranging between 100 A^{o} and 200 A^{o}. In an alternative embodiment, the dielectric layer 934 is present to provide isolation function. In this case, various metal layer are connected differently.

In FIGS. 16E-16H, metal layer 906 is patterned to form a pillar structure. A photoresist layer 984 is coated as illustrated in FIG. 16E; the photoresist layer 984 is patterned by exposure and developing as illustrated in FIG. 16F; the metal layer 906 is patterned by etching using the patterned photoresist layer 984 as an etch mask as illustrated in FIG. 16G; another dielectric layer 936 is further deposited over metal layer 906 as illustrated in FIG. 16H. The rest of the features are subsequently formed as described in FIGS. 12I˜12L and 13A˜13E.

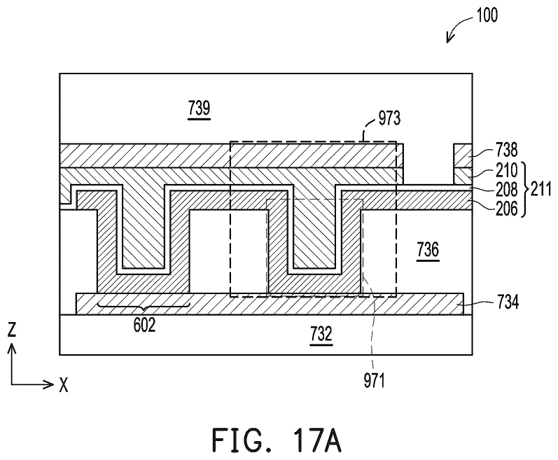

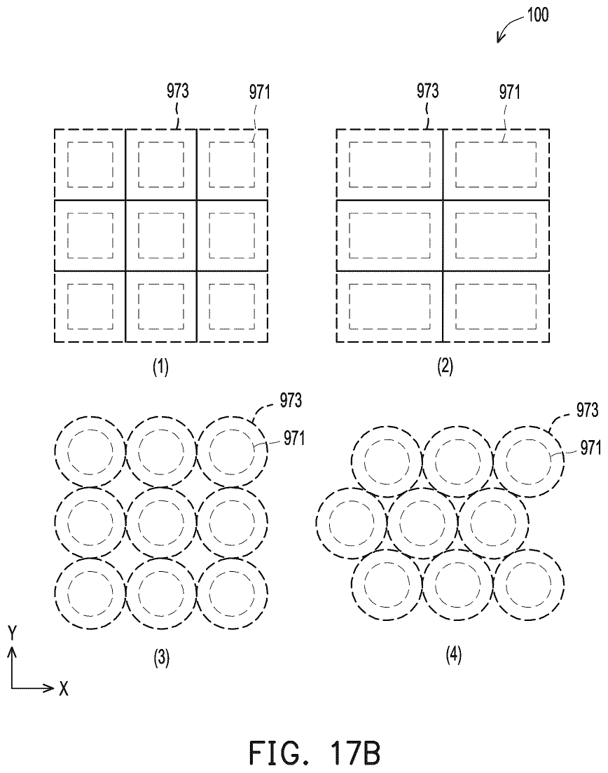

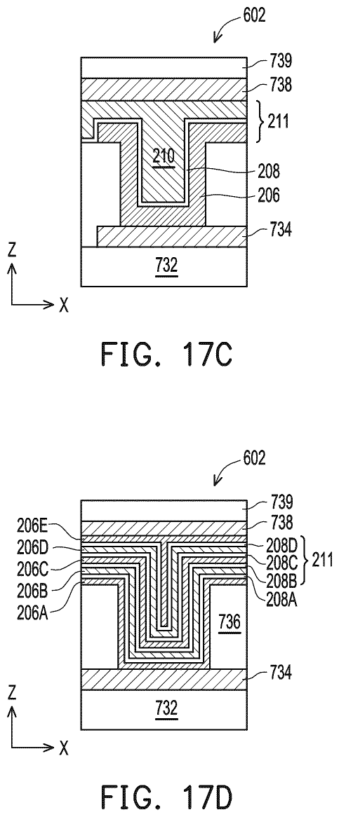

FIGS. 17A through 17D are provided to illustrate IC structure 100 according to some embodiments. FIG. 17A is a sectional view of the IC structure 100; FIG. 17B is a top view of the IC structure 100; FIG. 17C is a sectional view of the IC structure 100; and FIG. 17D is a sectional view of the IC structure 100, in portion, constructed according to various embodiments of the present disclosure. The IC structure 100 in FIGS. 17A through 17D is similar to IC structure 100 described above in various embodiments. Similar descriptions are not repeated for simplicity. However, trench MIM stacks 602 (or pillar MIM stacks 604) are different since MIM stacks includes multiple dielectric layers and multiple metal layers interleaved and properly connected to form an interleaved capacitor 158 so that the capacitance of the capacitor 158 is further increased. For example, the MIM stack 211 may include a dielectric layer 208 and two metal layers 206, 210 in a sandwiched configuration. Alternatively, the MIM stack 211 includes N dielectric layers and N+1 metal layers alternatively stacked on in an interleaved structure. N is any suitable integer, such as 2, 3, 4, or etc. In furtherance of the embodiment, various material layers of the MIM stack 211 are subsequently deposited and thereafter patterned with openings for proper connection to form electrodes of the capacitor 158.

A portion of the IC structure 100 in a dashed box 971 and a portion in a dashed box 973 are illustrated in FIG. 17B in a top view. The 3D MIM stack 211 in a top view may be square as illustrated in FIG. 17B (1); rectangle as illustrated in FIG. 17B (2); round as illustrated in FIG. 17B (3); or round but in different configurations as illustrated in FIG. 17B (4). Especially, the MIM stacks 211 are configured in a staggered structure with shift in FIG. 17B (4).

The portion of the IC structure 100 in a dashed box 973 is further illustrated in FIGS. 17C and 17D in sectional views. The MIM stack 211 may include a single dielectric layer 208 as illustrated in FIG. 17C; or include multiple dielectric layers (such as 208A through 208D) and multiple metal layers (such as metal layer 206A through 206E) configured in an interleaved structure as illustrated in FIG. 17D.

The IC structure 100 may include other material layers, such as 732, 734, 736, 738 and 739. In some embodiments, a material layer 732 is a passivation layer, a material layer 734 is a metal layer; a material layer 736 is another passivation layer; a material layer 738 is a metal layer; and a material layer 739 is another passivation layer.

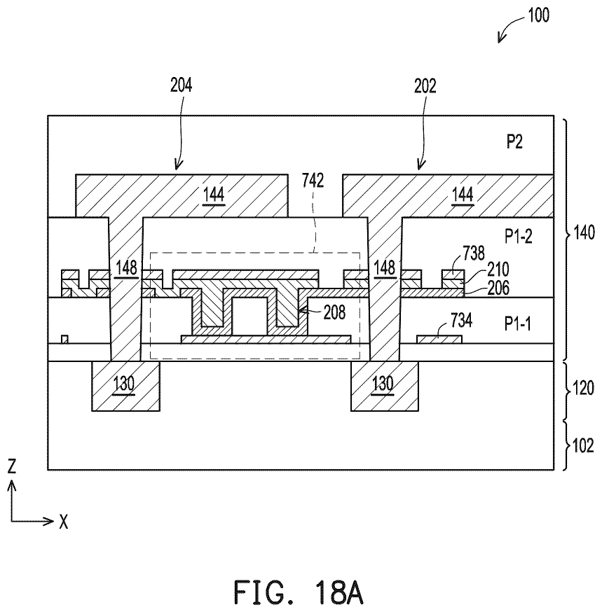

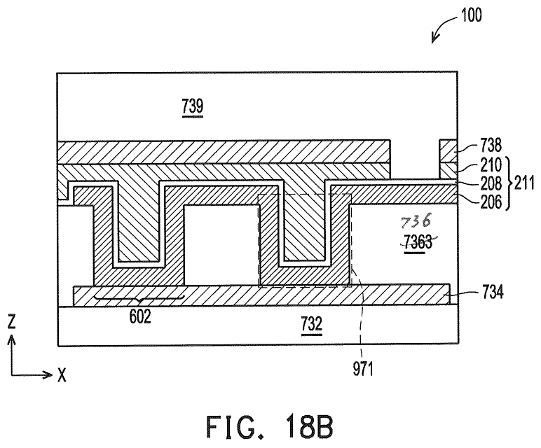

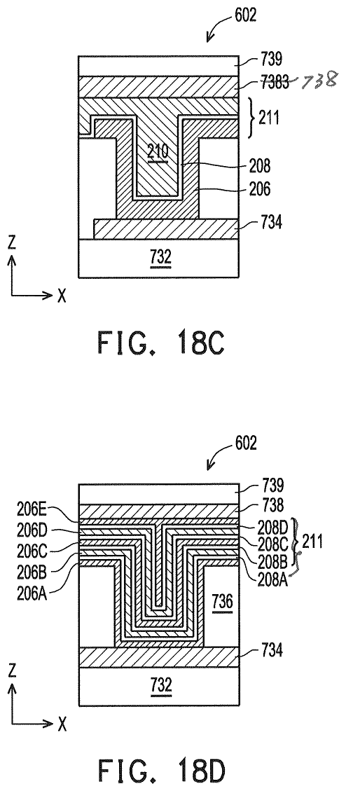

FIGS. 18A through 18D are provided to illustrate IC structure 100 according to some embodiments. FIGS. 18A through 18D are sectional views of the IC structure 100, in portion, constructed according to various embodiments of the present disclosure. The IC structure 100 in FIGS. 18A through 18D is similar to IC structure 100 described above in FIGS. 17A through 17D. Similar descriptions are not repeated for simplicity.

A portion of the IC structure 100 in a dashed box 742 of FIG. 18A is further illustrated in FIG. 18B. A portion of the IC structure 100 in a dashed box 971 of FIG. 18B is zoomed in and illustrated in FIGS. 18C and 18D in sectional views. The 3D MIM stack 211 may include a single dielectric layer 208 as illustrated in FIG. 18C; or include multiple dielectric layers (such as 208A through 208D) and multiple metal layers (such as metal layer 206A through 206E) configured in an interleaved structure as illustrated in FIG. 18D. Various dimensions are similar or same to those described In FIG. 6A. The IC structure 100 in FIG. 18A further includes vias 148 and metal lines 144 configured to connect various metal layers in the MIM stack 211 as the first electrode 202 and the second electrode 204 of the capacitor 158.

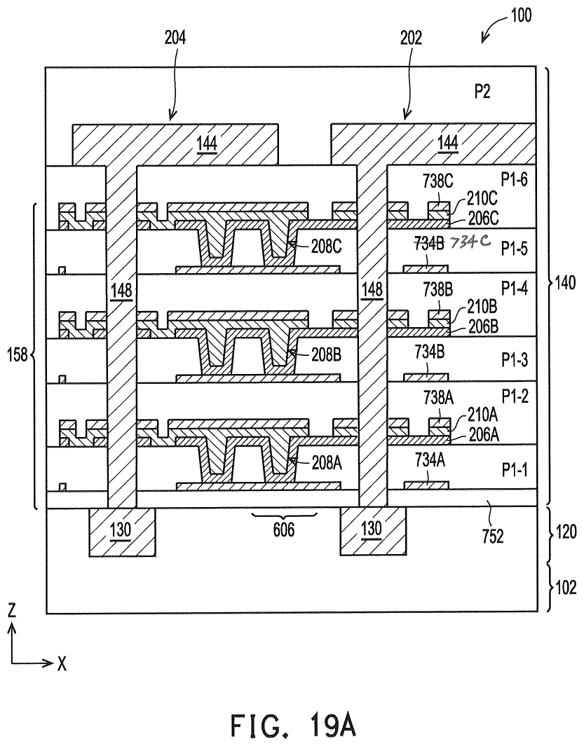

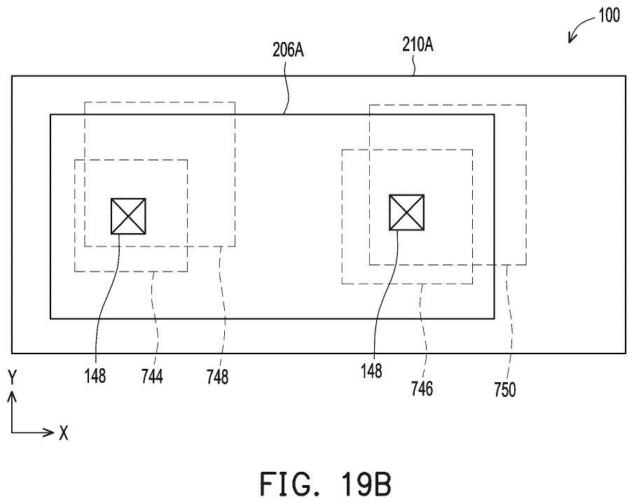

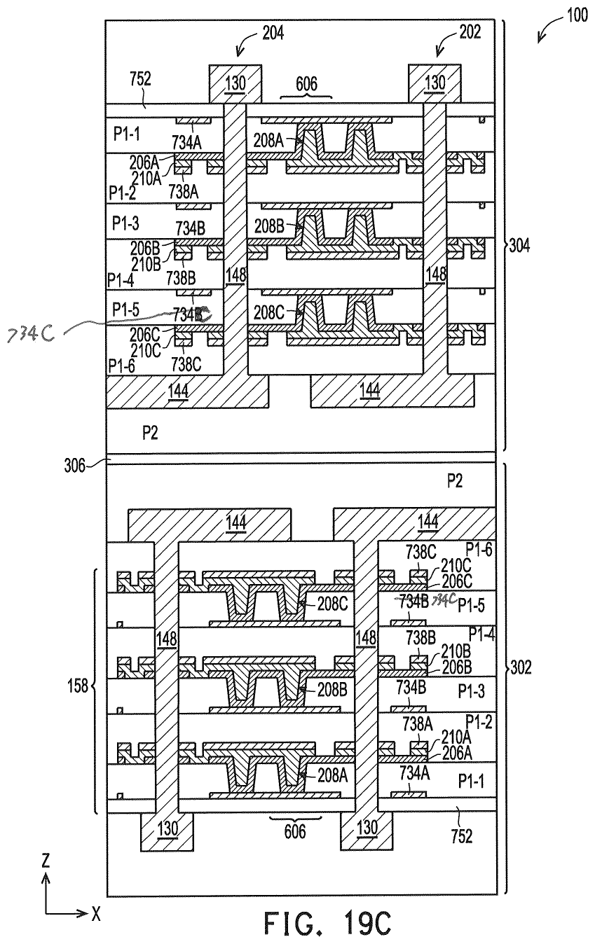

FIGS. 19A through 19C are provided to illustrate IC structure 100 according to some embodiments. FIG. 19A is a sectional view of IC structure 100; FIG. 19B is a top view of IC structure 100; and FIG. 19C is a sectional view of IC structure 100, in portion, constructed according to various embodiments of the present disclosure. The IC structure 100 in FIGS. 19A through 19C is similar to IC structure 100 described above in IC structure 100 in FIGS. 11A through 11C. Similar descriptions are not repeated for simplicity.

As illustrated in FIG. 19A, the IC structure 100 includes one or more capacitor 158 having 3D structure and formed with 3D MIM units 606 each having a trench MIM stacks 602, but no pillar MIM stack 604 is present. Especially, each 3D MIM unit 606 includes multiple N (such as three) trench MIM stacks 602 vertically aligned and stacked together. It is understood that the number N can be any proper integer, such as 2, 3, 4 and etc. In the illustrated embodiment, N equals 3. In some embodiments, trench MIM stacks 602 in each 3D MIM unit 606 may be vertically distanced. For example, the first trench MIM stacks 602 formed in the passivation sublayers P1-1, P1-2 include the bottom metal layer 206A, the dielectric layer 208A and the top metal layer 210A. the material layers 734A and 738A are further disposed underlying and overlying the first trench MIM stacks 602. In some embodiments, the material layers 734A and 738A are conductive material, such as metal, metal alloy, other suitable conductive material or a combination thereof. The conductive layers 734A and 738A are configured to improve the electric field distribution and enhance the performance of the capacitor 158. Similarly, the second trench MIM stacks 602 formed in the passivation sublayers P1-3, P1-4 include the bottom metal layer 206B, the dielectric layer 208B and the top metal layer 210B, and may further include the conductive layers 734B and 738B disposed underlying and overlying the second trench MIM stacks 602; and the third trench MIM stacks 602 formed in the passivation sublayers P1-5, P1-6 include the bottom metal layer 206C, the dielectric layer 208C and the top metal layer 210C, and may further include the conductive layers 734C and 738C disposed underlying and overlying the third trench MIM stacks 602. The dielectric material layer 752 may be further disposed on the interconnect structure 120. In an alternative embodiment, an additional dielectric material layer is interposed between the metal layers 210A and the metal layer 738A; and another dielectric material layer is interposed between the metal layers 206A and the metal layer 734A. In this case, four metal layers and three dielectric layers are configured alternatively in an interleaved structure and connected into a capacitor 158 with an increased capacitance.

FIG. 19B illustrates the metal layers 206A and 210A and the corresponding openings 744, 746, 748 and 750 in the first trench MIM stacks 602. The second and third trench MIM stacks 602 have the similar pattern and layout. In the disclosed embodiment, the metal layer 206A includes an opening 744 so that the via 148 on the left side can land on the metal layer 210A without landing on the metal layer 206A. The metal layer 206A may further include a stand-alone island formed in the opening 744. In this case, the via 148 on the left side directly lands on the island distanced from the main plate of the metal layer 206A. Similarly, the metal layer 210A includes an opening 746 so that the via 148 on the right side can land on the metal layer 206A without landing on the metal layer 210A. The metal layer 210A may further include a stand-alone island formed in the opening 746. In this case, the via 148 on the right side directly lands on the island distanced from the main plate of the metal layer 210A. The metal layers in other trench MIM stacks 602, such as the second or third trench MIM stacks 602, may have openings similar to the opening 744 and 746 or alternatively have openings shifted (such as 748 and 750) but still configured such that the corresponding vias 148 are landing within the corresponding openings.

Similarly, the IC structure 100 may also include 3DIC structure, as illustrated in FIG. 19C. The IC structure 100 in FIG. 19C includes a first IC die 302 and a second IC die 304 bonded together through a bonding interface 306, thereby forming a 3DIC structure having a capacitor 158 extended in the first die 302 and the second die 304. The first IC die 302 and the second IC die 304 are bonded in a proper mode, such as frontside to frontside bonding. The bonding interface 306 may adopt any suitable bonding structure, such as hybrid bonding structure, similar to those described in FIG. 3. Capacitor 158 in the first IC die 302 and capacitor 158 in the second IC die 304 are similar to capacitor 158 in FIG. 19A. In the disclosed embodiment, capacitor 158 of the first IC die 302 and the capacitor 158 of the second IC die 304 are integrated into a single capacitor (still be referred to as a capacitor 158).

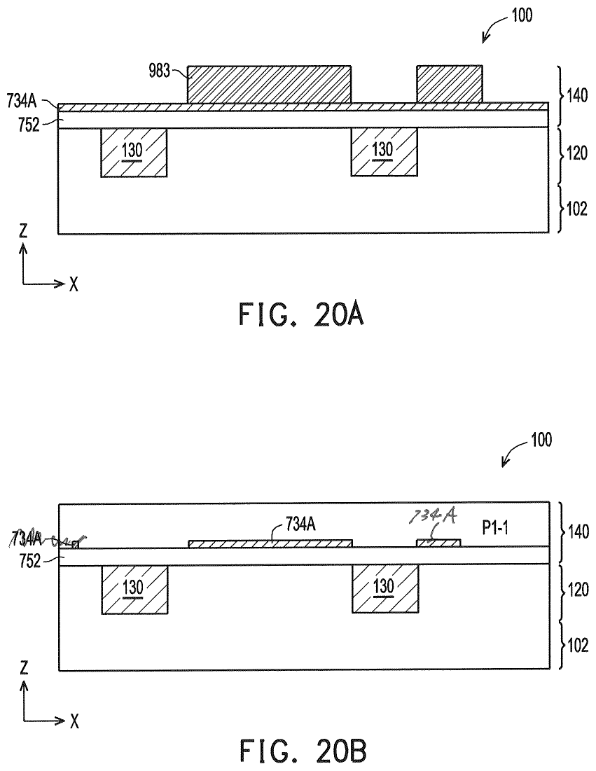

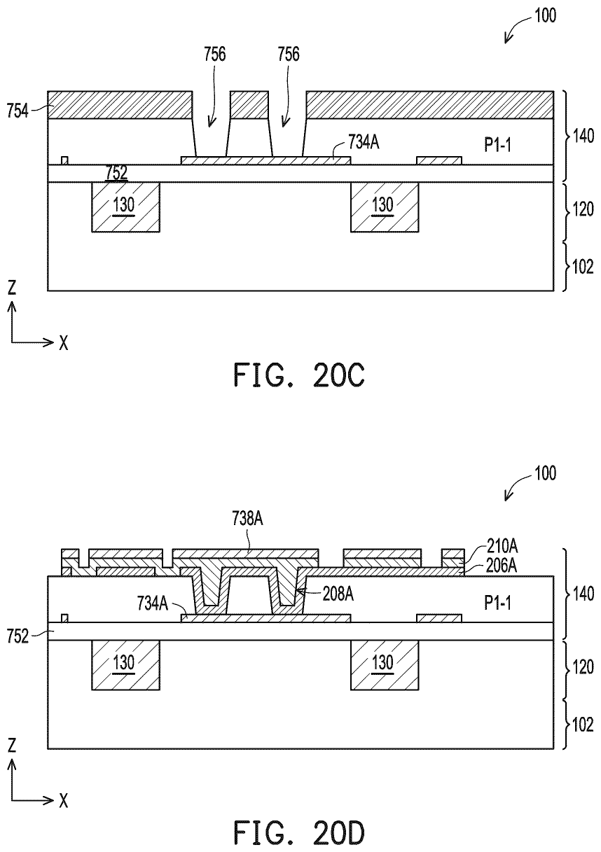

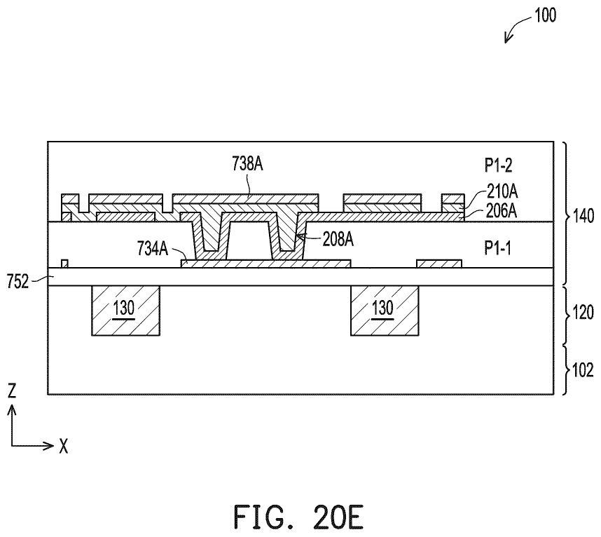

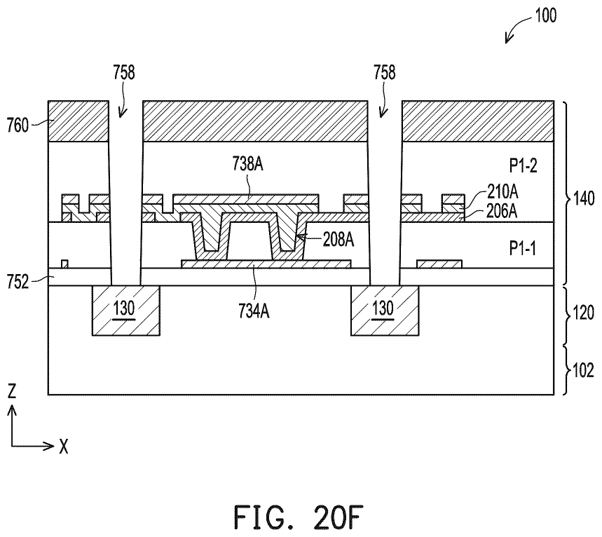

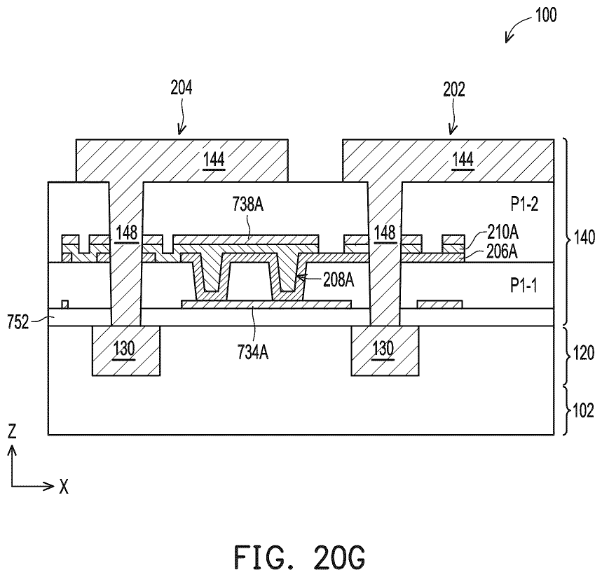

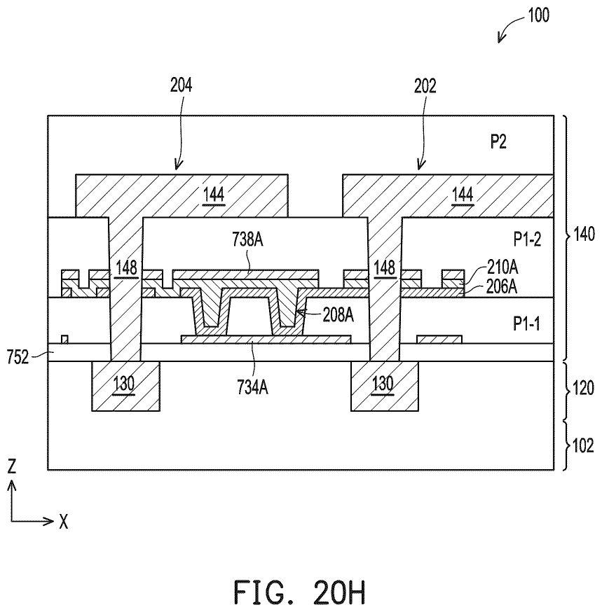

FIGS. 20A through 20L are sectional views of an IC structure 100 at various fabrication stages, in portion, constructed according to some embodiments. The IC structure 100 and the method making the same are collectively described through FIGS. 10A˜10H.

In FIG. 20A, an IC structure (or workpiece) 100 is provided. The IC structure 100 includes a substrate 102 and an interconnect structure 120. The substrate 102, devices formed thereon, and the interconnect structure 120 are described in FIGS. 1A and 1B. The descriptions are not repeated here for simplicity. For example, the interconnect structure 120 includes top metal lines 130. In FIG. 20A, a dielectric layer 752 is formed on workpiece 100. The dielectric layer 752 include silicon nitride with a thickness ranging between 1.5 k A^{o} and 4.5 k A^{o}. The formation of the dielectric layer 752 includes deposition (such as by CVD).

A metal layer 734A is further formed on the workpiece 100 by a suitable method, such as PVD. The metal layer 734A may include titanium nitride, other suitable conductive materials, or a combination of. The metal layer 734A includes a thickness ranging between 200 A^{o} and 700 A^{o}.

The metal layer 734A is further patterned. A patterned photoresist layer 983 is formed on the metal layer 734A by a lithography process. The metal layer 734A is etched through the opening of the photoresist layer 983. Thereafter, the photoresist layer 983 may be removed from the workpiece by wet stripping or plasma ashing.

In FIG. 20B, the first passivation sublayer P1-1 is formed on the patterned metal layer 734A by deposition (such as CVD) and CMP. The first passivation sublayer P1-1 includes silicon nitride, other suitable dielectric material or a combination thereof. The first passivation sublayer P1-1 includes a thickness ranging between 4 k A^{o} and 10 k A^{o}.

In FIG. 20C, the first passivation sublayer P1-1 is patterned to form trenches 756 by a patterning procedure that further includes a lithography process and an etching process. The lithography process includes coating a photoresist layer 754, exposure and development, and may further include various baking processes and removing the photoresist after etching by wet stripping or plasma ashing. The etching process may include wet etch, dry etch or a combination thereof.

In FIG. 20D, a MIM material stack is deposited and patterned. For example, a bottom metal layer 206A is deposited and patterned. A dielectric layer 208A is deposited. A top metal layer 210A is deposited and patterned, thereby forming a trench MIM stack 602. The bottom and top metal layers 206A, 210A may include any suitable conductive material such as titanium nitride, tantalum, tantalum nitride, titanium, other suitable metal or a combination thereof. The dielectric layer 208A may include any suitable dielectric material such as a high k dielectric material. The metal layers may be deposited by any suitable method, such as ALD, CVD, other suitable methods or a combination thereof. The dielectric layer 208A may be deposited by CVD, ALD, other suitable methods, or a combination thereof. The dielectric layer 208A includes a high k dielectric material. Each of the metal layers 206A and 210A may have a thickness ranging between 200 A^{o} and 700 A^{o}. The dielectric layer may have a thickness ranging between 40 A^{o} and 80 A^{o}. An additional metal layer 738A may be deposited and patterned as well. The metal layer 738A may include a conductive material different from that of the top metal layer 210A. For example, the top metal layer 210A includes titanium and the metal layer 210A includes titanium nitride.

In FIG. 20E, the second passivation sublayer P1-2 is formed by deposition and CMP. The second passivation sublayer P1-2 includes silicon nitride, other suitable dielectric material or a combination thereof. The second passivation sublayer P1-2 includes a thickness ranging between 4 k A^{o} and 10 k A^{o}.

In FIG. 20F, the workpiece 100 is patterned to form openings 758 such that the top metal features 130 are exposed within the trenches 758. In the disclosed embodiment, trenches 758 extend through the passivation sublayers P1-1 and P1-2. The patterning procedure further includes a lithography process and an etching process. The lithography process includes coating a photoresist layer 760, exposure and development to form a patterned photoresist layer 760 and may further include various baking processes and removing the photoresist after etching by wet stripping or plasma ashing. The etching process may include wet etch, dry etch or a combination thereof. The etching process uses the patterned photoresist layer 760 as an etch mask.

In FIG. 20G, one or more conductive material is deposited to fill in the openings 758, thereby forming vias 148 and metal lines 144. In the disclosed embodiment, the conductive material includes metal, metal alloy, other conductive material or a combination thereof. In furtherance of embodiment, the conductive material includes copper. The formation of the metal lines 144 and vias 148 includes deposition, CMP and patterning. The deposition may include PVD, plating, other suitable method or a combination thereof. In some embodiments, the deposition includes depositing a seed layer by PVD and plating such as ECP on the seed layer.

In FIG. 20H, a second passivation layer P2 is deposited and planarized by CMP. In some embodiments, the second passivation layer P2 includes silicon nitride. In some other embodiments, the second passivation layer P2 includes silicon nitride, USG or a combination thereof.

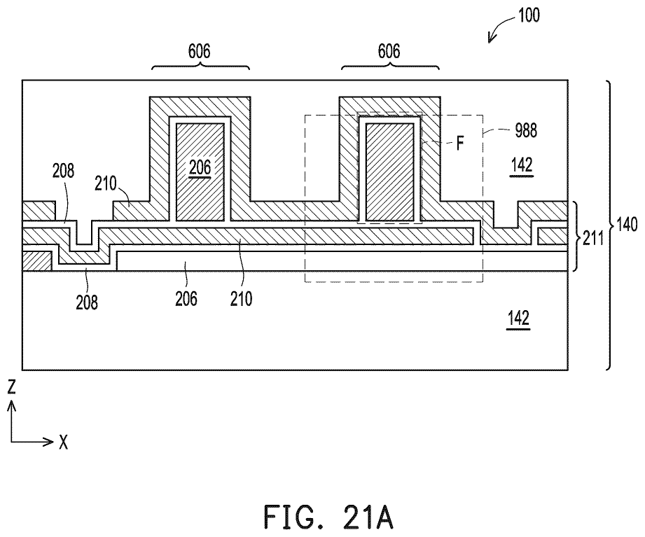

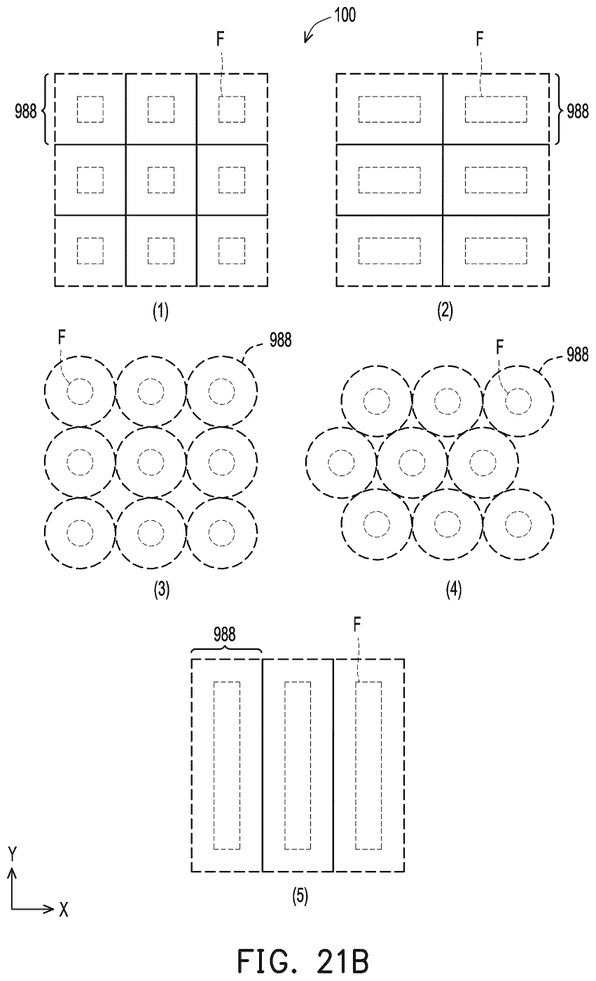

FIG. 21A is a sectional view of an IC structure 100, and FIG. 21B is a top view of the IC structure 100, in portion, constructed according to various embodiments. IC structure 100 is similar to IC structure described in various embodiments, such as the IC structure 100 in FIG. 6A. Similar descriptions are not repeated for simplicity. However, capacitor 158 only includes pillar MIM stacks 604 as illustrated in FIG. 21A. The IC structure 100 includes one or more capacitor 158 having 3D structure and formed with 3D MIM units 606 each having a pillar MIM stack 604 without trench MIM stacks.

A portion of the IC structure 100 in a dashed box 988 is illustrated in FIG. 21B in a top view. The 3D MIM stack 211 in a top view may be square as illustrated in FIG. 21B (1); rectangle as illustrated in FIG. 21B (2); round as illustrated in FIG. 21B (3); or in different configurations as illustrated in FIG. 21B (4). The dimensions 988 and F in FIG. 21B in the top view correspond to dimensions 988 and F defined in FIG. 21A.

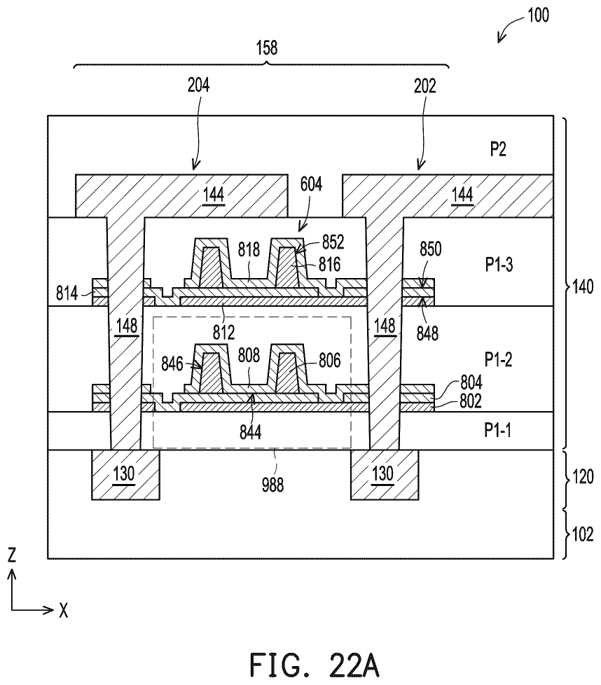

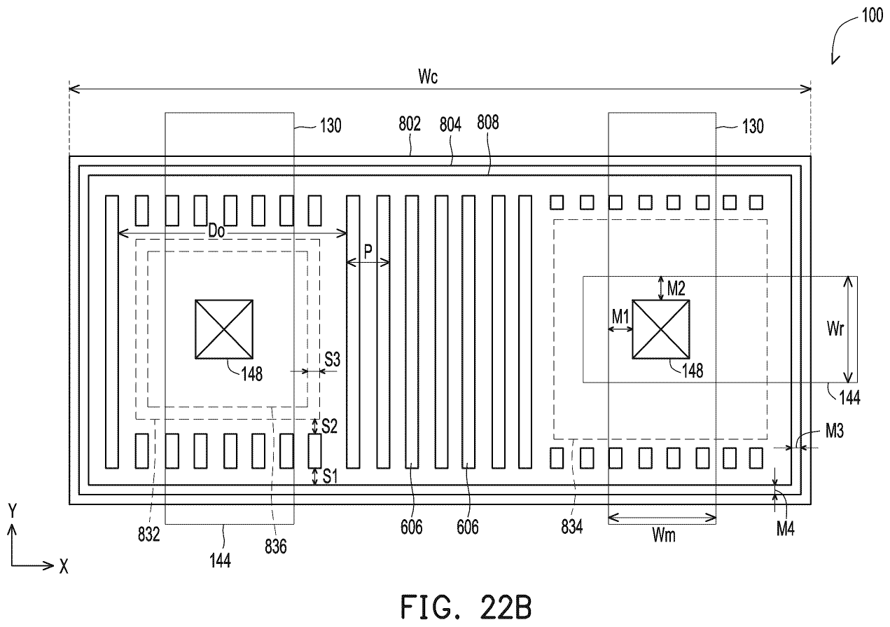

FIG. 22A is a sectional view of an IC structure 100, and FIG. 22B is a top view of the IC structure 100, in portion, constructed according to various embodiments. IC structure 100 is similar to IC structure described in FIGS. 21A and 21B. Similar descriptions are not repeated for simplicity. The IC structure 100 includes one or more capacitor 158 having 3D structure and formed with 3D MIM units 606 each having a pillar MIM stack 604 without any trench MIM stack. Furthermore, each 3D MIM unit 606 in FIG. 22A includes two pillar MIM stacks 604 vertically distanced and stacked. Even though FIG. 22A illustrates two pillar MIM stacks vertically stacked, it is understood that each 3D MIM unit 606 in FIG. 22A may include any suitable number pillar MIM stacks 604 vertically stacked, such as 3, 4, 5 and etc. Various features in FIGS. 22A and 22B are similar or same to those in FIGS. 8A and 8B. Similar descriptions are not repeated for simplicity.

FIG. 22B illustrates the layout and configuration of various features of capacitor 158. Especially, those metal layers are patterned to have openings (or islands), such as openings 832, 834 and 836 so that that a certain via 148 can properly contact some metal layers while avoiding contacting other metal layers. In FIG. 22B, only the metal layers 802, 804 and 808 in the passivation layers P1-1 and P1-2 are illustrated. The metal layers 812, 814 and 818 in the passivation layers P1-3 and P1-4 may have similar dimensions, shapes and locations, such as similar openings described below. The metal layer 806 is patterned into plugs over the metal layer 804, separated by the dielectric layer 844; or alternatively may directly land on the metal layer 804, therefore being connected to a same electrode. The metal layer 806 is not shown in FIG. 8B for simplicity. Similarly, the metal layer 816 is patterned into plugs over the metal layer 814, separated by the dielectric layer 850; or alternatively may directly land on the metal 814, therefore being connected to a same electrode. In some embodiments, the metal layer 802 has an opening 832; the metal layer 808 has an opening 836; and the metal layer 804 have an opening 834. The 3D MIM unit 606 may have a rectangle shape or other suitable shape with uniform spacing and width.

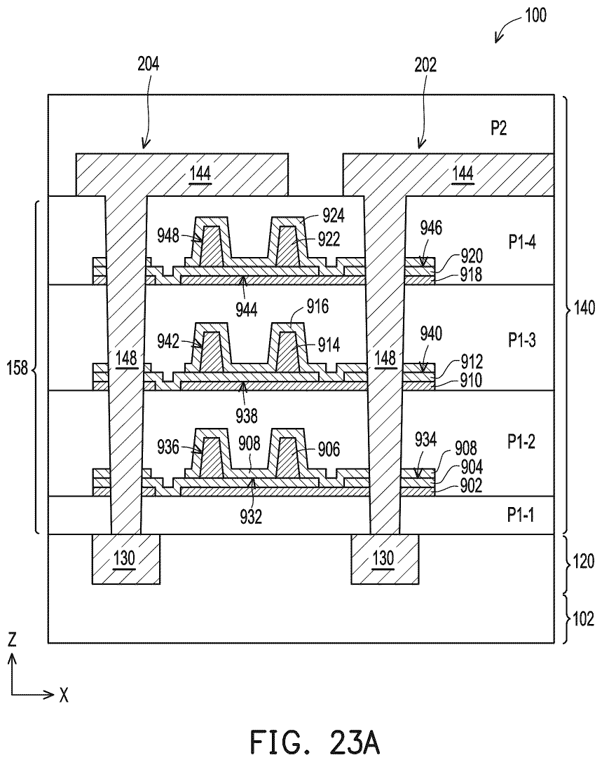

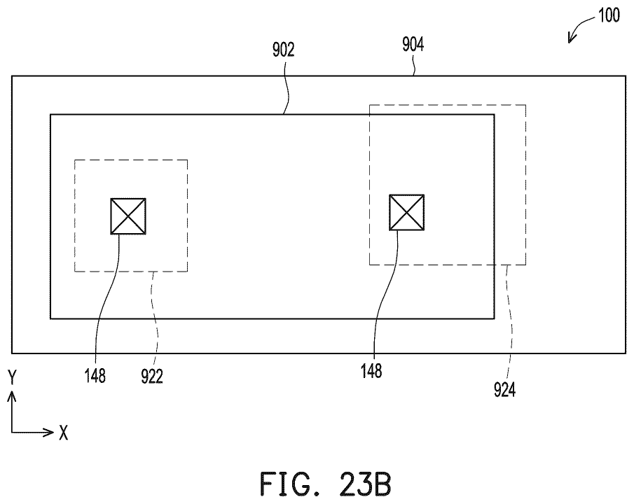

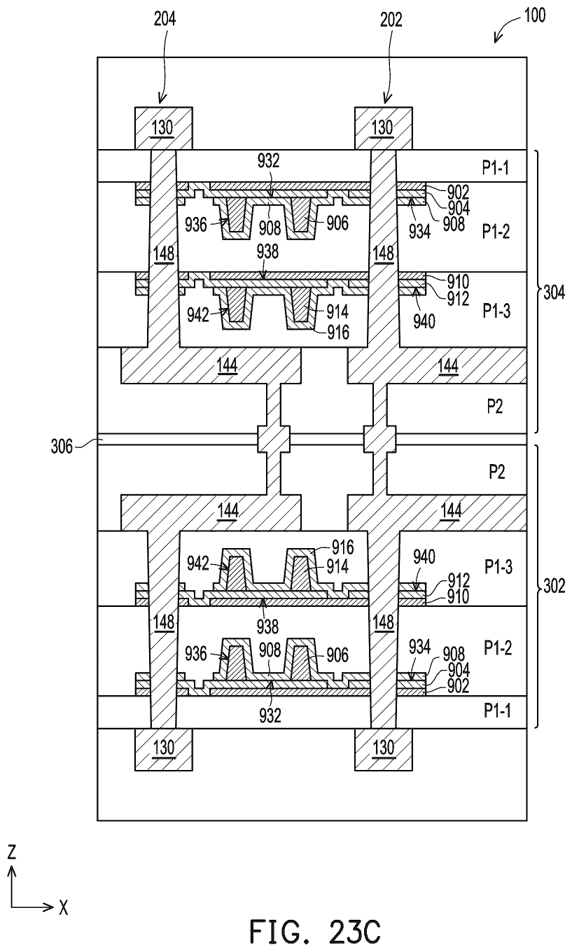

FIGS. 23A through 23C are provided to illustrate IC structure 100 according to some embodiments. FIG. 23A is a sectional view of IC structure 100; FIG. 23B is a top view of IC structure 100; and FIG. 23C is a sectional view of IC structure 100, in portion, constructed according to various embodiments of the present disclosure. The IC structure 100 in FIGS. 23A through 23C is similar to IC structure 100 described above in IC structure 100 in FIGS. 11A through 11C and FIGS. 22A through 22C. Similar descriptions are not repeated for simplicity.

As illustrated in FIG. 23A, the IC structure 100 includes one or more capacitor 158 having 3D structure and formed with 3D MIM units 606 each having pillar MIM stacks 604 and flat trench MIM stacks underlying the pillar MIM stacks 604. Especially, each 3D MIM unit 606 includes multiple N (such as three) pillar MIM stacks 604 aligned and stacked together. It is understood that the number N can be any proper integer, such as 2, 3, 4 and etc. In the illustrated embodiment, N equals 3. In some embodiments, pillar MIM stacks 604 in each 3D MIM unit 606 may be vertically distanced. In some embodiments, each 3D MIM unit 606 includes three pillar MIM stacks 604 and three flat MIM stacks configured as illustrated in FIG. 23A. Note that a flat MIM stack is inserted in a trench or folded into a pillar structurebut is formed on a plat surface. For example, the first flat MIM stacks include the metal layer 902, the dielectric layer 932 and the metal layer 904 configured in a sandwich structure. The second flat MIM stacks include the metal layer 910, the dielectric layer 938 and the metal layer 912 configured in a sandwich structure. The third flat MIM stacks includes the metal layer 918, the dielectric layer 944 and the metal layer 920 configured in a sandwich structure.

FIG. 23B illustrates the metal layers 902 and 904 and the corresponding openings 922 and 924. Only one flat MIM stack is illustrated. In the disclosed embodiment, the metal layer 902 includes an opening 922; and the metal layer 904 includes an opening 924 configured so that the vias 148 can properly landing on the corresponding metal layers to form the electrodes of the capacitor 158. Other metal layers in the pillar MIM stacks and flat MIM stacks may have same openings or similar openings with shifting to reduce the stress. In some embodiment, each metal layer may further include a stand-alone island located in the opening of that metal layer to redistribute the electric field and enhance the performance of the capacitor 158.

Similarly, the IC structure 100 may also include 3DIC structure, as illustrated in FIG. 23C. The IC structure 100 in FIG. 23C includes a first IC die 302 and a second IC die 304 bonded together through a bonding interface 306, thereby forming a 3DIC structure having a capacitor 158 extended in the first die 302 and the second die 304. The first IC die 302 and the second IC die 304 are bonded in a proper mode, such as frontside to frontside bonding. The bonding interface 306 may adopt any suitable bonding structure, such as hybrid bonding structure, similar to those described in FIG. 3. Capacitor 158 in the first IC die 302 and capacitor 158 in the second IC die 304 are similar to capacitor 158 in FIG. 19A. In the disclosed embodiment, capacitor 158 of the first IC die 302 and the capacitor 158 of the second IC die 304 are integrated into a single capacitor (still be referred to as a capacitor 158). Note the dielectric layers of MIM stacks are not shown for simplicity and it is understood that those dielectric layers are present.

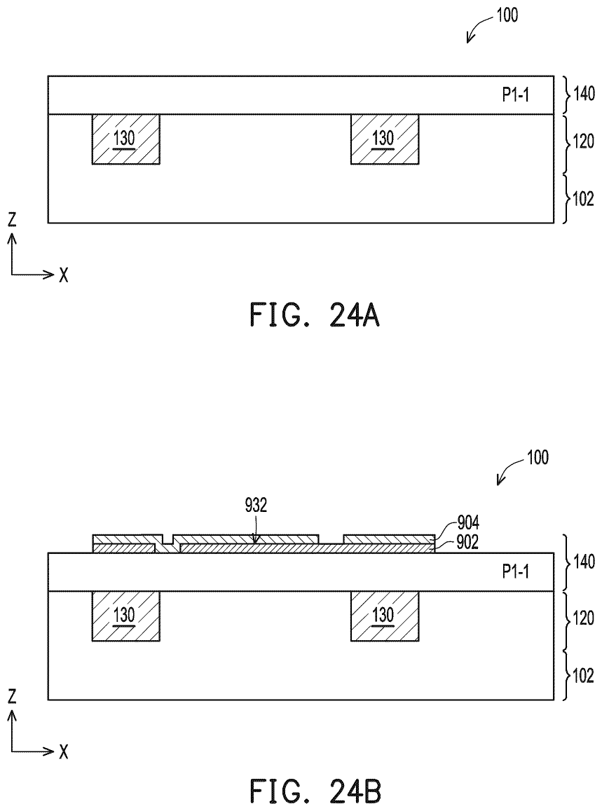

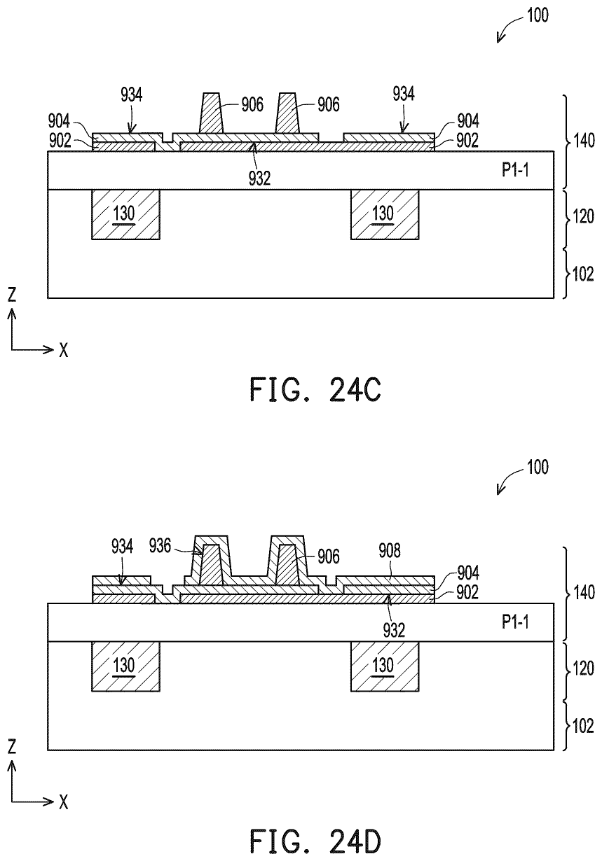

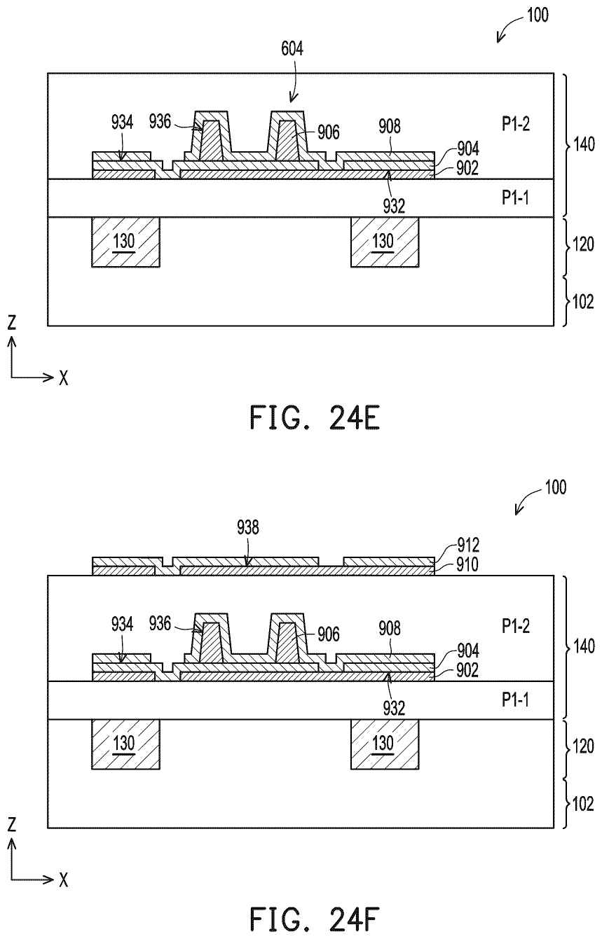

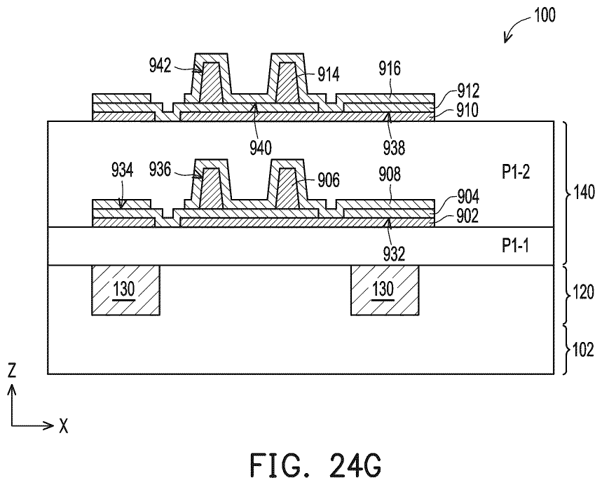

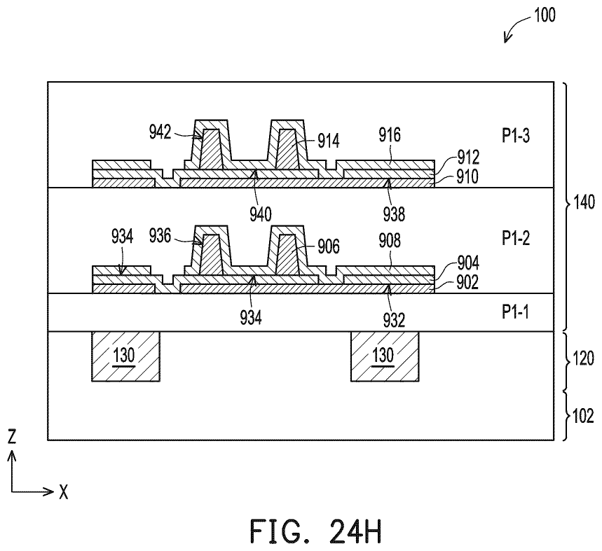

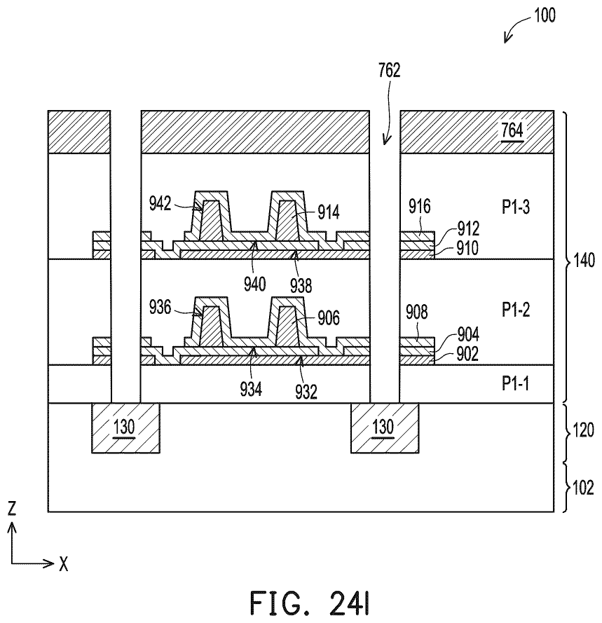

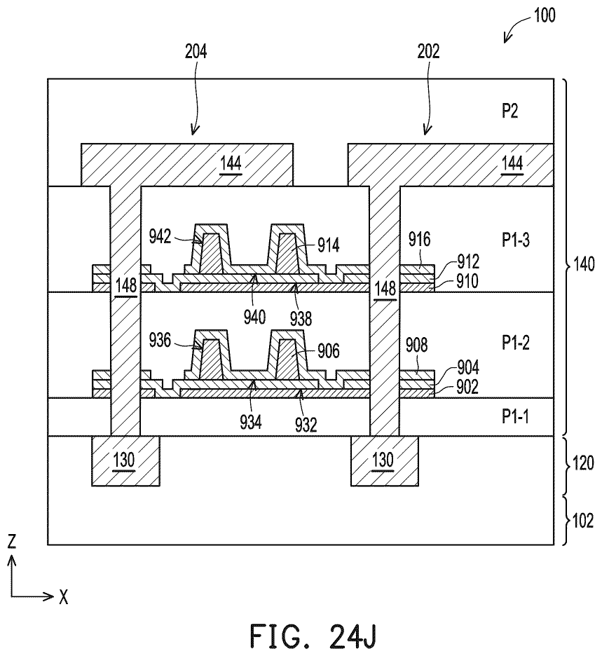

FIGS. 24A through 24J are sectional views of an IC structure 100 at various fabrication stages, in portion, constructed according to some embodiments. The IC structure 100 and the method making the same are collectively described through FIGS. 24A˜24J.

In FIG. 24A, an IC structure (or workpiece) 100 is provided. The IC structure 100 includes a substrate 102 and an interconnect structure 120. The substrate 102, devices formed thereon, and the interconnect structure 120 are described in FIGS. 1A and 1B. The descriptions are not repeated here for simplicity. For example, the interconnect structure 120 includes top metal lines 130. In FIG. 24A, a first passivation sublayer P1-1 is formed on workpiece 100. The first passivation sublayer P1-1 include silicon nitride with a thickness ranging between 4 k A^{o} and 10 k A^{o}. The formation of the first passivation sublayer P1-1 includes deposition (such as by CVD) and CMP.

In FIG. 24B, a MIM stack is deposited and patterned. For example, a bottom metal layer 902 is deposited and patterned. A dielectric layer 932 is deposited and may be patterned. A top metal layer 904 is deposited and patterned. The bottom and top metal layers 902, 904 may include any suitable conductive material such as titanium nitride, tantalum, tantalum nitride, titanium, other suitable metal or a combination thereof. The dielectric layer 932 may include any suitable dielectric material such as a high k dielectric material. The metal layers 902, 904 may be deposited by any suitable method, such as ALD, PVD, other suitable methods or a combination thereof. The dielectric layer 932 may be deposited by CVD, ALD, other suitable methods, or a combination thereof. Each of the metal layers 902 and 904 may have a thickness ranging between 200 A^{o} and 700 A^{o}. The dielectric layer 932 may have a thickness ranging between 40 A^{o} and 80 A^{o}.

In FIG. 24C, a dielectric layer 934 is deposited and may have a thickness ranging between 40 A^{o} and 80 A^{o}. The dielectric layer 934 includes a high k dielectric material. Another metal layer 906 is deposited over and patterned to form a pillar structure. The metal layer 906 may have a thickness ranging between 100 A^{o} and 200 A^{o}. The metal layer 906 is patterned by etching using the patterned photoresist layer as an etch mask. The metal layer 906 may be deposited by any suitable method, such as ALD, PVD, other suitable methods or a combination thereof. The dielectric layer 934 may be deposited by CVD, ALD, other suitable methods, or a combination thereof. The metal layer 906 may have a thickness ranging between 200 A^{o} and 700 A^{o}.

In FIG. 24D, a dielectric layer 936 is deposited and may have a thickness ranging between 40 A^{o} and 80 A^{o}. The dielectric layer 936 includes a high k dielectric material. Another metal layer 908 is deposited over and patterned to form a pillar MIM stack 604. The metal layer 908 may have a thickness ranging between 200 A^{o} and 700 A^{o}. The metal layer 908 is patterned by etching using the patterned photoresist layer as an etch mask. The metal layer 908 may be deposited by any suitable method, such as ALD, PVD, other suitable methods or a combination thereof. The dielectric layer 936 may be deposited by CVD, ALD, other suitable methods, or a combination thereof.

In FIG. 24E, a second passivation sublayer P1-2 is formed by deposition and CMP. The second passivation sublayer P1-2 includes silicon nitride and may have a thickness ranging between 4 k A^{o} and 10 k A^{o}.

In FIG. 24F, a flat MIM stack is deposited and patterned. For example, a bottom metal layer 910 is deposited and patterned. A dielectric layer 938 is deposited and may be patterned. A top metal layer 912 is deposited and patterned. The bottom and top metal layers 910, 912 may include any suitable conductive material such as titanium nitride, tantalum, tantalum nitride, titanium, other suitable metal or a combination thereof. The dielectric layer 938 may include any suitable dielectric material such as a high k dielectric material. The metal layers 910. 912 may be deposited by any suitable method, such as ALD, PVD, other suitable methods or a combination thereof. The dielectric layer 938 may be deposited by CVD, ALD, other suitable methods, or a combination thereof. Each of the metal layers 910 and 912 may have a thickness ranging between 200 A^{o} and 700 A^{o}. The dielectric layer 938 may have a thickness ranging between 40 A^{o} and 80 A^{o}.

In FIG. 24G, another pillar MIM stack 604 is deposited and patterned. In some embodiments, a dielectric layer 940 is deposited before MIM stack by a suitable method, such as CVD, and may have a thickness ranging between 40 A^{o} and 80 A^{o}. The pillar MIM stack 604 is deposited and patterned. For example, a bottom metal layer 914 is deposited and patterned to form a pillar structure. A dielectric layer 942 is deposited and may be patterned. A top metal layer 916 is deposited and patterned, thereby forming another pillar MIM stack 604. The bottom and top metal layers 914, 916 may include any suitable conductive material such as titanium nitride, tantalum, tantalum nitride, titanium, other suitable metal or a combination thereof. The dielectric layers 940, 942 may include any suitable dielectric material such as a high k dielectric material. The metal layers 914, 916 may be deposited by any suitable method, such as ALD, PVD, other suitable methods or a combination thereof. The dielectric layers 940, 942 may be deposited by CVD, ALD, other suitable methods, or a combination thereof. Each of the metal layers 914 and 916 may have a thickness ranging between 200 A^{o} and 700 A^{o}. Each of the dielectric layers 940 and 942 may have a thickness ranging between 40 A^{o} and 80 A^{o}.

In FIG. 24H, a third passivation sublayer P1-3 is formed by deposition and CMP. The third passivation sublayer P1-3 includes silicon nitride and may have a thickness ranging between 4 k A^{o} and 10 k A^{o}.

In FIG. 24I, workpiece 100 is patterned to form openings 762 such that the top metal features 130 are exposed within the trenches 762. In the disclosed embodiment, trenches 762 extend through the passivation sublayers P1-1, P1-2 and P1-3. The patterning procedure further includes a lithography process and an etching process. The lithography process includes coating a photoresist layer 764, exposure and development to form a patterned photoresist layer 764 and may further include various baking processes and removing the photoresist after etching by wet stripping or plasma ashing. The etching process may include wet etch, dry etch or a combination thereof. The etching process uses the patterned photoresist layer 764 as an etch mask. The depth of the openings 762 ranges between 30 k A^{o} and 45 k A^{o} according to some embodiments.

In FIG. 24J, one or more conductive material is deposited to fill in the openings 762, thereby forming vias 148 and metal lines 144 as electrodes 202 and 204 of the capacitor 158. In the disclosed embodiment, the conductive material includes metal, metal alloy, other conductive material or a combination thereof. In furtherance of embodiment, the conductive material includes copper. The formation of the metal lines 144 and vias 148 includes deposition, CMP and patterning. The deposition may include PVD, plating, other suitable method or a combination thereof. In some embodiments, the deposition includes depositing a seed layer by PVD and plating such as ECP on the seed layer. Thereafter, a second passivation layer P2 is deposited and planarized by CMP. In some embodiments, the second passivation layer P2 includes silicon nitride. In some other embodiments, the second passivation layer P2 includes silicon nitride and USG. The above method may be used to form the IC structure 100, such as the IC structure 100 in FIG. 22A or FIG. 23A according to some embodiments.

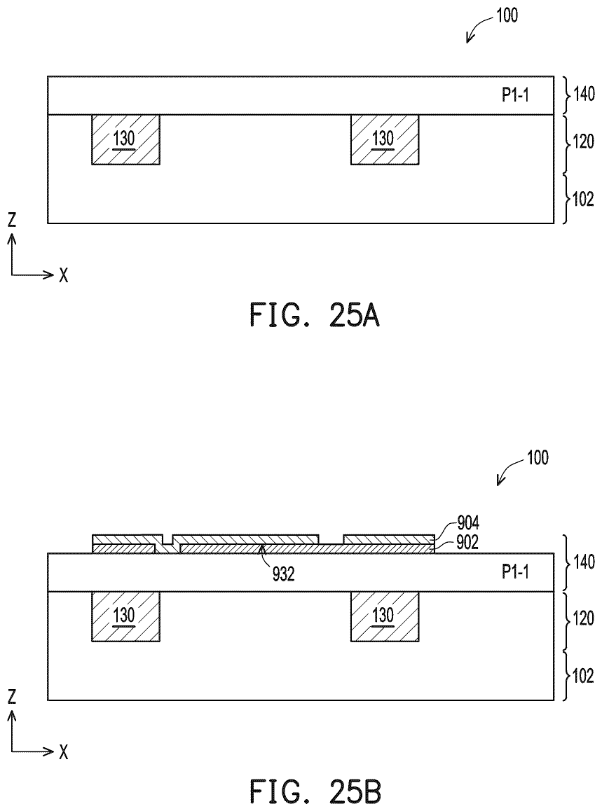

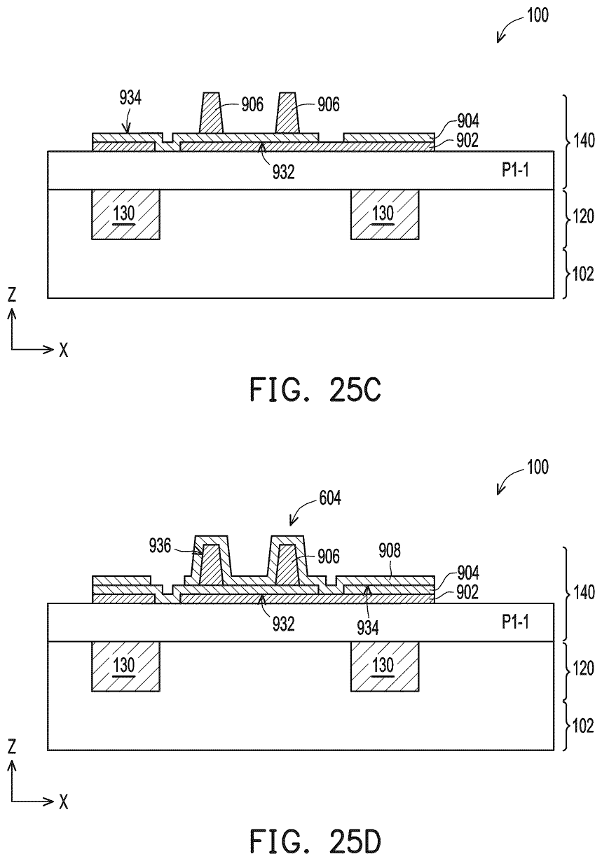

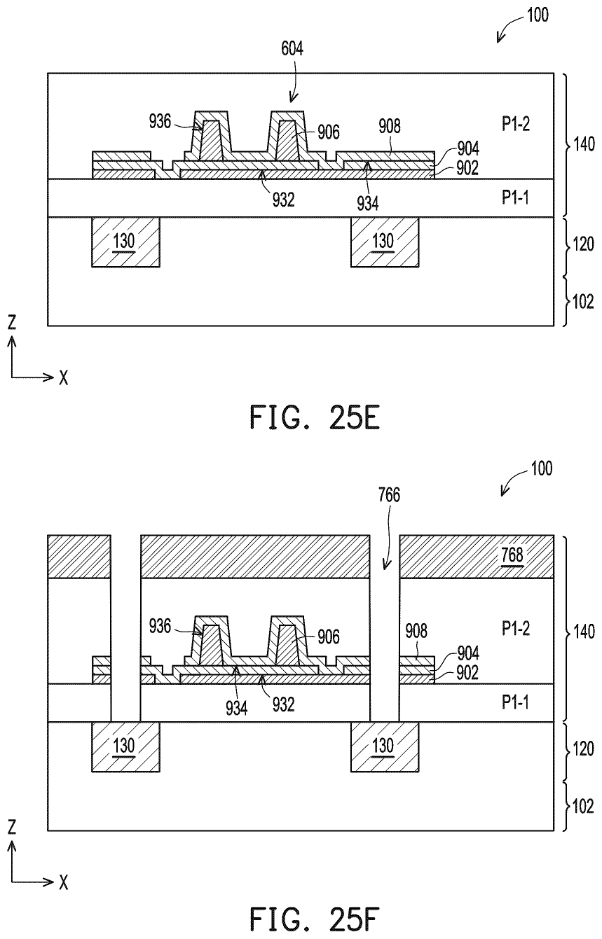

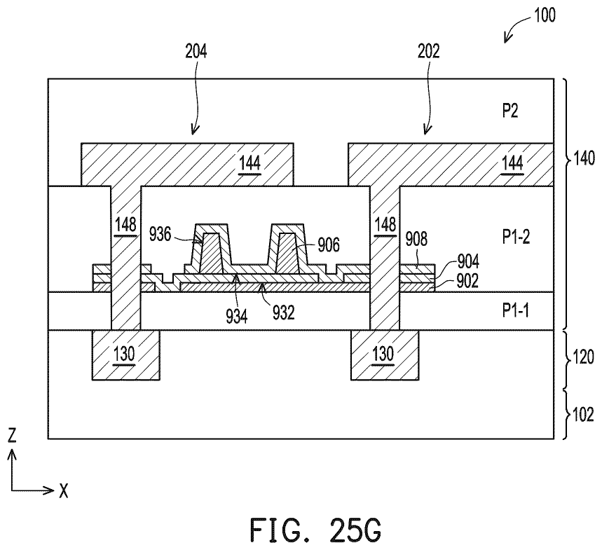

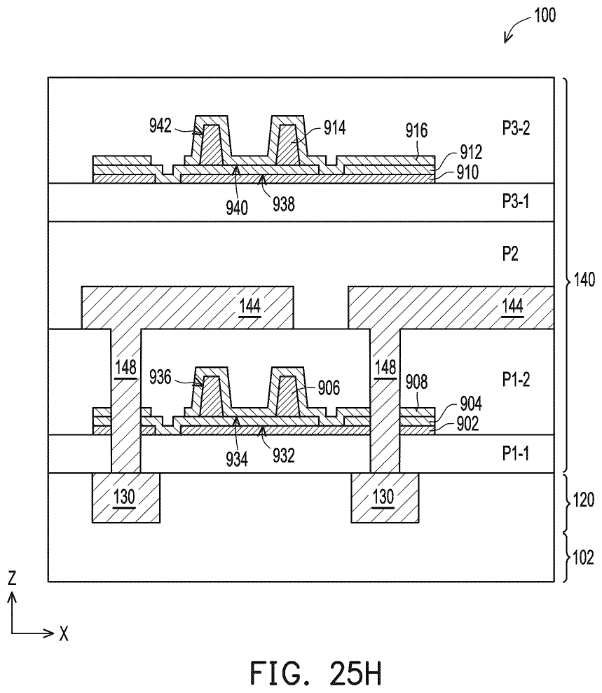

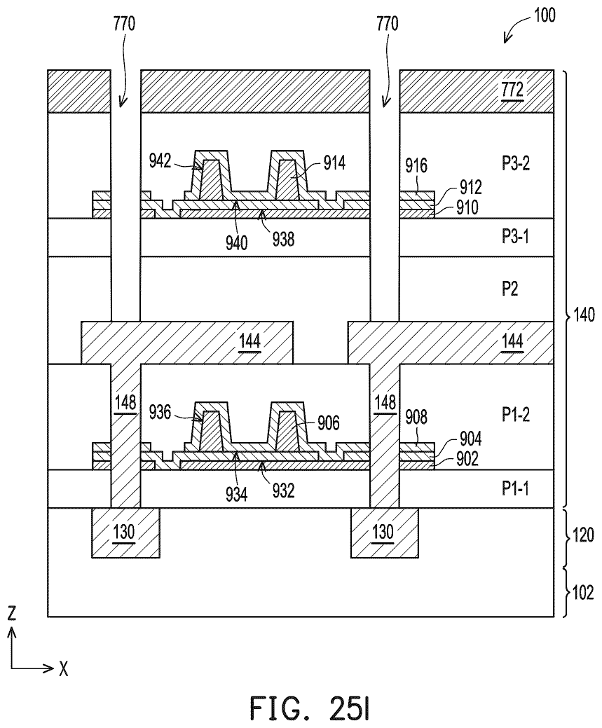

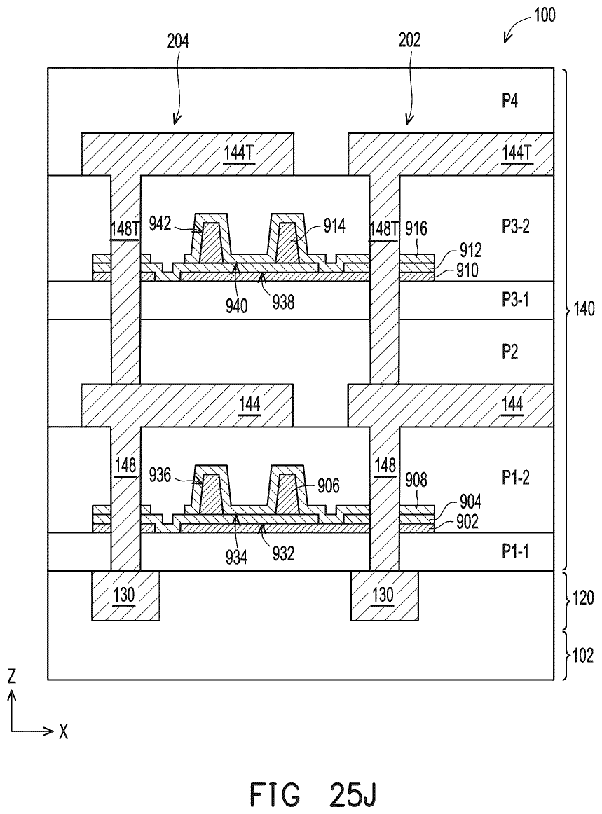

FIGS. 25A through 25J are sectional views of an IC structure 100 at various fabrication stages, in portion, constructed according to some embodiments. The IC structure 100 and the method making the same are collectively described through FIGS. 25A˜25J.

In FIG. 25A, an IC structure (or workpiece) 100 is provided. FIGS. 25A through 25E are similar to FIGS. 24A through 24E in terms of features, configurations and formations. Similar descriptions are not repeated for simplicity. Especially, in FIGS. 25A through 25E, flat MIM stacks and pillar MIM stacks 604 are formed on the workpiece 100 and are separated by the dielectric layer 934. The flat MIM stacks include the bottom metal layer 902, the dielectric layer 932, and the top metal layer 904; and the pillar MIM stacks 604 include the bottom metal layer 906, the dielectric layer 936, and the top metal layer 908.

In FIG. 25F, workpiece 100 is patterned to form openings 766 such that the top metal features 130 are exposed within the trenches 766. In the disclosed embodiment, trenches 766 extend through the passivation sublayers P1-1 and P1-2. The patterning procedure further includes a lithography process and an etching process. The lithography process includes coating a photoresist layer 768, exposure and development to form a patterned photoresist layer 768 and may further include various baking processes and removing the photoresist after etching by wet stripping or plasma ashing. The etching process may include wet etch, dry etch or a combination thereof. The etching process uses the patterned photoresist layer 768 as an etch mask. The depth of the openings 766 ranges between 30 k A^{o} and 45 k A^{o}.

In FIG. 25G, one or more conductive material is deposited to fill in the openings 766, thereby forming vias 148 and metal lines 144 for capacitor 158. In the disclosed embodiment, the conductive material includes metal, metal alloy, other conductive material or a combination thereof. In furtherance of embodiment, the conductive material includes copper. The formation of the metal lines 144 and vias 148 includes deposition, CMP and patterning. The deposition may include PVD, plating, other suitable method or a combination thereof. In some embodiments, the deposition includes depositing a seed layer by PVD and plating such as ECP on the seed layer. Thereafter, a second passivation layer P2 is deposited and planarized by CMP. In some embodiments, the second passivation layer P2 includes silicon nitride. In some other embodiments, the second passivation layer P2 includes silicon nitride and USG. The above method may be used to form the IC structure 100, such as the IC structure 100 in FIG. 21A according to some embodiments.

In FIG. 25H, pillar MIM stacks are formed in the third passivation layer P3 similar to the method described in FIGS. 14A through 14F. The third passivation layer P3 includes passivation sublayers P3-1 and P3-2. The pillar MIM stacks are aligned and stacked over the underlying pillar MIM stacks. The formation of the pillar MIM stacks 604 in third passivation layer P3 is similar to the formation of the pillar MIM stacks in the first passivation layer P1. Especially, in FIG. 25H, flat MIM stacks and pillar MIM stacks 604 are formed on the workpiece 100 and are separated by the dielectric layer 940. The flat MIM stacks include the bottom metal layer 910, the dielectric layer 938, and the top metal layer 912; and the pillar MIM stacks 604 include the bottom metal layer 914, the dielectric layer 942, and the top metal layer 916.

In FIG. 25I, workpiece 100 is patterned to form openings 770 such that the metal lines 144 are exposed within openings 770. In the disclosed embodiment, trenches 770 extend through the passivation sublayers P3-2, P3-1 and P2. The patterning procedure further includes a lithography process and an etching process. The lithography process includes coating a photoresist layer 772, exposure and development to form a patterned photoresist layer 772 and may further include various baking processes and removing the photoresist after etching by wet stripping or plasma ashing. The etching process may include wet etch, dry etch or a combination thereof. The etching process uses the patterned photoresist layer 772 as an etch mask.

In FIG. 25J, one or more conductive material is deposited to fill in the openings 770, thereby forming vias 148T and metal lines 144T collectively with metal lines 144 and vias 148 as electrodes 202 and 204 of the capacitor 158. The hybrid MIM stacks in the first passivation layer P1 and the hybrid MIM stacks in the third passivation layer P3 are thus electrically connected to form the combined capacitor 158. Each hybrid MIM stack includes a flat MIM stack and a pillar MIM stack 604. In the disclosed embodiment, the conductive material includes metal, metal alloy, other conductive material or a combination thereof. In furtherance of embodiment, the conductive material includes copper. The formation of the metal lines 144T and vias 148T includes deposition, CMP and patterning. The deposition may include PVD, plating, other suitable method or a combination thereof. In some embodiments, the deposition includes depositing a seed layer by PVD and plating such as electro-chemical plating deposition (ECP) on the seed layer. Thereafter, a second passivation layer P2 is deposited and planarized by CMP. In some embodiments, the second passivation layer P2 includes silicon nitride. In some other embodiments, the second passivation layer P2 includes silicon nitride and USG. The above method may be used to form the IC structure 100 according to some embodiments. In this case, the vias are formed through different procedure and the top portion of the vias and the bottom portion of the vias are electrically connected but are not necessarily aligned, thus providing more freedom with different layout and configuration for various advantages, such as tuning pattern density and reducing the stress to the workpiece by the vias.

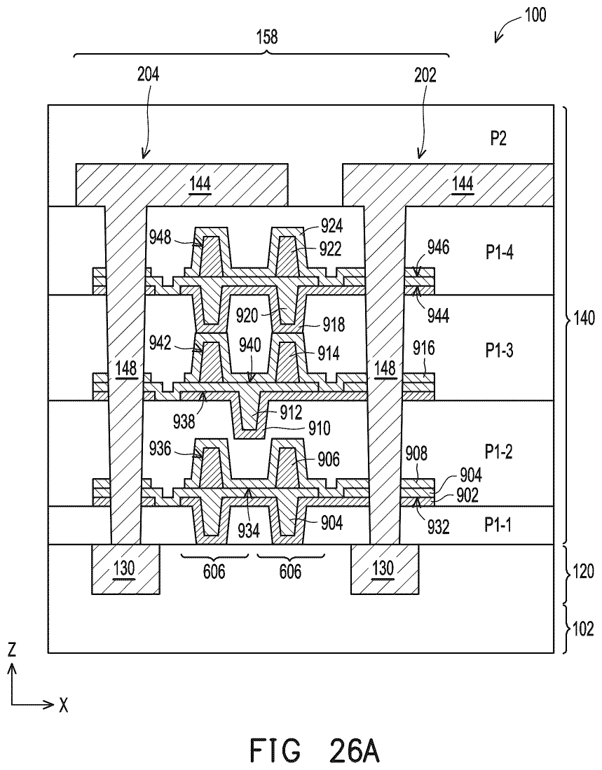

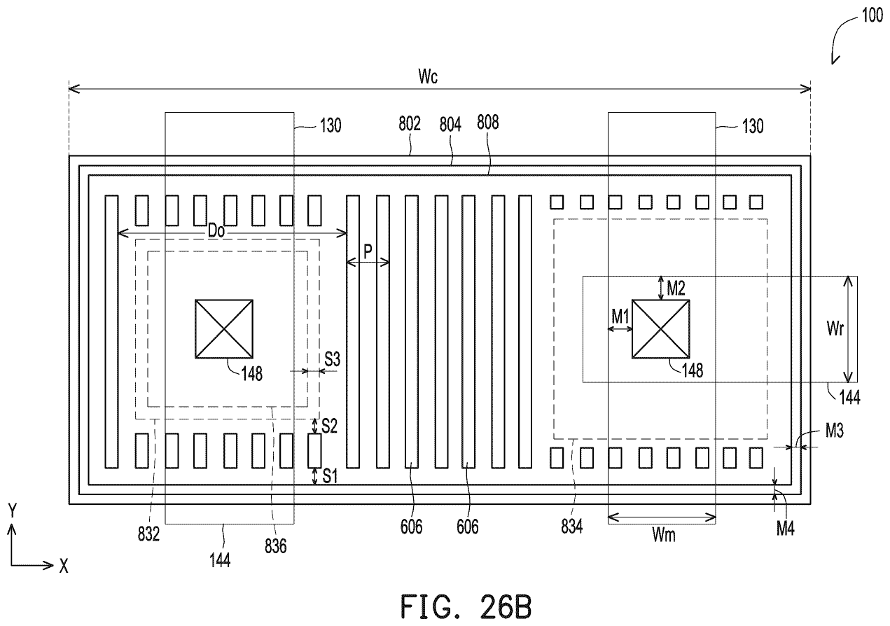

FIG. 26A is a sectional view of an IC structure 100, and FIG. 26B is a top view of the IC structure 100, in portion, constructed according to various embodiments. IC structure 100 is similar or same to IC structure 100 described in FIGS. 22A and 22B. Similar descriptions are not repeated for simplicity. The IC structure 100 includes one or more capacitor 158 having 3D structure and formed with 3D MIM units 606 each having a pillar MIM stack 604 and trench MIM stacks 602. Each 3D MIM unit 606 in FIG. 26A includes three hybrid MIM stacks vertically stacked. Even though FIG. 26A illustrates two pillar MIM stacks vertically stacked, it is understood that each 3D MIM unit 606 in FIG. 26A may include any suitable number hybrid MIM stacks vertically stacked, such as 3, 4, 5 and etc. However, those hybrid MIM stacks in different layers are offset and staggered. FIG. 26B is similar to FIG. 8B. Similar descriptions are not repeated for simplicity.

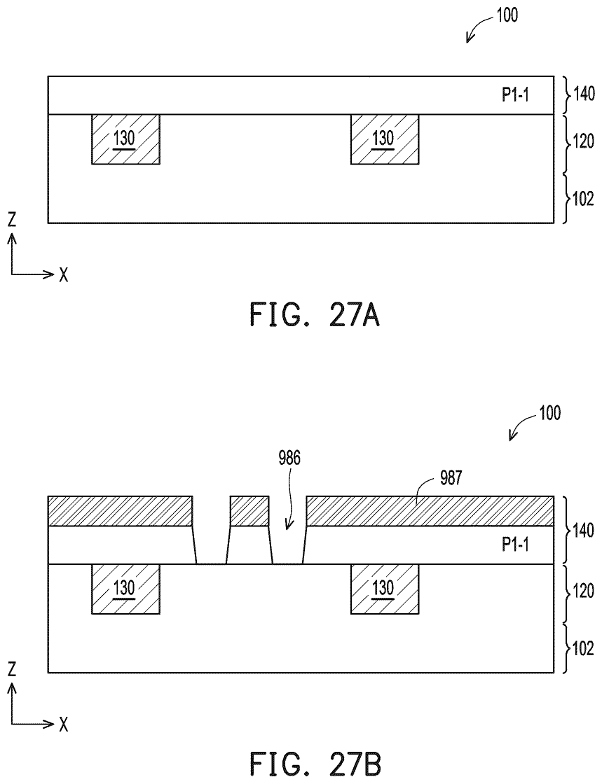

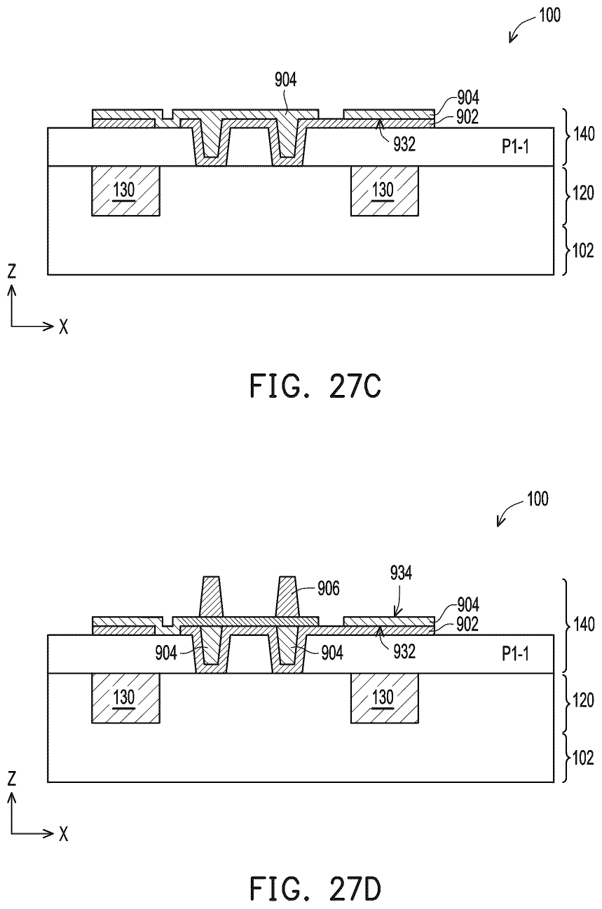

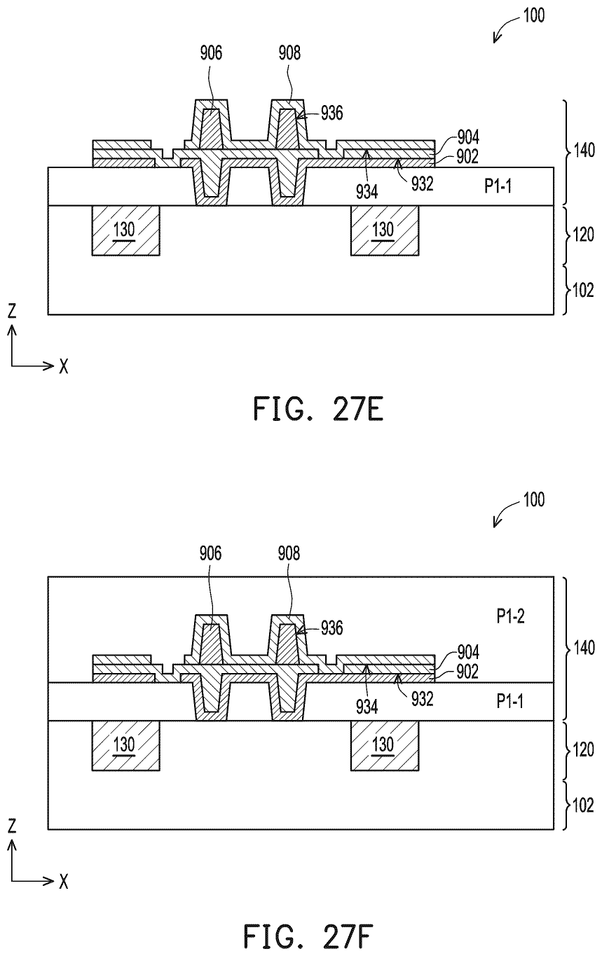

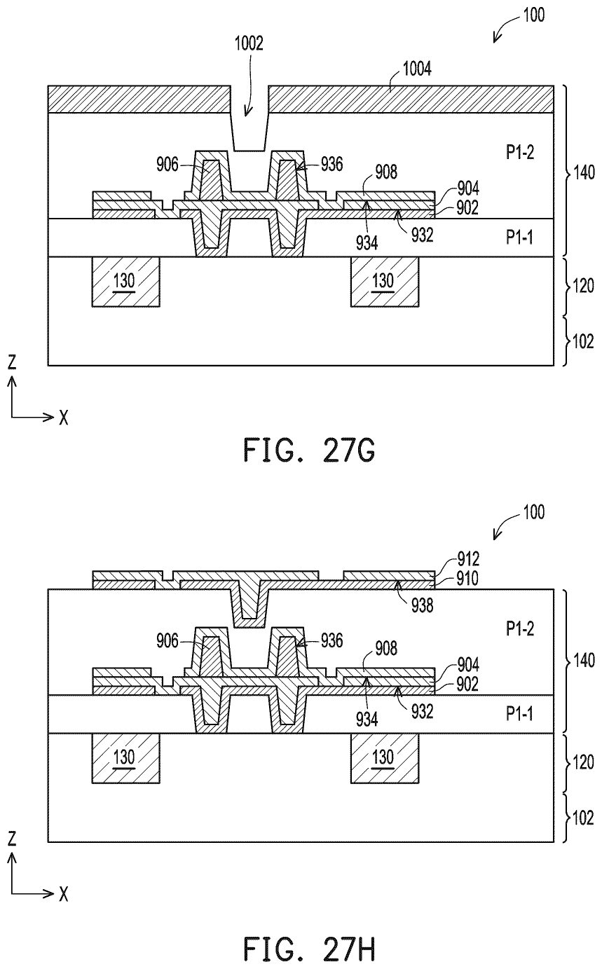

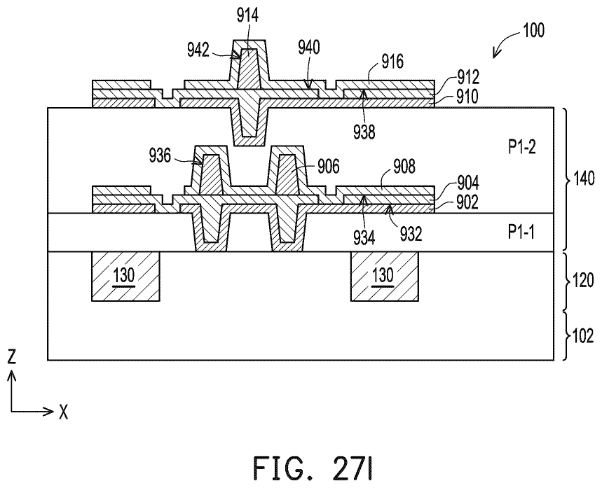

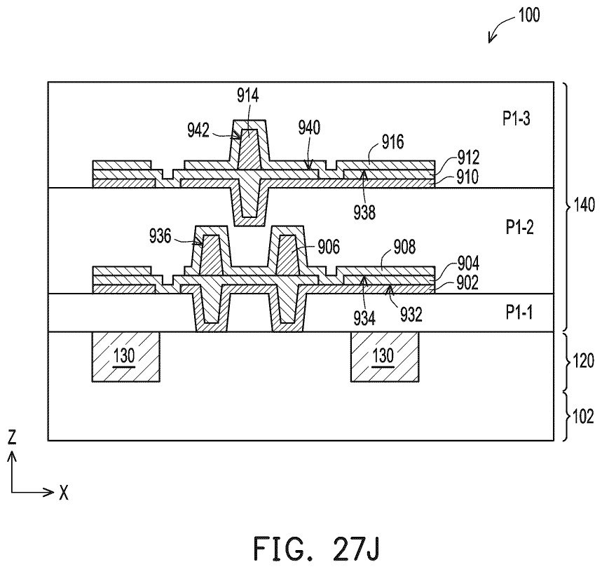

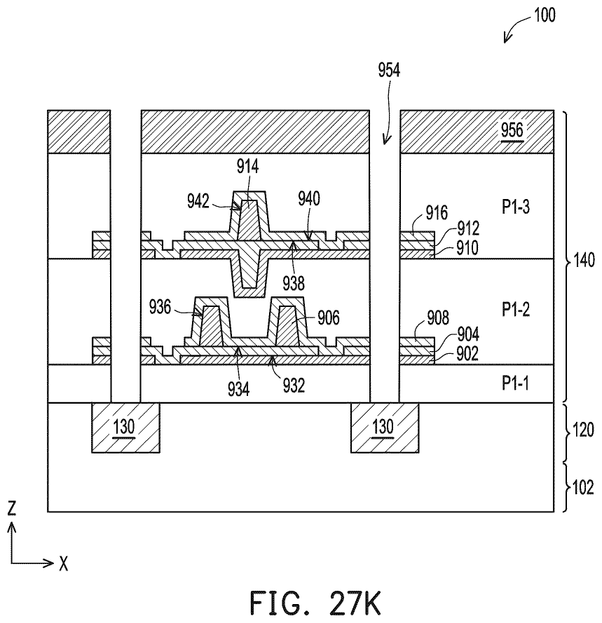

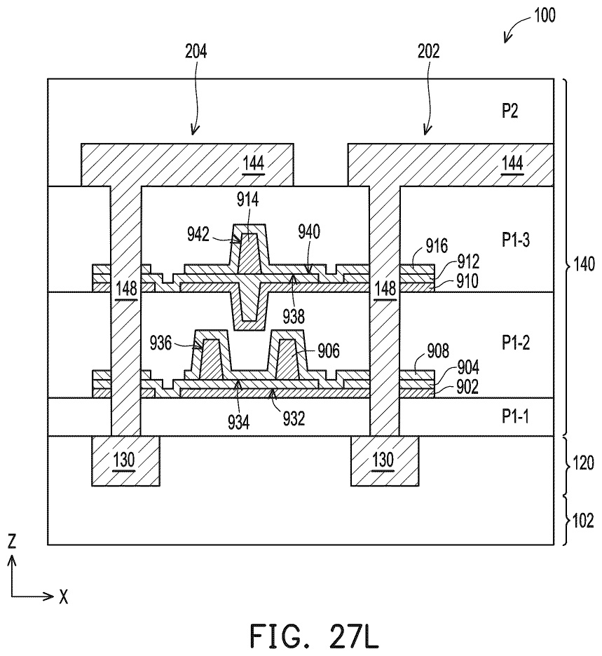

FIGS. 27A through 27L are sectional views of an IC structure 100 at various fabrication stages, in portion, constructed according to some embodiments. The IC structure 100 and the method making the same are collectively described through FIGS. 27A˜27L.

In FIG. 27A, an IC structure (or workpiece) 100 is provided. The IC structure 100 includes a substrate 102 and an interconnect structure 120. The substrate 102, devices formed thereon, and the interconnect structure 120 are described in FIGS. 1A and 1B. The descriptions are not repeated here for simplicity. For example, the interconnect structure 120 includes top metal lines 130. In FIG. 27A, a first passivation sublayer P1-1 is formed on workpiece 100. The first passivation sublayer P1-1 include silicon nitride with a thickness ranging between 4 k A^{o} and 10 k A^{o}. The formation of the first passivation sublayer P1-1 includes deposition (such as by CVD) and CMP.

In FIG. 27B, the first passivation sublayer P1-1 is patterned to form trenches 986 by a lithography process and an etching process. The lithography process forms a patterned photoresist layer 987. The etching process uses the patterned photoresist layer 955 as an etch mask.

In FIG. 27C, a MIM stack is deposited and patterned. For example, a bottom metal layer 902 is deposited and patterned; a dielectric layer 932 is deposited and may be patterned; and a top metal layer 904 is deposited and patterned. thereby forming trench MIM stacks 602. The bottom and top metal layers 902, 904 may include any suitable conductive material such as titanium nitride, tantalum, tantalum nitride, titanium, other suitable metal or a combination thereof. The dielectric layer 932 may include any suitable dielectric material such as a high k dielectric material. The metal layers 902, 904 may be deposited by any suitable method, such as ALD, PVD, other suitable methods or a combination thereof. The dielectric layer 932 may be deposited by CVD, ALD, other suitable methods, or a combination thereof. Each of the metal layers 902 and 904 may have a thickness ranging between 200 A^{o} and 700 A^{o}. The dielectric layer 932 may have a thickness ranging between 40 A^{o} and 80 A^{o}.

In FIG. 27D, a dielectric layer 934 is deposited and may have a thickness ranging between 40 A^{o} and 80 A^{o}. The dielectric layer 934 includes a high k dielectric material. Another metal layer 906 is deposited over and patterned to form a pillar structure. The metal layer 906 may have a thickness ranging between 100 A^{o} and 200 A^{o}. The metal layer 906 is patterned by etching using the patterned photoresist layer as an etch mask. The metal layer 906 may be deposited by any suitable method, such as ALD, PVD, other suitable methods or a combination thereof. The dielectric layer may be deposited by CVD, ALD, other suitable methods, or a combination thereof. The metal layer 906 may have a thickness ranging between 100 A^{o} and 200 A^{o}.

In FIG. 27E, a dielectric layer 936 is deposited and may have a thickness ranging between 40 A^{o} and 80 A^{o}. The dielectric layer 936 includes a high k dielectric material. Another metal layer 908 is deposited over and patterned to form a pillar MIM stack 604. The metal layer 908 may have a thickness ranging between 200 A^{o} and 700 A^{o}. The metal layer 908 is patterned by etching using the patterned photoresist layer as an etch mask. The metal layer 908 may be deposited by any suitable method, such as ALD, PVD, other suitable methods or a combination thereof. The dielectric layer may be deposited by CVD, ALD, other suitable methods, or a combination thereof.

In FIG. 27F, a second passivation sublayer P1-2 is formed by deposition and CMP. The second passivation sublayer P1-2 includes silicon nitride and may have a thickness ranging between 4 k A^{o} and 10 k A^{o}.

In FIG. 27G, the second passivation sublayer P1-2 is patterned to form trenches 1002 by a lithography process and an etching process. The lithography process forms a patterned photoresist layer 1004. The etching process uses the patterned photoresist layer 994 as an etch mask.

In FIG. 27H, another MIM stack is deposited and patterned. For example, a bottom metal layer 910 is deposited and patterned. A dielectric layer 938 is deposited and may be patterned. A top metal layer 912 is deposited and patterned. The bottom and top metal layers 910, 912 may include any suitable conductive material such as titanium nitride, tantalum, tantalum nitride, titanium, other suitable metal or a combination thereof. The dielectric layer 938 may include any suitable dielectric material such as a high k dielectric material. The metal layers 910, 912 may be deposited by any suitable method, such as ALD, PVD, other suitable methods or a combination thereof. The dielectric layer 938 may be deposited by CVD, ALD, other suitable methods, or a combination thereof. Each of the metal layers 910 and 912 may have a thickness ranging between 200 A^{o} and 700 A^{o}. The dielectric layer 038 may have a thickness ranging between 40 A^{o} and 80 A^{o}.

In FIG. 27I, a dielectric layer 940 is deposited and may be patterned. Another MIM stack is deposited and patterned. The dielectric layer 940 is deposited before MIM stack by a suitable method, such as CVD, and may have a thickness ranging between 40 A^{o} and 80 A^{o}. The MIM stack is deposited and patterned. For example, a bottom metal layer 914 is deposited and patterned; a dielectric layer 942 is deposited and may be patterned; and a top metal layer 916 is deposited and patterned, thereby forming another pillar MIM stack 604. The bottom and top metal layers 914, 916 may include any suitable conductive material such as titanium nitride, tantalum, tantalum nitride, titanium, other suitable metal or a combination thereof. The dielectric layer 942 may include any suitable dielectric material such as a high k dielectric material. The metal layers 914, 916 may be deposited by any suitable method, such as ALD, PVD, other suitable methods or a combination thereof. The dielectric layer 942 may be deposited by CVD, ALD, other suitable methods, or a combination thereof. Each of the metal layers 914 and 916 may have a thickness ranging between 200 A^{o} and 700 A^{o}. The dielectric layer 942 may have a thickness ranging between 40 A^{o} and 80 A^{o}.

In FIG. 27J, a third passivation sublayer P1-3 is formed by deposition and CMP. The third passivation sublayer P1-3 includes silicon nitride and may have a thickness ranging between 4 k A^{o} and 10 k A^{o}.

In FIG. 27K, workpiece 100 is patterned to form openings 954 such that the top metal features 130 are exposed within the trenches 954. In the disclosed embodiment, trenches 954 extend through the passivation sublayers P1-1, P1-2 and P1-3. The patterning procedure further includes a lithography process and an etching process. The lithography process includes coating a photoresist layer 956, exposure and development to form a patterned photoresist layer 956 and may further include various baking processes and removing the photoresist after etching by wet stripping or plasma ashing. The etching process may include wet etch, dry etch or a combination thereof. The etching process uses the patterned photoresist layer 956 as an etch mask. Trench depth ranges between 30 k A^{o} and 45 k A^{o}.

In FIG. 27L, one or more conductive material is deposited to fill in the openings 954, thereby forming vias 148 and metal lines 144 as electrodes 202 and 204 of the capacitor 158. In the disclosed embodiment, the conductive material includes metal, metal alloy, other conductive material or a combination thereof. In furtherance of embodiment, the conductive material includes copper. The formation of the metal lines 144 and vias 148 includes deposition, CMP and patterning. The deposition may include PVD, plating, other suitable method or a combination thereof. In some embodiments, the deposition includes depositing a seed layer by PVD and plating such as ECP on the seed layer. Thereafter, a second passivation layer P2 is deposited and planarized by CMP. In some embodiments, the second passivation layer P2 includes silicon nitride. In some other embodiments, the second passivation layer P2 includes silicon nitride and USG. The above method may be used to form the IC structure 100, such as the IC structure 100 in FIG. 26A according to some embodiments.

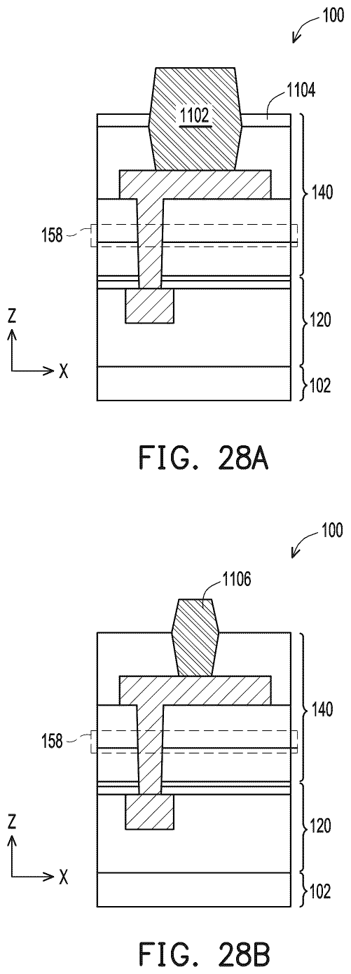

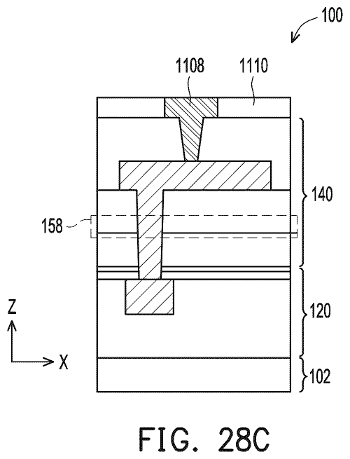

FIGS. 28A through 28C are sectional views of an IC structure 100 in portion, constructed according to some embodiments. The IC structure 100 and the method making the same are collectively described through FIGS. 28A˜28C.

In FIG. 28A, an IC structure (or workpiece) 100 includes a substrate 102 and devices formed thereon; an interconnect structure 120; and a passivation structure 140 formed thereon. The passivation structure 140 includes one or more capacitor 158 that may have any suitable structure described above in various embodiments. For example, capacitor 158 includes a plurality of 3D MIM units 606 that includes trench MIM stacks 602, pillar MIM stacks 604, flat MM stacks, hybrid MIM stacks or combinations thereof vertically stacked, aligned or offset. Each of 3D MIM units 606 may include multiple layers of trench MIM stacks 602, pillar MIM stacks 604, flat MIM stacks vertically stacked. Multiple layers of trench MIM stacks are aligned and overlapped, or alternatively staggered. Especially, the IC structure 100 further includes bond structures formed on the passivation structure 140 and configured to provide bonding features to other IC structure, such as another IC die, printed circuit board (PCB) or other suitable packaging structure. In the present embodiment, the bond structures 1102 are controlled collapse chip connection (C4) bumps. A suitable material layer 1104 may be formed on the passivation structure 140 and surrounding the bond structures 1102. For example, the material layer 1104 may be a polymeric material, such as polyimide, other suitable material layer or a combination thereof. In some embodiments, the C4 bumps are designed with dimensions and compositions for die to packaging integration; and the material layer 1104 is a underfilling material to fill the spacing between the die and the packaging structure.

Alternatively, the bond structure may be micro-bumps (μbumps) 1106 as illustrated in FIG. 28B or hybrid bond structure 1108 as illustrated in FIG. 28C. In the embodiment illustrated in FIG. 28C, the IC structure 100 may be bonded to another IC die to form a 3DIC sealed in the same packaging or a system on integrated chips (SoIO) hybrid bond. A dielectric layer 1110, such as silicon nitride, silicon oxide, other suitable dielectric material or a combination thereof, may be present in the bonding interface. Additionally, the bottom surface of the top metal feature 130 may be connected to various features of the interconnect structure 120, such as other metal lines and vias, devices (such as transistors), other capacitors, resistors, and etc. In some embodiments, the micro-bumps 1106 are designed with dimensions and composition to provide IC substrate to IC substrate bonding, such as chip to wafer bonding, chip to chip bonding, or other suitable bonding.

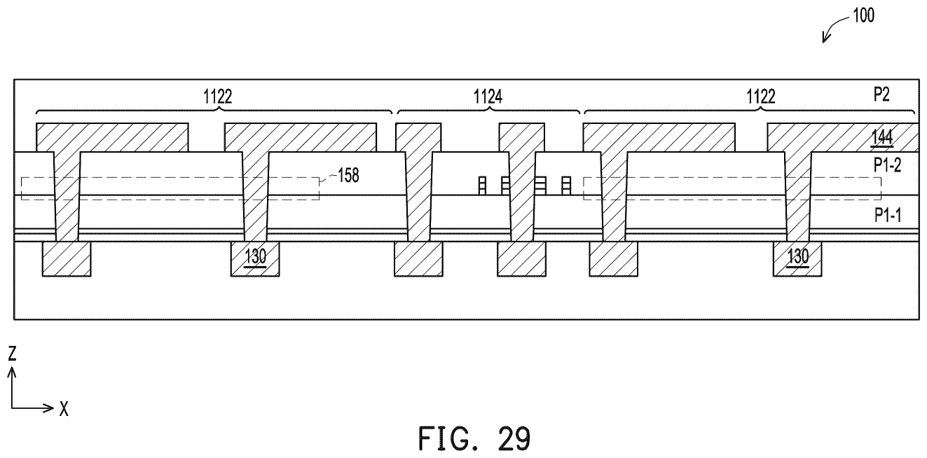

FIG. 29 is a sectional view of an IC structure 100, in portion, constructed according to some embodiments. Especially only a portion of interconnect structure 120 and the passivation structure 140 are illustrated. One or more capacitor 158 are embedded in the passivation structure 140. The RDL structure 144 includes various conductive features with one subset 1122 configured to provide connections to the corresponding capacitors 158 and another subset 1124 configured for redistributing the bonding features.

The present disclosure provides an IC structure having one or more capacitor, and a method making the same. The capacitor includes multiple conductive layers and dielectric layers alternatively stacked and connected through the conductive features to form an interleaved capacitor. Furthermore, the stack of the conductive layers and the dielectric layers is folded and inserted into one or more deep trenches, formed in pillar structures or both. The capacitor includes a plurality of 3D MIM units that includes trench MIM stacks, pillar MIM stacks or hybrid MIM stacks having both aligned and stacked. Each of 3D MIM units may include multiple layers of trench MIM stacks, pillar MIM stacks or both vertically stacked. Multiple layers of trench MIM stacks, pillar MIM stacks or both are aligned and overlapped, or alternatively staggered. By implementing the disclosed structure and the method making the same, the packing area of a capacitor is substantially reduced, and the stress is substantially reduced by achieving the hybrid MIM stacks that are aligned and overlapped. All those spatial configurations collectively further reduce the stress. Though not intended to be limiting, embodiments of the present disclosure offer benefits for semiconductor processing and semiconductor devices. For example, the disclosed structure and method collectively reduce the stress and prevent the workpiece from warpage or other deformation.

In one aspect, the present disclosure provides a semiconductor structure that includes a substrate having devices formed thereon and an interconnect structure electrically coupling the devices into an integrated circuit; a passivation structure formed on the interconnect structure; and a capacitor embedded in the passivation structure, wherein the capacitor includes first metal-insulator-metal (MIM) stacks inserted in first trenches, and second MIM stacks formed into first pillar structures.

In another aspect, the present disclosure provides a semiconductor structure that includes a substrate having devices formed thereon and an interconnect structure electrically coupling the devices into an integrated circuit; a passivation structure formed on the interconnect structure; and a capacitor embedded in the passivation structure. The passivation structure includes a first number N1 of passivation material layers, the capacitor includes a second number N2 of metal-insulator-metal (MIM) stacks alternatively stacked with the first number N1 of passivation material layers, each of N1 and N2 is greater than 2, and the MIM stacks include a first MIM stack inserted in first trenches, and a second MIM stack formed into a first pillar structure.

In yet another aspect, the present disclosure provides a semiconductor structure that includes a substrate having devices formed thereon and an interconnect structure electrically coupling the devices into an integrated circuit; a passivation structure formed on the interconnect structure; and a capacitor embedded in the passivation structure. The passivation structure includes a first number N1 of passivation material layers, the capacitor includes a second number N2 of metal-insulator-metal (MIM) stacks alternatively stacked with the first number N1 of passivation material layers, each of N1 and N2 is greater than 2, and the MIM stacks include a first MIM stack inserted in first trenches, and a second MIM stack formed into a first pillar structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate having devices formed thereon and an interconnect structure electrically coupling the devices into an integrated circuit;
a passivation structure formed on the interconnect structure; and
a capacitor embedded in the passivation structure, wherein the capacitor includes first metal-insulator-metal (MIM) stacks inserted in first trenches, and second MIM stacks formed into first pillar structures.

2. The semiconductor structure of claim 1, wherein each of the first MIM stacks and the second MIM stacks includes a first metal layer, a first dielectric layer disposed on the first metal layer, a second metal layer disposed on the first dielectric layer.

3. The semiconductor structure of claim 2, wherein the first metal layer and the second metal layer include respective openings offset from each other for a first conductive via and a second conductive via to electrically connected to the first metal layer and the second metal layer, respectively.

4. The semiconductor structure of claim 2, wherein the each of the first MIM stacks and the second MIM stacks further includes a second dielectric layer disposed on the second metal layer, and a third metal layer disposed on the second dielectric layer.

5. The semiconductor structure of claim 1, wherein the first MIM stacks and the second MIM stacks are aligned and vertically overlapped.

6. The semiconductor structure of claim 5, wherein the capacitor further includes third MIM stacks inserted in second trenches, and fourth MIM stacks formed into second pillar structures.

7. The semiconductor structure of claim 6, wherein the third MIM stacks and the fourth MIM stacks are vertically stacked and further stacked over the first and second MIM stacks.

8. The semiconductor structure of claim 7, wherein the third MIM stacks and the fourth MIM stacks are aligned and overlapped with the first and second MIM stacks.

9. The semiconductor structure of claim 7, wherein the third MIM stacks and the fourth MIM stacks are offset with the first and second MIM stacks in a staggered configuration.

10. The semiconductor structure of claim 1, wherein the capacitor includes a first number N1 of MIM stacks folded in trenches and a second number N2 of MIM stacks in pillar structures, wherein each of N1 and N2 is greater than 2.

11. The semiconductor structure of claim 10, wherein each of N1 is different from N2.

12. The semiconductor structure of claim 1, further comprising a redistribution structure formed in the passivation structure, wherein the redistribution structure includes conductive features connected to the capacitor as a first electrode and a second electrode of the capacitor.

13. The semiconductor structure of claim 1, wherein the capacitor includes multiple three-dimension (3D) MIM units electrically connected, wherein each of the 3D MIM units includes the first MIM stacks and the second MIM stacks.

14. The semiconductor structure of claim 13, wherein each of the 3D MIM units includes a same shape in a top view.

15. The semiconductor structure of claim 14, wherein the shape of the 3D MIM units includes one of square, rectangle and round.

16. A semiconductor structure, comprising:
a substrate having devices formed thereon and an interconnect structure electrically coupling the devices into an integrated circuit;
a passivation structure formed on the interconnect structure; and
a capacitor embedded in the passivation structure, wherein
the passivation structure includes a first number N1 of passivation material layers,
the capacitor includes a second number N2 of metal-insulator-metal (MIM) stacks alternatively stacked with the first number N1 of passivation material layers,
each of N1 and N2 is greater than 2, and
the MIM stacks include a first MIM stack inserted in first trenches, and a second MIM stack formed into a first pillar structure.

17. The semiconductor structure of claim 16, wherein
each of the first MIM stacks and the second MIM stacks includes a first metal layer, a first dielectric layer disposed on the first metal layer, a second metal layer disposed on the first dielectric layer; and
the first MIM stacks and the second MIM stacks are aligned and vertically overlapped.

18. The semiconductor structure of claim 16, wherein the capacitor further includes
third MIM stacks inserted in second trenches, and fourth MIM stacks formed into second pillar structures;
the third MIM stacks and the fourth MIM stacks are vertically stacked and further stacked over the first and second MIM stacks; and
the third MIM stacks and the fourth MIM stacks are offset with the first and second MIM stacks in a staggered configuration.

19. A method, comprising:
forming devices a substrate;
forming an interconnect structure on the devices and coupling the devices into an integrated circuit; and
forming a passivation structure on the interconnect structure, wherein the forming of the passivation structure includes forming a capacitor embedded in the passivation structure, wherein
the passivation structure includes a first number N1 of passivation material layers,
the capacitor includes a second number N2 of metal-insulator-metal (MIM) stacks alternatively stacked with the first number N1 of passivation material layers,
each of N1 and N2 is greater than 2, and
the MIM stacks include a first MIM stack inserted in first trenches, and a second MIM stack formed into a first pillar structures.

20. The semiconductor structure of claim 19, wherein
each of the first MIM stacks and the second MIM stacks includes a first metal layer, a first dielectric layer disposed on the first metal layer, a second metal layer disposed on the first dielectric layer; and
the first MIM stacks and the second MIM stacks are aligned and vertically overlapped.
